(19) United States
(12) Patent Application Publication
(10) Pub. No.: US 2024/0192563 A1
(43) Pub. Date: Jun. 13, 2024

(54) DYNAMIC SIGNAL ROUTING IN A FACILITY

(71) Applicant: View, Inc., Milpitas, CA (US)

(72) Inventors: Yerang Hur, Fremont, CA (US); Ji Hoon Lee, Louisville, CO (US); Todd Daniel Antes, San Jose, CA (US); Nitesh Trikha, Pleasanton, CA (US)

(21) Appl. No.: 18/555,275

(22) PCT Filed: Apr. 15, 2022
(86) PCT No.: PCT/US2022/024999

§ 371 Date: Oct. 13, 2023

Related U.S. Application Data
(63) Continuation-in-part of application No. 17/904,156, filed on Aug. 12, 2022.
(63) Continuation-in-part of application No. 17/609,671, filed on Nov. 8, 2021.
(63) Continuation-in-part of application No. 17/916,986, filed on Oct. 4, 2022.
(63) Continuation-in-part of application No. 17/679,027, filed on Feb. 23, 2022.
(62) Division of application No. 16/664,089, filed on Oct. 25, 2019, now Pat. No. 11,294,254.
(63) Continuation-in-part of application No. 17/899,019, filed on Aug. 30, 2022.
Application No. 17/899,019 is a continuation of application No. 17/081,809, filed on Oct. 27, 2020, now Pat. No. 11,460,749.
Application No. 17/081,809 is a continuation of application No. 16/608,159, filed on Oct. 24, 2019, now Pat. No. 11,300,849.

(51) Int. Cl. G02F 1/163; B32B 17/10; E06B 9/24; G02F 1/15; G02F 1/155; G05B 15/02; G05B 19/042; G06F 3/041; G06F 3/044; G06F 3/14; G09F 19/22; G09G 3/34; G09G 3/38; H02J 50/20; H02J 50/80; H04K 3/00; H10K 50/80; H10K 59/65

(52) U.S. Cl. CPC G02F 1/163; B32B 17/10513; E06B 9/24; G02F 1/15; G02F 1/155; G05B 15/02; G05B 19/042; G05B 19/0426; G06F 3/0412; G06F 3/044; G06F 3/1446; G09F 19/227; G09G 3/38; H02J 50/20; H02J 50/80; H10K 50/80; H10K 59/65; B32B 2419/00; E06B 2009/2417; E06B 2009/2464; G05B 2219/25011; G05B 2219/25252; G05B 2219/2614; G05B 2219/2628; G05B 2219/2642; G09G 3/3433; G09G 2300/02; G09G 2300/023; G09G 2300/026; G09G 2300/04; G09G 2370/02; G09G 2370/06; G09G 2370/16; H04K 3/45

(57) ABSTRACT

In various embodiments, methods, systems, software, and apparatuses for dynamically routing signals in a facility are provided, e.g., depending on current and/or predicted occupancy in the facility. The method may include: identifying small cell devices and Radio Access Units (RAUs) operatively coupled to a network of the facility; receiving one or more inputs through the network; determining a configuration for routing cellular communication signals between one or more of the small cell devices and one or more of the RAUs, which configuration is based at least in part on the one or more inputs; and routing the cellular communication signals between the one or more of the small cell devices and the one or more of the RAUs based at least in part on the configuration.

### RELATED APPLICATIONS

This International Application claims benefit and priority to U.S. Provisional Patent Application No. 63/187,632, filed May 12, 2021, titled “DYNAMIC SIGNAL ROUTING IN A FACILITY.” This International Application also claims benefit and priority to U.S. Provisional Patent Application No. 63/265,653, filed Dec. 17, 2021, titled “PROVIDING ENHANCED CELLULAR COMMUNICATION IN A FACILITY BACKGROUND.” This application relates as a Continuation-in-Part to International Patent Application Serial No. PCT/US21/17946, filed Feb. 12, 2021 titled “DATA AND POWER NETWORK OF A FACILITY,” which claims priority from U.S. Provisional Patent Application Ser. No. 63/146,365, filed Feb. 5, 2021, titled “DATA AND POWER NETWORK OF A FACILITY,” from U.S. Provisional Patent Application Ser. No. 63/027,452, filed May 20, 2020, titled “DATA AND POWER NETWORK OF AN ENCLOSURE,” from U.S. Provisional Patent Application Ser. No. 62/978,755, filed Feb. 19, 2020, titled “DATA AND POWER NETWORK OF AN ENCLOSURE,” from U.S. Provisional Patent Application Ser. No. 62/977,001, filed Feb. 14, 2020, titled “DATA AND POWER NETWORK OF AN ENCLOSURE.” This application relates as a Continuation-in-Part of International Patent Application Serial No. PCT/US20/32269, filed May 9, 2020, titled “ANTENNA SYSTEMS FOR CONTROLLED COVERAGE IN BUILDINGS,” which claims priority to (i) U.S. Provisional Patent Application Ser. No. 62/850,993, filed May 21, 2019, titled “ANTENNA SYSTEMS FOR CONTROLLED COVERAGE IN BUILDINGS,” and to (ii) U.S. Provisional Patent Application Ser. No. 62/845,764, filed May 9, 2019, titled “ANTENNA SYSTEMS FOR CONTROLLED COVERAGE IN BUILDINGS.” This application relates as a Continuation-in-Part of U.S. patent application Ser. No. 15/709,339, filed Sep. 19, 2017, titled “WINDOW ANTENNAS FOR EMITTING RADIO FREQUENCY SIGNALS.” This application relates as a Continuation-in-Part of U.S. patent application Ser. No. 16/099,424, filed Nov. 6, 2018, titled “WINDOW ANTENNAS,” that is a National Stage Entry of International Patent Application Serial No. PCT/US17/31106, filed May 4, 2017, titled “WINDOW ANTENNAS,” that claims benefit (i) from U.S. Provisional Patent Application Ser. No. 62/379,163, filed Aug. 24, 2016, titled “WINDOW ANTENNAS,” (ii) from U.S. Provisional Patent Application Ser. No. 62/352,508, filed Jun. 20, 2016, titled “WINDOW ANTENNAS,” (iii) from U.S. Provisional Patent Application Ser. No. 62/340,936, filed May 24, 2016, titled “WINDOW ANTENNAS,” and (iv) from U.S. Provisional Patent Application Ser. No. 62/333,103, filed May 6, 2016, titled “WINDOW ANTENNAS.” This application relates as a Continuation-in-Part of U.S. patent application Ser. No. 16/949,978, filed Nov. 23, 2020, titled “WINDOW ANTENNAS,” which is a Continuation of U.S. patent application Ser. No. 16/849,540, filed Apr. 15, 2020, titled “WINDOW ANTENNAS,” that is a Continuation of U.S. patent application Ser. No. 15/529,677, filed May 25, 2017, issued as U.S. Pat. No. 10,673,121 on Jun. 2, 2020, titled “WINDOW ANTENNAS,” that is a National Stage Entry of International Patent Application Serial No. PCT/US15/62387, filed Nov. 24, 2015, titled “WINDOW ANTENNAS,” which claims benefit from U.S. Provisional Patent Application Ser. No. 62/084,502, filed Nov. 25, 2014, titled “WINDOW ANTENNAS.” This International Application also claims benefit and priority to, and is a Continuation-in-Part of, International Patent Application Serial No. PCT/US21/27418, filed Apr. 15, 2021, titled “INTERACTION BETWEEN AN ENCLOSURE AND ONE OR MORE OCCUPANTS”. International Patent Application Serial No. PCT/US21/27418, filed Apr. 15, 2021, titled “INTERACTION BETWEEN AN ENCLOSURE AND ONE OR MORE OCCUPANTS, claims priority from U.S. Provisional Patent Application Ser. No. 63/080,899, filed Sep. 21, 2020, titled “INTERACTION BETWEEN AN ENCLOSURE AND ONE OR MORE OCCUPANTS,” from U.S. Provisional Patent Application Ser. No. 63/052,639, filed Jul. 16, 2020, titled “INDIRECT INTERACTIVE INTERACTION WITH A TARGET IN AN ENCLOSURE,” and from U.S. Provisional Patent Application Ser. No. 63/010,977, filed Apr. 16, 2020, titled “INDIRECT INTERACTION WITH A TARGET IN AN ENCLOSURE.” Ibis application also relates as a Continuation-In-Part to U.S. patent application Ser. No. 17/083,128, filed Oct. 28, 2020, titled “BUILDING NETWORK,” which is a Continuation of U.S. patent application Ser. No. 16/664,089, filed Oct. 25, 2019, titled “BUILDING NETWORK,” that is a National Stage Entry of International Patent Application Serial No. PCT/US19/30467, filed May 2, 2019, titled “EDGE NETWORK FOR BUILDING SERVICES,” which claims priority from U.S. Provisional Patent Application Ser. No. 62/666,033, filed May 2, 2018, titled “EDGE NETWORK FOR BUILDING SERVICES.” U.S. patent application Ser. No. 17/083,128, is also a Continuation-In-Part of International Patent Application Serial No. PCT/US18/29460, filed Apr. 25, 2018, titled “TINTABLE WINDOW SYSTEM FOR BUILDING SERVICES,” which claims priority from (i) U.S. Provisional Patent Application Ser. No. 62/607,618, filed Dec. 19, 2017, titled “ELECTROCHROMIC WINDOWS WITH TRANSPARENT DISPLAY TECHNOLOGY FIELD,” (ii) U.S. Provisional Patent Application Ser. No. 62/523,606, filed Jun. 22, 2017, titled “ELECTROCHROMIC WINDOWS WITH TRANSPARENT DISPLAY TECHNOLOGY,” (iii) U.S. Provisional Patent Application Ser. No. 62/507,704, filed May 17, 2017, titled “ELECTROCHROMIC WINDOWS WITH TRANSPARENT DISPLAY TECHNOLOGY,” (iv) U.S. Provisional Patent Application Ser. No. 62/506,514, filed May 15, 2017, titled “ELECTROCHROMIC WINDOWS WITH TRANSPARENT DISPLAY TECHNOLOGY,” and (v) U.S. Provisional Patent Application Ser. No. 62/490,457, filed Apr. 26, 2017, titled “ELECTROCHROMIC WINDOWS WITH TRANSPARENT DISPLAY TECHNOLOGY.” Ibis application relates as a Continuation-in-Part to U.S. patent application Ser. No. 17/081,809, filed Oct. 27, 2020, titled “TINTABLE WINDOW SYSTEM COMPUTING PLATFORM,” which is a Continuation of U.S. patent application Ser. No. 16/608,159, filed Oct. 24, 2019, titled “TINTABLE WINDOW SYSTEM COMPUTING PLATFORM,” that is a National Stage Entry of International Patent Application Serial No. PCT/US18/29406, filed Apr. 25, 2018, titled “TINTABLE WINDOW SYSTEM COMPUTING PLATFORM,” which claims priority from U.S. Provisional Patent Application Ser. No. 62/607,618, U.S. Provisional Patent Application Ser. No. 62/523,606, from U.S. Provisional Patent Application Ser. No. 62/507,704, U.S. Provisional Patent Application Ser. No. 62/506,514, and from U.S. Provisional Patent Application Ser. No. 62/490,457. Each of the above recited patent applications is entirely incorporated herein by reference.

### BACKGROUND

Macro cells are at times used to provide cellular communication to facilities, for example, by providing cellular communication signals from a carrier network to facilities. However, macro cells may have some disadvantages. For example, a macro cell is required to be positioned at a distance from a facility and/or at a high elevation, e.g., thus requiring expensive cabling from the macro cell to the facility. For example, a macro cell may be expensive to operate (e.g., due to hardware required to cool the macro cell). For example, a macro cell be unable to accommodate dynamically changing connectivity needs within a facility.

### SUMMARY

Various aspects disclosed herein alleviate as least part of the above referenced shortcomings.

As disclosed herein, types and/or strength of signals diverted to various facility spaces may be manipulated. Signals may be provided to a facility via a distributed antenna system (DAS) that is operatively coupled to one or more small cell devices. Configuration of one or more small cell devices with respect to a DAS may be based at least in part on signals from a control network, sensors, emitters, transceivers, or the like.

In another aspect, a method of routing signals in a facility, the method comprises: identifying small cell devices and Radio Access Units (RAUs) operatively coupled to a network of the facility; receiving one or more inputs through the network; determining a configuration for routing cellular communication signals between one or more of the small cell devices and one or more of the RAUs, which configuration is based at least in part on the one or more inputs; and routing the cellular communication signals between the one or more of the small cell devices and the one or more of the RAUs based at least in part on the configuration.

In some embodiments, the small cell devices are disposed in the facility. In some embodiments, the RAUs are disposed in the facility. In some embodiments, the network is operatively coupled to one or more sensors of the facility. In some embodiments, the one or more sensors are disposed in the facility. In some embodiments, the one or more sensors are disposed outside of the facility. In some embodiments, the one or more sensors are attached to the facility. In some embodiments, the network comprises cabling. In some embodiments, the cabling comprises optical cabling and/or coaxial cabling. In some embodiments, a cable of the cabling is configured to transmit electrical power and communication signals. In some embodiments, a cable of the cabling is configured to transmit electrical power, cellular communication signals, and communication signals of at least one other communication type. In some embodiments, a cable of the cabling is disposed at least in part in an envelope of the facility. In some embodiments, the facility comprises a building. In some embodiments, a cable of the cabling is disposed at least in part in an envelope of the building. In some embodiments, the cabling is a first cabling system installed in the facility. In some embodiments, the at least one other communication type comprises media communication, control communication, or data communication. In some embodiments, the data communication comprises communication of sensor data. In some embodiments, the one or more inputs are associated with an occupancy of personnel in the facility. In some embodiments, the one or more inputs comprise scheduling information, occupancy information, sensor data, or any combination thereof. In some embodiments, the sensor data comprises electromagnetic radiation data. In some embodiments, the electromagnetic radiation data comprises data associated with electromagnetic radiation in a visual spectrum, an infrared spectrum, a radio frequency spectrum, or any combination thereof. In some embodiments, the electromagnetic radiation data comprises data associated with ultrawideband radiation. In some embodiments, the sensor data comprises geolocation signals. In some embodiments, the geolocation signals comprise Global Positioning System signals, ultrawideband signals, short-range wireless signal, or any combination thereof. In some embodiments, the sensor data comprises heat signatures associated with one or more personnel. In some embodiments, the configuration is dynamically determined. In some embodiments, the configuration is determined in real-time during receipt of the cellular communication signals. In some embodiments, the network is operatively coupled to one or more controllers. In some embodiments, the one or more controllers are part of a hierarchical control system. In some embodiments, the one or more controllers are configured to control at least one device. In some embodiments, the at least one device includes (i) a service device, (ii) a safety device, (iii) a security device, and/or (iv) a health device. In some embodiments, the service device comprises a media player, a media display, a radio, a music player, a heater, a cooler, a ventilator, lighting, a tintable window, an automatic door, or a heating, ventilation, and air conditioning (HVAC) system. In some embodiments, the service device is configured to adjust an environment of the facility. In some embodiments, the safety device comprises an alarm, an announcement system, alarm lighting, a sensor, a door, a window, or a lock. In some embodiments, the door, window, and/or lock, are automatic. In some embodiments, the at least one device comprises a sensor. In some embodiments, the sensor includes a temperature sensor, a motion sensor, a pressure sensor, an infrared sensor, a visual sensor, and/or an occupancy sensor. In some embodiments, the health device comprises a glucose monitor, a heart rate monitor, a blood pressure monitor, a temperature sensor, an infrared sensor, an ultraviolet sensor, or a visual sensor. In some embodiments, the service device includes a processor, or a media display. In some embodiments, the media display comprises a television screen or a computer monitor. In some embodiments, the at least one device is disposed in a device ensemble. In some embodiments, the device ensemble comprises (i) a sensors or (ii) a sensor and an emitter. In some embodiments, the device ensemble is affixed to, or disposed in, a fixture of the facility. In some embodiments, the cellular communication signals arrive at the small cell devices directly from a service provider. In some embodiments, the configuration dynamically routes the cellular communication signals based at least in part on occupancy in one or more portions of the facility. In some embodiments, the configuration is based at least in part on an occupancy in the facility. In some embodiments, the configuration is based at least in part on an occupancy of users of the cellular communication signals in the facility. In some embodiments, routing the cellular communication signals between the one or more of the small cell devices and the one or more of the RAUs based at least in part on the configuration comprises transmitting information indicating the configuration to a router associated with the facility, the router configurable to carry out routing of the cellular communication signals between the one or more of the small cell devices and the one or more of the RAUs. In some embodiments, the cellular communication signals are modulated.

In another aspect, an apparatus for routing signals in a facility, the apparatus comprising at least one controller configured to execute, or direct execution of, one or more operations of any of the methods disclosed above.

In some embodiments, the at least one controller comprises circuitry. In some embodiments, at least two of the one or more operations are executed by a controller of the at least one controller. In some embodiments, at least two of the one or more operations are each executed by a different controllers of the at least one controller.

In another aspect, an apparatus for routing signals in a facility, the apparatus comprises at least one controller, which at least one controller is configured to: operatively couple (i) to small cell devices and (ii) to Radio Access Units (RAUs), which are operatively coupled to a network of the facility; receive, or direct receipt of, one or more inputs through the network; determine, or direct determination of, a configuration for routing cellular communication signals between one or more of the small cell devices and one or more of the RAUs, which configuration is based at least in part on the one or more inputs; and route, or direct routing of, the cellular communication signals between the one or more of the small cell devices and the one or more of the RAUs based at least in part on the configuration.

In some embodiments, the at least one controller is configured to direct a device. In some embodiments, the at least one controller is part of a distributed network of controllers in which one controller is configured to direct another controller. In some embodiments, the one controller and the other controller are part of the distributed network of controllers. In some embodiments, the distributed network of controllers is a hierarchical network of controllers.

In another aspect, a non-transitory computer program instructions for routing signals in a facility, the non-transitory computer program instructions, when read by one or more processors, causes the one or more processors to execute, or direct execution of, one or more operations of any of the methods disclosed above.

In some embodiments, the program instructions are embedded in at least one program product. In some embodiments, the program instructions are embedded in a medium or in media. In some embodiments, at least two of the one or more operations are executed by a processor of the one or more processors. In some embodiments, at least two of the one or more operations are each executed by a different processor of the one or more processors.

In another aspect, a non-transitory computer readable program instructions for routing signals in a facility, the non-transitory computer readable program instructions, when read by one or more processors, causes the one or more processors to execute operations comprises: receiving, or directing receipt of, one or more inputs through the network; determining, or directing determination of, a configuration for routing cellular communication signals between one or more of the small cell devices and one or more of the RAUs, which configuration is based at least in part on the one or more inputs; and routing the cellular communication signals between the one or more of the small cell devices and the one or more of the RAUs based at least in part on the configuration wherein the one or more processors are operatively coupled (i) to the small cell devices and (ii) to the Radio Access Units (RAUs), which are operatively coupled to the network of the facility.

In some embodiments, the one or more processors are configured to direct a device. In some embodiments, the one or more processors are part of a distributed network of processors in which one processor is configured to direct another processor. In some embodiments, the one processors and the other processor are part of the distributed network of processors. In some embodiments, the distributed network of processors is a hierarchical network of processors.

In another aspect, a system for routing signals in a facility, the system comprises a network disposed in the facility; one or more small cell devices operatively coupled to the network; and one or more RAUs operatively coupled to the network; which network is configured to facilitate one or more operations of any of the methods disclosed above.

In some embodiments, the network is configured to facilitate control at least in part by being configured to transmit control related communication. In some embodiments, the network is configured to facilitate the one or more operations at least in part by being configured to transmit communication of one or more protocols associated with the one or more operations.

In another aspect, a system for routing signals in a facility, the system comprises: a network disposed in the facility; one or more small cell devices operatively coupled to the network; one or more RAUs operatively coupled to the network; which network is configured to facilitate: transmission of one or more inputs; determination of a configuration for routing cellular communication signals between one or more of the small cell devices and one or more of the RAUs, which configuration is based at least in part on the one or more inputs; and routing the cellular communication signals to be routed between the one or more small cell devices and the one or more RAUs based at least in part on the configuration.

In some embodiments, the network is configured to facilitate transmission of the one or more inputs, determination of the configuration, and routing the cellular communication signals at least in part by being configured to transmit appropriate signals confirming to respective protocols.

In another aspect, a method of changing communications characteristics in a facility, the method comprises: obtaining a configuration for routing signals between one or more small cell devices associated with the facility and one or more Radio Access Units (RAUs) associated with the facility; obtaining usage information associated with the facility, wherein the usage information indicates current or expected small cell device usage by mobile devices associated with the facility; determining one or more parameters associated with: (I) a channel sharing protocol for two or more small cell devices allocated to an RAU of the one or more RAUs based at least in part on the configuration, (II) transmit or receive power specifications for one or more components associated with the facility based at least in part on the usage information, or (III) any combination thereof; and providing the one or more parameters associated with: (i) the channel sharing protocol to the two or more small cell devices, (ii) the transmit or receive power specifications to the one or more components associated with the facility, or (iii) any combination thereof.

In some embodiments, the one or more small cell devices are disposed in the facility. In some embodiments, the one or more RAUs are disposed in the facility. In some embodiments, the usage information is based on data from one or more sensors of the facility. In some embodiments, the one or more sensors are disposed in the facility. In some embodiments, the one or more sensors are disposed outside the facility. In some embodiments, the one or more sensors are attached to the facility. In some embodiments, the one or more sensors provide sensor data comprising electromagnetic radiation data. In some embodiments, the electromagnetic radiation data comprises data associated with electromagnetic radiation in a visual spectrum, an infrared spectrum, a radio frequency spectrum, or any combination thereof. In some embodiments, the electromagnetic radiation data comprises data associated with ultrawideband radiation. In some embodiments, the one or more sensors provide sensor data comprising geolocation signals. In some embodiments, the geolocation signals comprise Global Positioning System signals, ultrawideband signals, short-range wireless signal, or any combination thereof. In some embodiments, the one or more sensors provide sensor data comprising heat signatures associated with one or more personnel. In some embodiments, the facility comprises a building. In some embodiments, the usage information is received via a network associated with the facility. In some embodiments, the network comprises cabling. In some embodiments, the cabling comprises optical cabling and/or coaxial cabling. In some embodiments, a cable of the cabling is disposed at least in part in an envelope of a building of the facility. In some embodiments, the usage information comprises scheduling information, occupancy information, or any combination thereof. In some embodiments, the scheduling information comprises calendar information associated with the facility. In some embodiments, the calendar information indicates scheduled events at one or more locations of the facility. In some embodiments, the occupancy information comprises current occupancy at one or more locations of the facility. In some embodiments, the occupancy information comprises a future occupancy at one or more locations of the facility. In some embodiments, the future occupancy is predicted by a machine learning model trained to predict the future occupancy at the one or more locations of the facility. In some embodiments, the one or more parameters are determined based on a noise level in the facility. In some embodiments, the noise level in the facility is based on current or planned construction in the facility. In some embodiments, determining the one or more parameters associated with the channel sharing protocol comprises determining two or more channels corresponding to the two or more small cell devices allocated to the one RAU. In some embodiments, the channel sharing protocol comprises Frequency Division Multiple Access (FDMA). In some embodiments, the one or more components comprise a headend router associated with the facility, one or more of the one or more RAUs, one or more antennas operatively coupled to the one or more RAUs, or any combination thereof.

In another aspect, an apparatus for changing communications characteristics in a facility, the apparatus comprises at least one controller configured to execute, or direct execution of, one or more operations of any of the methods disclosed above.

In another aspect, an apparatus for changing communications characteristics in a facility, the apparatus comprises at least one controller, which at least one controller is configured to: obtain, or direct obtainment of, a configuration for routing signals between one or more small cell devices associated with the facility and one or more Radio Access Units (RAUs) associated with the facility; obtain, or direct obtainment of, usage information associated with the facility, wherein the usage information indicates current or expected small cell device usage by mobile devices associated with the facility; determine, or direct determination of, one or more parameters associated with: (I) a channel sharing protocol for two or more small cell devices allocated to an RAU of the one or more RAUs based at least in part on the configuration, (II) transmit or receive power specifications for one or more components associated with the facility based at least in part on the usage information, or (III) any combination thereof; and provide, or direct provision of, the one or more parameters associated with: (i) the channel sharing protocol to the two or more small cell devices, (ii) the transmit or receive power specifications to the one or more components associated with the facility, or (iii) any combination thereof.

In another aspect, a non-transitory computer readable program instructions for changing communications characteristics in a facility, the non-transitory computer program instructions, when read by one or more processors, causes the one or more processors to execute, or direct execution of, one or more operations of any of the methods disclosed above.

In another aspect, a non-transitory computer readable program instructions for changing communications characteristics in a facility, the non-transitory computer readable program instructions, when read by one or more processors, causes the one or more processors to execute operations comprising: obtaining, or directing obtainment of, usage information associated with the facility, wherein the usage information indicates current or expected small cell device usage by mobile devices associated with the facility; obtaining, or directing obtainment of, usage information associated with the facility, wherein the usage information indicates current or expected small cell device usage by mobile devices associated with the facility; determining, or directing determination of, one or more parameters associated with: (I) a channel sharing protocol for two or more small cell devices allocated to an RAU of the one or more RAUs based at least in part on the configuration, (II) power specifications for one or more components associated with the facility based at least in part on the usage information, or (III) any combination thereof; and providing, or directing provision of, the one or more parameters associated with: (i) the channel sharing protocol to the two or more small cell devices, (ii) the exchange of power specifications to the one or more components associated with the facility, or (iii) any combination thereof.

In some embodiments, the power specifications for the one or more components comprise a transmit power and/or a receive power.

In another aspect, a system for changing communication characteristics in a facility, the system comprises one or more small cell devices associated with the facility and one or more RAUs associated with the facility, and at least one controller configured to facilitate one or more operations of any of the methods disclosed above.

In another aspect, a system for changing communication characteristics in a facility, the system comprises: a network disposed in the facility; one or more small cell devices operatively coupled to the network; one or more Radio Access Units (RAUs) operatively coupled to the network; which network is configured to facilitate: obtaining a configuration for routing signals between the one or more small cell devices associated with the facility and the one or more RAUs associated with the facility; obtaining usage information associated with the facility, wherein the usage information indicates current or expected small cell device usage by mobile devices associated with the facility; determining one or more parameters associated with: (I) a channel sharing protocol for two or more small cell devices allocated to an RAU of the one or more RAUs based at least in part on the configuration, (II) transmit or receive power specifications for one or more components associated with the facility based at least in part on the usage information, or (III) any combination thereof; and providing the one or more parameters associated with: (i) the channel sharing protocol to the two or more small cell devices, (ii) the transmit or receive power specifications to the one or more components associated with the facility, or (iii) any combination thereof.

In some embodiments, the network is configured to facilitate obtaining of the configuration, obtaining the usage information, determining the one or more parameters, and providing the one or more parameters, at least in part by being configured to transmit appropriate signals confirming to respective protocols.

In another aspect, a method of routing signals in a facility, the method comprising: receiving a configuration for routing cellular communication signals between small cell devices associated with the facility and Radio Access Units (RAUs) associated with the facility; and routing the cellular communication signals between one or more of the small cell devices and one or more of the RAUs, wherein routing the cellular communication signals between the one or more of the small cell devices and the one or more of the RAUs comprises: (i) (A) receiving a downstream cellular communication signal from at least one of the one or more of the small cell devices; (B) manipulating the downstream cellular communication signal at least in part by splitting and/or combining the downstream cellular communication signal based at least in part on the configuration; and (C) routing the downstream cellular communication signal manipulated, to at least one RAU of the one or more of the RAUs based at least in part on the configuration; and/or (ii) (a) receiving an upstream cellular communication signal from at least one RAU of the one or more of the RAUs; (b) manipulating the upstream cellular communication signal by splitting and/or combining the upstream cellular communication signal based at least in part on the configuration; and (c) routing the manipulated upstream cellular communication signal to at least one of the one or more of the small cell devices based at least in part on the configuration.

In some embodiments, the downstream cellular communication signals have been modulated. In some embodiments, the downstream cellular communication signal has been modulated to a baseband frequency or an Intermediate Frequency (IF) prior to routing to the at least one RAU. In some embodiments, the upstream cellular communication signal has have been modulated. In some embodiments, the upstream cellular communication signal has been modulated to a baseband frequency or an Intermediate Frequency (IF) prior to routing to the one or more small cell devices. In some embodiments, manipulating the downstream cellular communication signal comprises splitting the downstream cellular communication signal to a number of channels that corresponds to a number of RAUs to which the downstream cellular communication signal manipulated, is routed. In some embodiments, manipulating the downstream cellular communication signal comprises combining downstream cellular communication signals from two or more small cell devices to one channel that is routed to a single RAU. In some embodiments, manipulating the upstream cellular communication signal comprises splitting the upstream cellular communication signal from a single RAU to a number of channels that corresponds to a number of small cell devices to which the manipulated upstream cellular communication signal is routed. In some embodiments, manipulating the upstream cellular communication signal comprises combining upstream cellular communication signals from two or more RAUs to one channel that is routed to a single small cell device. In some embodiments, the small cell devices are disposed in the facility. In some embodiments, the RAUs are disposed in the facility. In some embodiments, the small cell devices and the RAUs are operatively coupled to a network of the facility. In some embodiments, the configuration is obtained via the network. In some embodiments, the network comprises cabling. In some embodiments, the cabling comprises optical cabling and/or coaxial cabling. In some embodiments, the downstream cellular communication signal manipulated, is routed to the at least one RAU via the cabling. In some embodiments, the cabling is configured to transmit electrical power and communication signals. In some embodiments, a cable of the cabling is configured to transmit electrical power, cellular communication signals, and communication signals of at least one other communication type. In some embodiments, a cable of the cabling is disposed at least in part in an envelope of the facility. In some embodiments, the facility comprises a building. In some embodiments, the cabling is disposed at least in part in an envelope of the building. In some embodiments, the cabling is a first cabling system installed in the facility.

In another aspect, an apparatus for routing signals in a facility, the apparatus comprises at least one controller configured to execute, or direct execution of, one or more operations of any of the methods disclosed above.

In another aspect, an apparatus for routing signals in a facility, the apparatus comprises at least one controller, which at least one controller is configured to: receive, or direct receipt of, a configuration for routing cellular communication signals between small cell devices associated with the facility and Radio Access Units (RAUs) associated with the facility; and route, or direct routing of, the cellular communication signals between one or more of the small cell devices and one or more of the RAUs, wherein routing the cellular communication signals between the one or more of the small cell devices and the one or more of the RAUs comprises: (i) (A) receive, or direct receipt of, a downstream cellular communication signal from at least one of the one or more of the small cell devices; (B) manipulate, or direct manipulation of, the downstream cellular communication signal by splitting and/or combining the downstream cellular communication signal based at least in part on the configuration; and (C) route, or direct routing of, the downstream cellular communication signal manipulated, to at least one RAU of the one or more of the RAUs based at least in part on the configuration; and/or (ii)(a) receive, or direct receipt of, an upstream cellular communication signal from at least one RAU of the one or more of the RAUs; (b) manipulate, or direct manipulation of, the upstream cellular communication signal at least in part by splitting and/or combining the upstream cellular communication signal based at least in part on the configuration; and (c) routing the upstream cellular communication signal manipulated, to at least one of the one or more of the small cell devices based at least in part on the configuration.

In another aspect, a non-transitory computer readable program instructions for routing signals in a facility, the non-transitory computer program instructions, when read by one or more processors, causes the one or more processors to execute, or direct execution of, one or more operations of any of the methods disclosed above.

In another aspect, a non-transitory computer readable program instructions for routing signals in a facility, the non-transitory computer program instructions, when read by one or more processors, causes the one or more processors to execute operations comprising: receiving, or directing receipt of, a configuration for routing cellular communication signals between small cell devices associated with the facility and Radio Access Units (RAUs) associated with the facility; and routing, or directing routing of, the cellular communication signals between one or more of the small cell devices and one or more of the RAUs, wherein routing, or directing routing of, the cellular communication signals between the one or more of the small cell devices and the one or more of the RAUs comprises: (i) (A) receiving, or directing receipt of, a downstream cellular communication signal from at least one of the one or more of the small cell devices; (B) manipulating, or directing manipulation of, the downstream cellular communication signal by splitting and/or combining the downstream cellular communication signal based at least in part on the configuration; and (C) routing, or directing routing of, the downstream cellular communication signal manipulated, to at least one RAU of the one or more of the RAUs based at least in part on the configuration; and/or (ii) (a) receiving, or directing receipt of, an upstream cellular communication signal from at least one RAU of the one or more of the RAUs; (b) manipulating, or directing manipulation of, the upstream cellular communication signal at least in part by splitting and/or combining the upstream cellular communication signal based at least in part on the configuration; and (c) routing, or directing routing of, the upstream cellular communication signal manipulated, to at least one of the one or more of the small cell devices based at least in part on the configuration.

In another aspect, a system for routing signals in a facility, the system comprising one or more small cell devices associated with the facility, one or more Radio Access Units (RAUs) associated with the facility, and at least one controller configured to facilitate one or more operations of any of the methods disclosed above.

In another aspect, a system for routing signals in a facility, the system comprises: a network disposed in the facility; small cell devices operatively coupled to the network; Radio Access Units (RAUs) operatively coupled to the network; and a router operatively coupled to the network, which router is configured to: receive, or direct receipt of, a configuration for routing cellular communication signals between small cell devices associated with the facility and Radio Access Units (RAUs) associated with the facility; and route, or direct routing of, the cellular communication signals between one or more of the small cell devices and one or more of the RAUs, wherein routing the cellular communication signals between the one or more of the small cell devices and the one or more of the RAUs comprises: (i) (A) receive, or direct receipt of, a downstream cellular communication signal from at least one of the one or more of the small cell devices; (B) manipulating the downstream cellular communication signal by splitting and/or combining the downstream cellular communication signal based at least in part on the configuration; and (C) routing the downstream cellular communication signal manipulated, to at least one RAU of the one or more of the RAUs based at least in part on the configuration; and/or (ii) (a) receive, or direct receipt of, an upstream cellular communication signal from at least one RAU of the one or more of the RAUs; (b) manipulating the upstream cellular communication signal at least in part by splitting and/or combining the upstream cellular communication signal based at least in part on the configuration; and (c) routing the upstream cellular communication signal manipulated, to at least one of the one or more of the small cell devices based at least a in part on the configuration.

In some embodiments, the router comprises at least one processor one or more processors.

In some embodiments, the network is a local network (e.g., a network of a facility). In some embodiments, the network comprises a cable configured to transmit power and communication in a single cable. The communication can be one or more types of communication. The communication can comprise cellular communication abiding by at least a second generation (2G), third generation (3G), fourth generation (4G) or fifth generation (5G) cellular communication protocol. In some embodiments, the communication comprises media communication facilitating stills, music, or moving picture streams (e.g., movies or videos). In some embodiments, the communication comprises data communication (e.g., sensor data). In some embodiments, the communication comprises control communication, e.g., to control the one or more nodes operatively coupled to the networks. In some embodiments, the network comprises a first (e.g., cabling) network installed in the facility. In some embodiments, the network comprises a (e.g., cabling) network installed in an envelope of the facility (e.g., in an envelope of a building included in the facility).

In another aspect, the present disclosure provides systems, apparatuses (e.g., controllers), and/or non-transitory computer-readable medium or media (e.g., software) that implement any of the methods disclosed herein.

In another aspect, the present disclosure provides methods that use any of the systems, computer readable media, and/or apparatuses disclosed herein, e.g., for their intended purpose.

In another aspect, an apparatus comprises at least one controller that is programmed to direct a mechanism used to implement (e.g., effectuate) any of the method disclosed herein, which at least one controller is configured to operatively couple to the mechanism. In some embodiments, at least two operations (e.g., of the method) are directed/executed by the same controller. In some embodiments, at less at two operations are directed/executed by different controllers.

In another aspect, an apparatus comprises at least one controller that is configured (e.g., programmed) to implement (e.g., effectuate) any of the methods disclosed herein. The at least one controller may implement any of the methods disclosed herein. In some embodiments, at least two operations (e.g., of the method) are directed/executed by the same controller. In some embodiments, at less at two operations are directed/executed by different controllers.

In some embodiments, one controller of the at least one controller is configured to perform two or more operations. In some embodiments, two different controllers of the at least one controller are configured to each perform a different operation.

In another aspect, a system comprises at least one controller that is programmed to direct operation of at least one another apparatus (or component thereof), and the apparatus (or component thereof), wherein the at least one controller is operatively coupled to the apparatus (or to the component thereof). The apparatus (or component thereof) may include any apparatus (or component thereof) disclosed herein. The at least one controller may be configured to direct any apparatus (or component thereof) disclosed herein. The at least one controller may be configured to operatively couple to any apparatus (or component thereof) disclosed herein. In some embodiments, at least two operations (e.g., of the apparatus) are directed by the same controller. In some embodiments, at less at two operations are directed by different controllers.

In another aspect, a computer software product (e.g., inscribed on one or more non-transitory medium) in which program instructions are stored, which instructions, when read by at least one processor (e.g., computer), cause the at least one processor to direct a mechanism disclosed herein to implement (e.g., effectuate) any of the method disclosed herein, wherein the at least one processor is configured to operatively couple to the mechanism. The mechanism can comprise any apparatus (or any component thereof) disclosed herein. In some embodiments, at least two operations (e.g., of the apparatus) are directed/executed by the same processor. In some embodiments, at less at two operations are directed/executed by different processors.

In another aspect, the present disclosure provides a non-transitory computer-readable program instructions (e.g., included in a program product comprising one or more non-transitory medium) comprising machine-executable code that, upon execution by one or more processors, implements any of the methods disclosed herein. In some embodiments, at least two operations (e.g., of the method) are directed/executed by the same processor. In some embodiments, at less at two operations are directed/executed by different processors.

In another aspect, the present disclosure provides a non-transitory computer-readable medium or media comprising machine-executable code that, upon execution by one or more processors, effectuates directions of the controller(s) (e.g., as disclosed herein). In some embodiments, at least two operations (e.g., of the controller) are directed/executed by the same processor. In some embodiments, at less at two operations are directed/executed by different processors.

In another aspect, the present disclosure provides a computer system comprising one or more computer processors and a non-transitory computer-readable medium or media coupled thereto. The non-transitory computer-readable medium comprises machine-executable code that, upon execution by the one or more processors, implements any of the methods disclosed herein and/or effectuates directions of the controller(s) disclosed herein.

In another aspect, the present disclosure provides a non-transitory computer readable program instructions that, when read by one or more processors, causes the one or more processors to execute any operation of the methods disclosed herein, any operation performed (or configured to be performed) by the apparatuses disclosed herein, and/or any operation directed (or configured to be directed) by the apparatuses disclosed herein.

In some embodiments, the program instructions are inscribed in a non-transitory computer readable medium or media. In some embodiments, at least two of the operations are executed by one of the one or more processors. In some embodiments, at least two of the operations are each executed by different processors of the one or more processors.

The content of this summary section is provided as a simplified introduction to the disclosure and is not intended to be used to limit the scope of any invention disclosed herein or the scope of the appended claims.

Additional aspects and advantages of the present disclosure will become readily apparent to those skilled in this art from the following detailed description, wherein only illustrative embodiments of the present disclosure are shown and described. As will be realized, the present disclosure is capable of other and different embodiments, and its several details are capable of modifications in various obvious respects, all without departing from the disclosure. Accordingly, the drawings and description are to be regarded as illustrative in nature, and not as restrictive.

These and other features and embodiments will be described in more detail with reference to the drawings.

### INCORPORATION BY REFERENCE

All publications, patents, and patent applications mentioned in this specification are herein incorporated by reference to the same extent as if each individual publication, patent, or patent application was specifically and individually indicated to be incorporated by reference.

### BRIEF DESCRIPTION OF THE DRAWINGS

The novel features of the invention are set forth with particularity in the appended claims. A better understanding of the features and advantages of the present invention will be obtained by reference to the following detailed description that sets forth illustrative embodiments, in which the principles of the invention are utilized, and the accompanying drawings or figures (also “Fig.” and “Figs.” herein), of which:

FIG. 1 schematically shows routing of signals associated with a facility;

FIG. 2 schematically shows routing of signals associated with a facility;

FIG. 3 schematically shows routing of signals associated with a facility;

FIG. 4 schematically shows an infrastructure of a building;

FIG. 5 schematically shows a network infrastructure of a building;

FIG. 6 illustrates an example routing configuration;

FIG. 7 illustrates an example routing configuration;

FIG. 8 is an information flow diagram for routing downstream signals;

FIG. 9 is an information flow diagram for routing upstream signals;

FIG. 10 is a system diagram of an example system for routing signals;

FIG. 11 is a flow diagram for determining a configuration for routing signals;

FIG. 12 is a flow diagram for determining usage information;

FIG. 13 is a flow diagram for determining signal characteristics;

FIG. 14 schematically shows an electrochromic device;

FIG. 15 schematically shows a cross-section of a tintable window;

FIG. 16 schematically shows an example of a control system architecture; and

FIG. 17 schematically shows an example computer system.

The figures and components therein may not be drawn to scale. Various components of the figures described herein may not be drawn to scale.

### DETAILED DESCRIPTION

While various embodiments of the invention have been shown, and described herein, it will be obvious to those skilled in the art that such embodiments are provided by way of example only. Numerous variations, changes, and substitutions may occur to those skilled in the art without departing from the invention. It should be understood that various alternatives to the embodiments of the invention described herein might be employed.

Terms such as “a,” “an,” and “the” are not intended to refer to only a singular entity but include the general class of which a specific example may be used for illustration. The terminology herein is used to describe specific embodiments of the invention(s), but their usage does not delimit the invention(s).

When ranges are mentioned, the ranges are meant to be inclusive, unless otherwise specified. For example, a range between value 1 and value 2 is meant to be inclusive and include value 1 and value 2. The inclusive range will span any value from about value 1 to about value 2. The term “adjacent” or “adjacent to,” as used herein, includes “next to,” “adjoining,” “in contact with,” and “in proximity to.”

As used herein, including in the claims, the conjunction “and/or” in a phrase such as “including X, Y, and/or Z”, refers to in inclusion of any combination or plurality of X, Y, and Z. For example, such phrase is meant to include X. For example, such phrase is meant to include Y. For example, such phrase is meant to include Z. For example, such phrase is meant to include X and Y. For example, such phrase is meant to include X and Z. For example, such phrase is meant to include Y and Z. For example, such phrase is meant to include a plurality of Xs. For example, such phrase is meant to include a plurality of Ys. For example, such phrase is meant to include a plurality of Zs. For example, such phrase is meant to include a plurality of Xs and a plurality of Ys. For example, such phrase is meant to include a plurality of Xs and a plurality of Zs. For example, such phrase is meant to include a plurality of Ys and a plurality of Zs. For example, such phrase is meant to include a plurality of Xs and Y. For example, such phrase is meant to include a plurality of Xs and Z. For example, such phrase is meant to include a plurality of Ys and Z. For example, such phrase is meant to include X and a plurality of Ys. For example, such phrase is meant to include X and a plurality of Zs. For example, such phrase is meant to include Y and a plurality of Zs.

The term “operatively coupled” or “operatively connected” refers to a first element (e.g., mechanism) that is coupled (e.g., connected) to a second element, to allow the intended operation of the second and/or first element. The coupling may comprise physical or non-physical coupling (e.g., communicative coupling). The non-physical coupling may comprise signal-induced coupling (e.g., wireless coupling). Coupled can include physical coupling (e.g., physically connected), or non-physical coupling (e.g., via wireless communication). Operatively coupled may comprise communicatively coupled.

An element (e.g., mechanism) that is “configured to” perform a function includes a structural feature that causes the element to perform this function. A structural feature may include an electrical feature, such as a circuitry or a circuit element. A structural feature may include an actuator. A structural feature may include a circuitry (e.g., comprising electrical or optical circuitry). Electrical circuitry may comprise one or more wires. Optical circuitry may comprise at least one optical element (e.g., beam splitter, mirror, lens and/or optical fiber). A structural feature may include a mechanical feature. A mechanical feature may comprise a latch, a spring, a closure, a hinge, a chassis, a support, a fastener, or a cantilever, and so forth. Performing the function may comprise utilizing a logical feature. A logical feature may include programming instructions. Programming instructions may be executable by at least one processor. Programming instructions may be stored or encoded on a medium accessible by one or more processors. Additionally, in the following description, the phrases “operable to,” “adapted to,” “configured to,” “designed to,” “programmed to,” or “capable of” may be used interchangeably where appropriate.

In some embodiments, an enclosure comprises an area defined by at least one structure. The at least one structure may comprise at least one wall. An enclosure may comprise and/or enclose one or more sub-enclosures. The at least one wall may comprise metal (e.g., steel), clay, stone, plastic, glass, plaster (e.g., gypsum), polymer (e.g., polyurethane, styrene, or vinyl), asbestos, fiber-glass, concrete (e.g., reinforced concrete), wood, paper, or a ceramic. The at least one wall may comprise wire, bricks, blocks (e.g., cinder blocks), tile, drywall, or frame (e.g., steel frame).

In some embodiments, the enclosure comprises one or more openings. The one or more openings may be reversibly closable. The one or more openings may be permanently open. A fundamental length scale of the one or more openings may be smaller relative to the fundamental length scale of the wall(s) that define the enclosure. A fundamental length scale may comprise a diameter of a bounding circle, a length, a width, or a height. A surface of the one or more openings may be smaller relative to the surface the wall(s) that define the enclosure. The opening surface may be a percentage of the total surface of the wall(s). For example, the opening surface can measure at most about 30%, 20%, 10%, 5%, or 1% of the walls(s). The wall(s) may comprise a floor, a ceiling, or a side wall. The closable opening may be closed by at least one window or door. The enclosure may be at least a portion of a facility. The facility may comprise a building. The enclosure may comprise at least a portion of a building. The building may be a private building and/or a commercial building. The building may comprise one or more floors. The building (e.g., floor thereof) may include at least one of: a room, hall, foyer, attic, basement, balcony (e.g., inner or outer balcony), stairwell, corridor, elevator shaft, façade, mezzanine, penthouse, garage, porch (e.g., enclosed porch), terrace (e.g., enclosed terrace), cafeteria, and/or Duct. The building may comprise a family home. The building may be an apartment building (e.g., multi residential building) or a single family home. A facility may comprise one or more buildings. In some embodiments, an enclosure may be stationary and/or movable (e.g., a train, an airplane, a ship, a vehicle (e.g., a car), or a rocket). In some embodiments, the facility may be stationary and/or movable (e.g., a train, a plane, a ship, a vehicle (e.g., a car), or a rocket). The facility may comprise a factory, a medical facility, a financial institution (e.g., a bank), in a hospitality institution (e.g., hotel), a shopping center, a restaurant, a distribution center, an educational facility (e.g., school, college or university), an office building, a mass transit station (e.g., train station, or an airport), or a governmental building. The facility can be a commercial and/or a residential building such as an apartment complex or a single family home.

In some embodiments, the enclosure encloses an atmosphere. The atmosphere may comprise one or more gases. The gases may include inert gases (e.g., comprising argon or nitrogen) and/or non-inert gases (e.g., comprising oxygen or carbon dioxide). The enclosure atmosphere may resemble an atmosphere external to the enclosure (e.g., ambient atmosphere) in at least one external atmosphere characteristic that includes: temperature, relative gas content, gas type (e.g., humidity, and/or oxygen level), debris (e.g., dust and/or pollen), and/or gas velocity. The enclosure atmosphere may be different from the atmosphere external to the enclosure in at least one external atmosphere characteristic that includes: temperature, relative gas content, gas type (e.g., humidity, and/or oxygen level), debris (e.g., dust and/or pollen), and/or gas velocity. For example, the enclosure atmosphere may be less humid (e.g., drier) than the external (e.g., ambient) atmosphere. For example, the enclosure atmosphere may contain the same (e.g., or a substantially similar) oxygen-to-nitrogen ratio as the atmosphere external to the enclosure. The velocity of the gas in the enclosure may be (e.g., substantially) similar throughout the enclosure. The velocity of the gas in the enclosure may be different in different portions of the enclosure (e.g., by flowing gas through to a vent that is coupled with the enclosure).

Certain disclosed embodiments provide a network infrastructure in the enclosure (e.g., a facility such as a building). The network infrastructure is available for various purposes such as for providing communication and/or power services. The communication services may comprise high bandwidth (e.g., wireless and/or wired) communications services. The communication services can be to occupants of a facility and/or users outside the facility (e.g., building). The network infrastructure may work in concert with, or as a partial replacement of, the infrastructure of one or more cellular carriers. The network infrastructure can be provided in a facility that includes electrically switchable windows. Examples of components of the network infrastructure include a high speed backhaul. The network infrastructure may include at least one cable, switch, physical antenna, transceivers, sensor, transmitter, receiver, radio, processor and/or controller (that may comprise a processor). The network infrastructure may be operatively coupled to, and/or include, a wireless network. The network infrastructure may comprise wiring. One or more sensors can be deployed (e.g., installed) in an environment as part of installing the network and/or after installing the network. The network may be a local network. The network may comprise a cable configured to transmit power and communication in a single cable. The communication can be one or more types of communication. The communication can comprise cellular communication abiding by at least a second generation (2G), third generation (3G), fourth generation (4G) or fifth generation (5G) cellular communication protocol. The communication may comprise media communication facilitating stills, music, or moving picture streams (e.g., movies or videos). The communication may comprise data communication (e.g., sensor data). The communication may comprise control communication, e.g., to control the one or more nodes operatively coupled to the networks. The network may comprise a first (e.g., cabling) network installed in the facility. The network may comprise a (e.g., cabling) network installed in an envelope of the facility (e.g., such as in an envelope of an enclosure of the facility. For example, in an envelope of a building included in the facility).

In some embodiments, macro cells are used to provide cellular communication signals to a facility. For example, a macro cell may receive signals from, or transmit signals to, a service provider. The service provider may provide access to a cellular communication core network (e.g., a 4G core network, a 5G core network, or the like). In some embodiments, the core network is a telecommunication network's core part. The core network may offer numerous services to customers who are interconnected by the access network. In some embodiments, the core network is configured to direct cellular communication over the public-switched communication network. The access network can physically connect an end system to the immediate router (also known as the “edge router”) on a path from the end system to any other distant end system. Examples of access networks are ISP, home network, enterprise network, ADSL, mobile network, FITH, and the like. The macro cell may be communicatively coupled with a router (e.g., a headend router) that rotes signals to Radio Access Units (RAUs) of a facility. For example, the router may capture downstream signals from the macro cell and route the downstream signals to one or more RAUs. The one or more RAUs may cause one or more antennas to transmit RF signals corresponding to the downstream signals. As another example, the router may capture upstream signals from one or more RAUs associated with the facility. The router may transmit the upstream signals to the macro cell. A macro cell may have various disadvantages. For example, to provide a strong signal with a far-reaching range, a macro cell may require an elevated location (e.g., on top of a tower, a hill, a building, or any other elevated location). A macro cell may heat up and may be expensive to cool. A macro cell may require dedicated hardware. A macro cell may provide a fixed coverage area for regions of a facility regardless of facility usage. Routing cables from a macro cell to a facility may be expensive as the cabling range may be extensive. The routing may require cabling configured for fast signal communication such as optical cables, that may contribute to the expense.

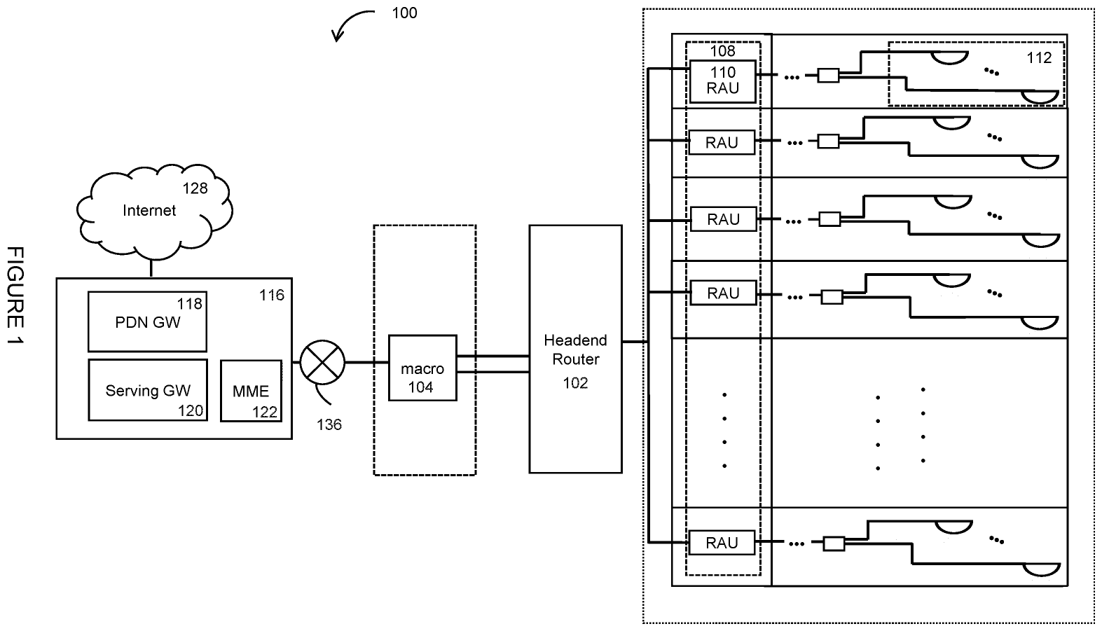

FIG. 1 shows an example a schematic diagram 100 of an example of a system for routing signals. In the example shown in FIG. 1, a headend router 102 routes signals between a macro cell 104 and RAUs 108. Each RAU of RAUs 108 is communicatively coupled to one or more antennas. For example, RAU 110 is communicatively coupled to antennas 112. Each RAU may be associated with a coverage area (e.g., a part of, or an entire, floor of a building). Macro cell 104 is communicatively coupled to a 4G network 116. 4G network 116 includes a Packet Data Network (PDN) Gateway (GW) 118, a serving GW 120, and a mobility management entity (MME) 122. 4G network 116 provides a connection between macro cell 104 and Internet 128. PDN GW 118 acts as an interface between the 4G core network and other packet data networks, such as Internet 128 and/or Session Initiation Protocol (SIP)-based IP Multimedia Subsystem (IMS) networks. Serving GW 120 may perform various functions, such as (i) routing and forwarding user plane data packets, (ii) serving as a mobility anchor point during handovers between the 4G core network and other core networks (e.g., a 2G network, a 3G network, and/or other networks) in the user plane, (iii) buffering downlink data packets for UEs in an idle mode, and/or (iv) any combination thereof. MME 122 may perform various functions, such as (I) selecting PDN gateways and/or serving GWs, (II) authenticating a user (e.g., by interacting with a Home Subscriber Server), (III) paging and tagging UEs in idle mode, (IV) providing control plane mobility between the 4G core network and other core networks (e.g., a 2G network, a 3G network, and/or other networks), and/or (V) any combination thereof. Switch 136 connects network 116 to macro cell 104. Switch 136 operatively couples to network 116 to a network of the facility.

In some embodiments, at least one small cell controller (e.g., as part of a control system) dynamically adjusts the coverage areas of one or more small cell devices in a facility (e.g., comprising a building). The coverage area of at least one (e.g., each) small cell device may be changed to different locations and coverage ranges throughout the facility, e.g., based at least in part on actual and/or predicted usage needs. For example, a small cell device that currently serves a particular coverage area on the first floor of a building may be reassigned to serve a coverage area on the sixth floor of the building. For example, a small cell device that currently serves a first building of a facility may be reassigned to serve a coverage area on a second building of the facility. A plurality of coverage areas currently served by a plurality of small cell devices may be reassigned to be served by a single small cell device. A single coverage area currently served by a single small cell device may be reassigned to be served by a plurality of small cell devices (e.g., having a contacting or an overlapping range). In some embodiments, the ability of the small cell controller(s) to dynamically adjust the coverage areas of a small cell device promotes efficient use of the capacity of the small cell device through flexible allocation.

In some embodiments, the small cell controller(s) adjusts coverage areas of one or more small cell devices. The small cell controller(s) may adjust the coverage areas of one or more small cell devices by changing the routing of signals between one or more small cell devices and one or more Radio Access Units (RAUs) associated with the facility. The RAUs may be geographically dispersed in the facility (e.g., having a plurality of enclosures). An RAU may be communicatively coupled to one or more antennas. The one or more antennas may collectively function as a distributed antenna system (DAS). The one or more antennas may correspond to a particular coverage area. For example, an RAU may serve a dedicated region of a facility. For example, a particular RAU may be placed on a particular floor of a building, in a particular wing of a building, in a particular building of the facility, or any combination thereof. By changing the routing of signals between small cell devices and RAUs, the small cell controller can enlarge, reduce, re-locate, and/or otherwise change the coverage area of at least one (e.g., each) small cell device, thereby modifying how small cell capacity is deployed throughout the facility.

In some embodiments, signals are routed between one or more small cell devices and one or more RAUs. The signals being routed between a small cell device and an RAU comprise upstream and downstream cellular communication signals along the path between a User Equipment device (UE) and a network, such as a cellular communication core network (e.g., a 5G core network). The network may be configured to transmit and/or receive data according to at least a second generation (2G), third generation (3G), fourth generation (4G), or fifth generation (5G) cellular communication protocol. The network may provide a connection to the Internet. Communications between the network and a UE may be bidirectional or monodirectional. For example, communications between the network and a UE may be bidirectional, including downstream data (e.g., from the core network to a UE) and upstream data (e.g., from a UE to the core network). Along this path, the signals routed between small cell devices(s) and the RAU(s) may be analog signals or digital signals. In instances in which the signals comprise analog signals, the signals may comprise baseband signals or intermediate frequency (IF) signals. For example, in the downstream direction, a small cell device may modulate downstream data (e.g., bits representing network traffic, audio signals, and/or other data) from the network and modulate the downstream data into a downstream baseband or IF signal, which is routed to an RAU. The RAU may upconvert the downstream baseband or IF signal to a radio frequency (RF) frequency for transmission to UEs within a particular coverage area. In the upstream direction, a UE may transmit an RF frequency signal that is received by an RAU. The RAU may down-convert the RF signal to an upstream baseband or IF signal, which may be routed to a small cell device. The small cell device may demodulate the upstream baseband, or IF signal, into upstream data (e.g., bits representing network traffic, audio signals, and/or other data), and send the upstream data to the core network. In instances in which the signals routed between small cell device(s) and the RAU(s) are digital signals, the RAU(s) may receive digital signals (e.g., digitized representations of downstream signals from a cellular core communication core network). The RAU(s) may up-sample and/or up-convert the digital signals to an RF frequency signal. An RAU may then cause one or more antennas (e.g., a DAS) to transmit the RF frequency signal. In the downstream direction, the RAU may down-convert a received RF signal. The RAU may down-sample the down-converted RF signal. The down-converted RF signal may be transmitted to one or more small cell devices as a digitized representation of the received RF signal.

In some embodiments, the small cell device(s) and the RAU(s) are operatively coupled to a router. The router (e.g., a headend router) may provide a physical switching capability for routing signals between one or more small cell devices and one or more RAUs associated with the facility. The physical switching capability may be provided according to a programmable routing configuration. The programmable routing configuration may be dynamically altered, e.g., in real time. The programmable routing configuration may be pre-programmed. A small cell controller may provide the routing configuration and, e.g., thereby control the router. The small cell controller may determine the configuration based at least in part on input data. The input data may be received though the network. For example, the input data may be received from a control system, from sensor(s) and/or from server associated with a facility. The control system may include, or be separate from, the small cell controller. In some embodiments, a control system configured to control the facility includes the small cell controller.

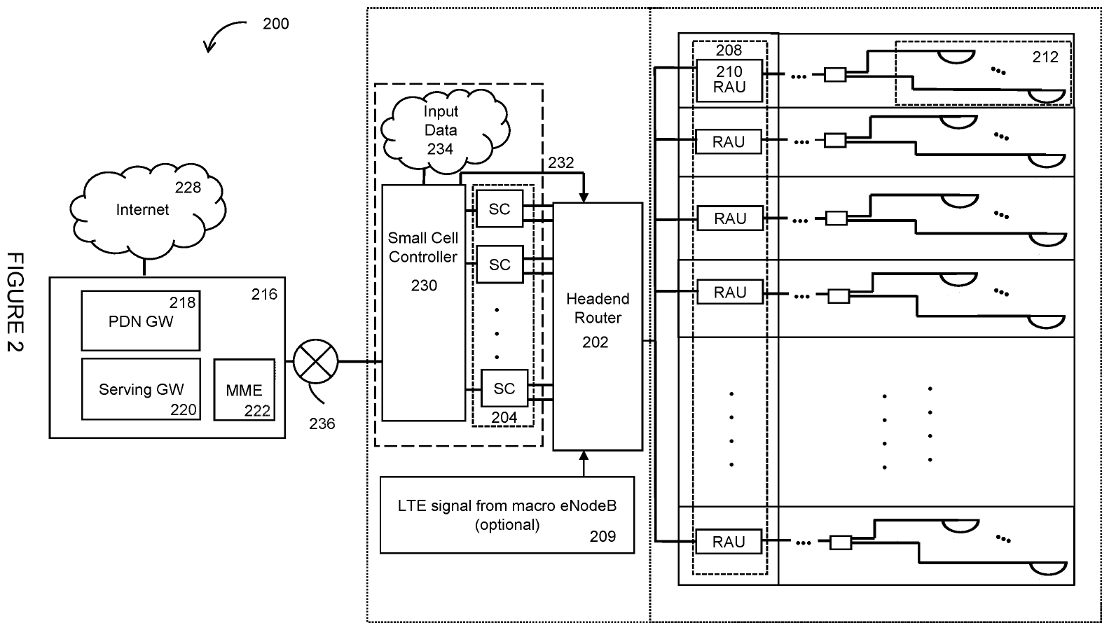

FIG. 2 shows an example of a schematic diagram 200 of an example of a system for routing signals. In the example shown in FIG. 2, a headend router 202 routes signals between small cell devices 204 and RAUs 208. Headend router 202 may optionally receive an LTE signal 209 from a macro eNodeB cell. Each RAU of RAUs 208 is communicatively coupled to one or more antennas (e.g., a DAS). For example, RAU 210 is communicatively coupled to antennas 212. Each RAU may be associated with a coverage area (e.g., a part of or an entire floor of a building). Small cell devices 204 are communicatively coupled to a 4G network 216. 4G network 216 includes a Packet Data Network (PDN) Gateway (GW) 218, a serving GW 220, and a mobility management entity (MME) 222. 4G network 216 provides a connection between small cell devices 204 and Internet 228. PDN GW 218 acts as an interface between the 4G core network and other packet data networks, such as Internet 228 and/or Session Initiation Protocol (SIP)-based IP Multimedia Subsystem (IMS) networks. Serving GW 220 may perform various functions, such as (i) routing and/or forwarding user plane data packets, (ii) serving as a mobility anchor point during handovers between the 4G core network and other core networks (e.g., a 2G network, a 3G network, and/or other networks) in the user plane, (iii) buffering downlink data packets for UEs in an idle mode, or (iv) any combination thereof. MME 222 may perform various functions, such as (1) selecting PDN gateways and/or serving GWs, (2) authenticating a user (e.g., by interacting with a Home Subscriber Server), (3) paging and/or tagging UEs in idle mode, (4) providing control plane mobility between the 4G core network and other core networks (e.g., a 2G network, a 3G network, and/or other networks), or (5) any combination thereof. A small cell controller 230 determines a configuration for headend router 202 to route signals between small cell devices 204 and RAUs 208. The small cell controller can be part of control system, e.g., as disclosed herein. Small cell controller 230 provides a control signal 232 to headend router 202. The control signal 232 may indicate the configuration for headend router 202 to route signals between small cell devices 204 and RAUs 208. Small cell controller 230 determines the configuration based at least in part on input data 234. Input data 234 may be obtained from one or more servers or control systems associated with the building. Switch 236 connects network 216 to small cell controller 230. Switch 236 operatively couples to network 216 to a network of the facility. Operatively coupling may comprise communication and/or power coupling.

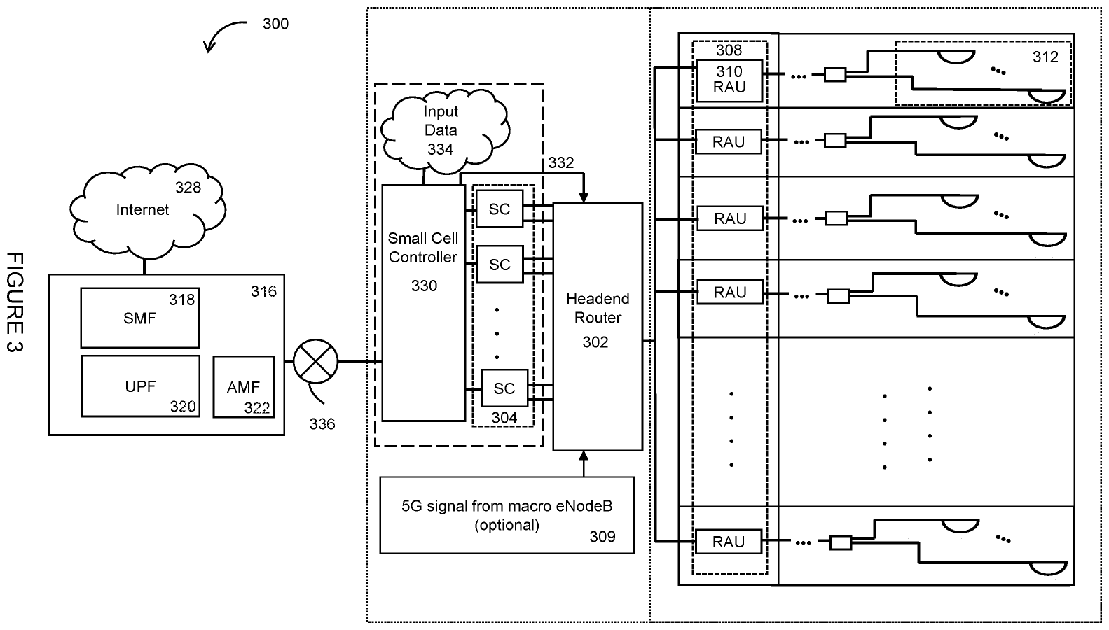

FIG. 3 shows another example of a schematic diagram 300 of an example of a system for routing signals. In the example shown in FIG. 3, a headend router 302 routes signals between small cell devices 304 and RAUs 308. Headend router 302 may optionally receive a 5G signal 309 from a macro gNodeB cell. Each RAU of RAUs 308 is communicatively coupled to one or more antennas (e.g., a DAS). For example, RAU 310 is communicatively coupled to antennas 312. Each RAU may be associated with a coverage area (e.g., a part of or an entire floor of a building). Small cell devices 304 are communicatively coupled to a 5G network 316. 5G network 316 includes a Session Management Function (SMF) 318, a User Plane Function (UPF) 320, and an Access and Mobility Function (AMF) 322. 5G network 316 provides a connection between small cell devices 304 and Internet 328. SMF 318 may be responsible for interacting a decoupled data plane, creating, updating, and/or removing Protocol Data Unit (PDU) sessions, managing session context with UPF 320, allocating IP addresses of User Equipment (UE) devices, any combination thereof, or other functions. UPF 320 may be responsible for (1) packet routing and/or forwarding, (2) packet buffering for UEs in an idle mode, (3) any combination thereof, or (4) other functions. AMF 322 may be responsible for handling connection and/or mobility management tasks. A small cell controller 330 determines a configuration for headend router 302 to route signals between small cell devices 304 and RAUs 308. Small cell controller 330 provides a control signal 332 to headend router 302. The control signal 332 may indicate the configuration for headend router 302 to route signals between small cell devices 304 and RAUs 308. Small cell controller 330 determines the configuration based at least in part on input data 334. Input data 334 may be obtained from one or more servers or control systems associated with the building. Switch 336 connects network 316 to small cell controller 330. Switch 336 operatively couples to network 316 to a network of the facility (e.g., a local network of a building).

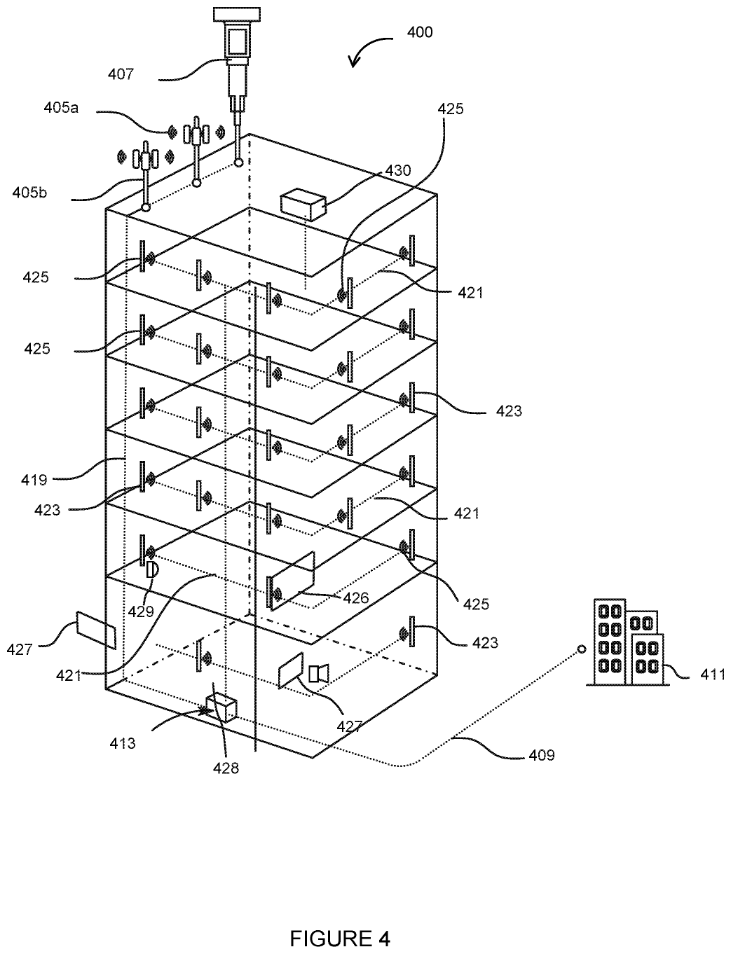

In certain embodiments, a building network infrastructure has a vertical data plane (between building floors) and a horizontal data plane (all within a single floor or multiple (e.g., contiguous) floors). In some cases, the horizontal and vertical data planes have at least one (e.g., all) data carrying capabilities and/or components that is (e.g., substantially) the same or similar data. In other cases, these two data planes have at least one (e.g., all) different data carrying capabilities and/or components. For example, the vertical data plane may contain one or more components for fast data transmission rates and/or bandwidths. In one example, the vertical data plane contains components that support at least about 10 Gigabit/second (Gbit/s) or faster (e.g., Ethernet) data transmissions (e.g., using a first type of wiring (e.g., UTP wires and/or fiber optic cables)), while the horizontal data plane contains components that support at most about 8 Gbit/s, 5 Gbit/s, or 1 Gbit/s (e.g., Ethernet) data transmissions, e.g., via a second type of wiring (e.g., coaxial cable). In some cases, the horizontal data plane supports data transmission via G.hn or Multimedia over Coax Alliance (MoCA) standards (e.g., MoCA 2.5 or MoCA 3.0). In some embodiments, G.hn is a specification for local (e.g., facility such as home) networking. The G.hn specification may facilitate operation over four types of wires comprising telephone wiring, coaxial cables, power lines, or plastic optical fiber. A G.hn semiconductor device may be able to network over any of the supported wire types in the facility (e.g., lowering installation and/or deployment costs). In some embodiments, MoCA publishes standard specifications for networking (e.g., Ethernet link) over coaxial cables. In certain embodiments, connections between floors on the vertical data plane employ control panels with high speed (e.g., Ethernet) switches that pair communication between the horizontal and vertical data planes and/or between the different types of wiring. These control panels can communicate with (e.g., IP) addressable nodes (e.g., devices) on a given floor via the communication (e.g., G.hn or MoCA) interface and associated wiring (e.g., coaxial cables, twisted cables, and/or optical cables) on the horizontal data plane. Horizontal and vertical data planes in a single building structure are depicted in FIG. 4.

In some embodiments, data transmission (and in some embodiments voice services), may be provided in a building via wireless and/or wired communications. The communication may be provided to and/or from occupants of the building. The data transmission and/or voice services may become difficult due at least in part to attenuation by building structures (such as walls, floors, ceilings, and/or windows) in third, fourth, or fifth generation (3G, 4G, or 5G) cellular communication. Relative to 3G and 4G communication, the attenuation becomes more severe with higher frequency protocols such as that of 5G. To address this challenge, a building can be outfitted with components that serve as gateways, or ports, for cellular signals. Such gateways may couple to infrastructure in the interior of the building that provide wireless service (e.g., via interior antennas and/or other infrastructure implementing Wi-Fi, small cell service (e.g., via microcell or femtocell devices), CBRS, etc.). The gateways, or points of entry, for such services may include high speed cable (e.g., underground) from a central office of a carrier and/or a wireless signal received at an antenna strategically located on the building exterior (e.g., a donor antenna and/or sky sensor on the building's roof). The high speed cable to the building can be referred to as “backhaul.”

FIG. 4 shows an example of a building with device ensembles (e.g., assemblies). As points of connection, the building can include multiple rooftop donor antennas 405a, 405b as well as a sky sensor 407 for sending electromagnetic radiation (e.g., infrared, ultraviolet, and/or visible light). These wireless signals may allow a building services network to wirelessly interface with one or more communications service provider systems. The building has a control panel 413 for connecting to a provider's central office 411 via a physical line 409 (e.g., an optical fiber such as a single mode optical fiber). The control panel 413 (e.g., including a controller such as part of a control system) may include hardware and/or software configured to provide functions of, for example, a signal source carrier headend, a fiber distribution headend, and/or a (e.g., bi-directional) amplifier or repeater. The rooftop donor antennas 405a and 405b allow building occupants and/or devices to access a wireless system communications service of a (e.g., 3^{rd} party) provider. the antenna and/or controller(s) may provide access to the same service provider system, a different service provider system, or some variation such as two interface elements providing access to a system of a first service provider, and a different interface element providing access to a system of a second service provider.

As shown in the example of FIG. 4, a vertical data plane may include a (e.g., high capacity, or high-speed) data carrying line 419 such as (e.g., single mode) optical fiber or UTP copper lines (of sufficient gauge). In some embodiments, at least one control panel could be provided on at least part of the floors of the building (e.g., on each floor). In some embodiments, one (e.g., high capacity) communication line can directly connect a control panel in the top floor with (e.g., main) control panel 413 in the bottom floor (or in the basement floor). Note that control panel 413 directly connects to rooftop antennas 405a, 405b and/or sky sensor 407, while control panel 413 also directly connects to the (e.g., 3^{rd} party) service provider central office 411.

FIG. 4 shows an example of a horizontal data plane that may include one or more of the control panels and data carrying wiring (e.g., lines), which include trunk lines 421. In certain embodiments, the trunk lines are made from coaxial cable. The trunk lines may comprise any wiring disclosed herein. The control panels may be configured to provide data on the trunk lines 421 via a data communication protocol (such as MoCA and/or G.hn). The data communication protocol may comprise (i) a next generation home networking protocol (abbreviated herein as “G.hn” protocol), (ii) communications technology that transmits digital information over power lines that traditionally used to (e.g., only) deliver electrical power, or (iii) hardware devices designed for communication and transfer of data (e.g., Ethernet, USB and/or Wi-Fi) through electrical wiring of a building. The data transfer protocols may facilitate data transmission rates of at least 1 Gigabits per second (Gbit/s), 2 Gbit/s, 3 Gbit/s, 4 Gbit/s, or 5 Gbit/s. The data transfer protocol may operate over telephone wiring, coaxial cables, power lines, and/or (e.g., plastic) optical fiber. The data transfer protocol may be facilitated using a chip (e.g., comprising a semiconductor device).

Each horizontal data plane may provide high speed network access to one or more device ensembles 423 (e.g., a set of one or more devices in a housing comprising an assembly of devices) and/or antennas 425, some or all of which are optionally integrated with device ensembles 423. Antennas 425 (and associated radios, not shown) may be configured to provide wireless access by any of various protocols, including, e.g., cellular (e.g., one or more frequency bands at or proximate 28 GHz), Wi-Fi (e.g., one or more frequency bands at 2.4, 5, and 60 GHz), CBRS, and the like. Drop lines may connect device ensembles 423 to trunk lines 421. In some embodiments, a horizontal data plane is deployed on a floor of a building. The devices in the device ensemble may comprise a sensor, emitter, or antenna. The device ensemble may comprise a circuitry. The devices in the device ensemble may be operatively coupled to the circuitry. One or more donor antennas such as 405a, or 405b may connect to the control panel 413 via high speed lines (e.g., single mode optical fiber or copper). In the depicted example, the control panel 413 may be located in a lower floor of the building. The connection to the donor antenna(s) 405a, 405b may be via one or more vRAN radios and wiring (e.g., coaxial cable).

The communications service provider central office 411 connects to ground floor control panel 413 via a high speed line 409 (e.g., an optical fiber serving as part of a backhaul). This entry point of the service provider to the building is sometimes referred to as a Main Point of Entry (MPOE), and it may be configured to permit the building to distribute both voice and data traffic.

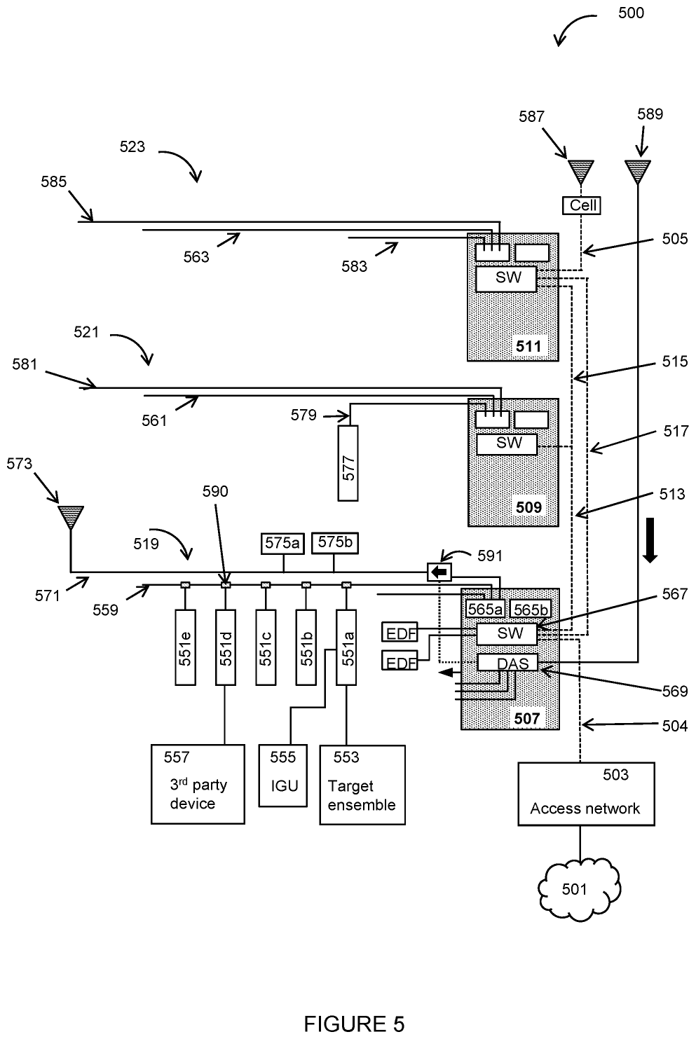

FIG. 5 presents an embodiment of a communications network 200 for an enclosure such as a building. The example shown in FIG. 5 depicts links that may comprise one or more cables (e.g., coaxial cables or twisted cables). The link may be a communication and/or electrical power line. The cables may be a cable bundle. The cable bundle can transmit electrical power and/or communication. The cable (e.g., coaxial cable) can transmit electrical power and/or communication. In the depicted embodiment, network 500 includes a vertically oriented network portion (including a vertical communication line 505) that connects network targets (e.g., components) on multiple floors of the enclosure (e.g., of the facility). In the example shown in FIG. 5, a vertical data plane comprises a first control panel 507 (e.g., comprising a floor controller) on a first floor, a second control panel 509 (e.g., comprising a floor controller) on a second floor, and a third control panel 511 (e.g., comprising a floor controller) on third floor. Physical communications and/or electrical power link 513 connects control panels 507 and 509. Physical communications and/or electrical power link 515 connects control panels 509 and 511. Physical communications and/or electrical power link 517 connects control panels 507 and 511. As illustrated, control panels 507, 509, and 511 along with physical communications and/or power links 513, 515, and 517 form a loop. The loop may provide redundancy in the network. As an example, physical communications and/or electrical power link 517 provides redundancy on the vertical plane if one of the other physical communications and/or electrical power links (e.g., link 513 or 515) should fail. Communications links 513, 515, and 517 may comprise electrical wires and/or optical fibers. Communications links 513, 515, and 517 may comprise a coaxial wire.

In the example shown in FIG. 5, control panel 507 is communicatively coupled (e.g., connected) to an external network 501 (e.g., external to the building and/or in the cloud) via an access network 503. Control panel 507 is communicatively coupled (e.g., connected) to access network 503 by a physical communications and/or electrical power link 504, which may comprise an optical fiber and/or an electrical wire. Control panel 507 is connected to an antenna 589 that is external to the building. The antennal 589 may be a receiving antenna (e.g., a donor antenna).

FIG. 5 shows an example of control panel 507 that is operatively coupled (e.g., connected) to a first horizontal network portion that is horizontal data plane 519. Control panel 509 is operatively coupled (e.g., connected) to a second horizontal network portion that is horizontal data plane 521. Control panel 511 is operatively coupled (e.g., connected) to a third horizontal network portion that is horizontal data plane 523. The horizontal data planes 519, 521, and 523 include multiple network targets (e.g., components and/or devices such as a device ensemble). The network targets (e.g., components) can include client nodes. The client nodes can be located on respective floors of the building.

In the example shown in FIG. 5, horizontal data plane 519 includes network adaptors 551a-551e. The network adapter (e.g., 551a) is coupled to communication and/or electrical power line (e.g., trunk line) 559 via a distribution junction (e.g., 590). Network adaptor 551a is connected to a collection of targets (e.g., including a transceiver, sensor and/or emitter) 553 and connected to an IGU 555 that may be an optically switchable window. Network adaptor 551a is configured to provide electrical power and data to the collection of targets 553 (also referred to herein as “target ensemble”), e.g., using a Power over Ethernet protocol (PoE). Network adaptor 551d is connected to at least one third-party device 557 such as a computation device. Network adaptor 551d is configured to provide network connectivity to third party device 557. Providing the network connectivity may comprise logic implementing a link layer discovery protocol (LLDP) that supports, e.g., PoE. A target may comprise a device. The deice may comprise a transceiver, a sensor, an emitter, a display, a smart window, a processor, a controller (e.g., a local controller such as a microcontroller), a memory, an antenna, or a communication hub.

In the example shown in FIG. 5, control panel 507 is connected to network adaptors 551a-551e by a link (e.g., coaxial cable) 559. The connection can be by a coaxial or other type of (e.g., electrical and/or optical) cable, e.g., as disclosed herein. Control panel 509 is connected to client nodes on horizontal data plane 521 by a link (e.g., coaxial cable) 561. Control panel 511 is connected to client nodes on horizontal data plane 523 by a link (e.g., coaxial cable) 563. In the example shown in FIG. 5, control panel 507 comprises two head ends 565a and 565b, a switch 567 (abbreviated herein as “SW”) and a distributed antenna system (abbreviated herein as “DAS”) 569. The Switch is operatively coupled (e.g., connected to two edge distribution frame devices (abbreviated herein as “EDFs”). Head end 565a is connected to multiple links (e.g., coaxial cables), including link (e.g., coaxial cable) 559. While not shown, head end 565b is connected to at least one link (e.g., coaxial cable). Switch 567 is connected to (e.g., communication and/or electrical power) links 504, 513, and 517. The connection may be via optical and/or electrical cable(s). DAS 569 is configured to control and/or communicate with one or more antennas, including antenna 573, on horizontal data plane 519. The antenna may be an internal building antenna (e.g., 573) and/or or an external (e.g., donor) antenna (e.g., 589). In the example shown in FIG. 5, an electrical power and/or communications link (e.g., cable) 571 connects antenna 573 to control panel 507. Link 571 is also connected to a directional coupler (e.g., configured for directional data communication protocol such as MoCA or G.hn) Other client nodes 575a and 575b are connected to control panel 507 via electrical power and/or communications link (e.g., cable) 571. Head ends 565a and 565b are configured to send and/or receive data encoded in accordance with one or more protocols which comprise (i) a next generation home networking protocol (abbreviated herein as “G.hn” protocol), (ii) communications technology that transmits digital information over electrical power lines that traditionally used to (e.g., only) deliver electrical power, or (iii) hardware devices designed for communication and transfer of data (e.g., Ethernet, USB and Wi-Fi) through electrical wiring of a building. The data transfer protocols may facilitate data transmission rates of at least 1 Gigabits per second (Gbit/s), 2 Gbit/s, 3 Gbit/s, 4 Gbit/s, or 5 Gbit/s. The data transfer protocol may operate over telephone wiring, coaxial cables, electrical power lines, and/or (e.g., plastic) optical fiber. The data transfer protocol may be facilitated using a chip (e.g., comprising a semiconductor device). In the example shown in FIG. 5, Horizontal data plane 521 includes a network adaptor 577 connected to control panel 509 by a link (e.g., coaxial cable) 579. Horizontal data plane 521 includes a physical power (e.g., 48V DC) and/or (electrical power and/or communications) line 581 for connecting one or more antennas (not shown) to control panel 509. Horizontal data plane 523 includes, in addition to link (e.g., coaxial cable) 563, a second link (e.g., coaxial cable) 583 for connecting to one or more network adaptors or other client nodes (not shown) to control panel 511. Horizontal data plane 523 includes a physical (e.g., electrical power and/or communications) line 585 for connecting one or more antennas (not shown) to control panel 511. Control panel 511 is also connected to a (e.g., cellular) antenna 587.

In some embodiments, a router (e.g., a headend router) routes signals between one or more small cell devices associated with a facility and one or more RAUs associated with the facility. A router may be configured to route signals between one small cell device and one RAU, between two or more small cell devices and one RAU, and/or between two or more RAUs and one small cell device. The router may be configured to dynamically change routing of signals, based on, for example, a configuration received by a small cell controller. Dynamic change in routing may be implemented via a signal manipulator of a router. In some embodiments, the signal manipulator may be programmable. For example, in some embodiments, the signal manipulator may be programmed to split and/or combine signals from one or more small cell devices and/or one or more RAUs according to a configuration, e.g., received from a small cell controller.

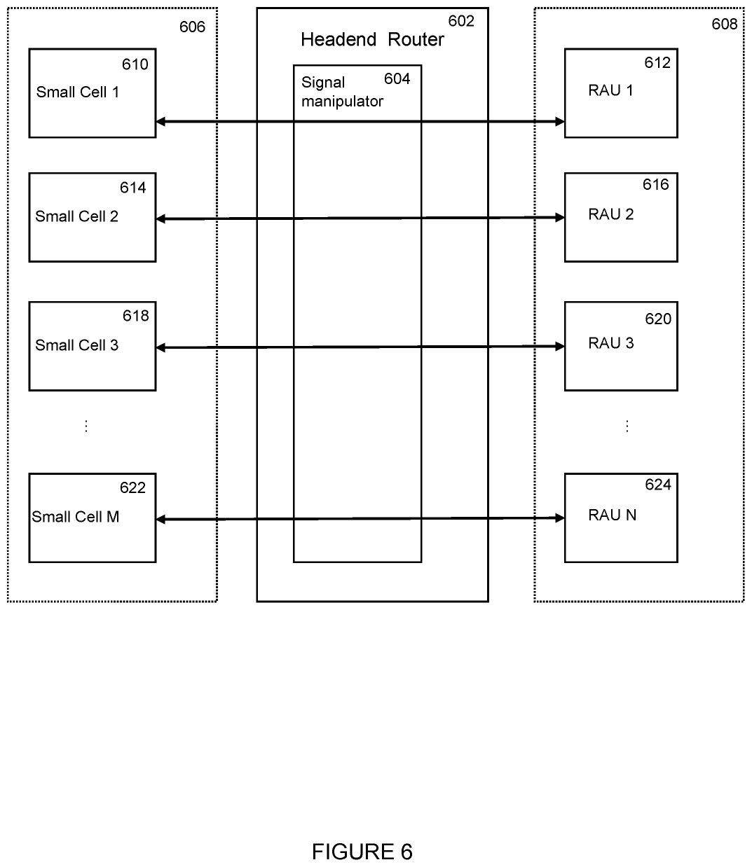

FIG. 6 shows an example of a schematic diagram for routing signals. In the example shown in FIG. 6, a headend router 602 routes signals between small cell devices 606 and RAUs 608. Headend router 602 comprises a signal manipulator 604. Signal manipulator 604 may be programmable. For example, signal manipulator 604 may be a programmable splitter/combiner that splits and/or combines signals received from or transmitted to small cell devices 606 and/or received from or transmitted to RAUs 608. In the example shown in FIG. 6, headend router 602 routes signals between small cell devices 606 and RAUs 608 in a one-to-one configuration. For example, headend router 602 routes signals between small cell device 610 and RAU 612, between small cell device 614 and RAU 616, between small cell device 618 and RAU 620, and between small cell device 622 and RAU 624.

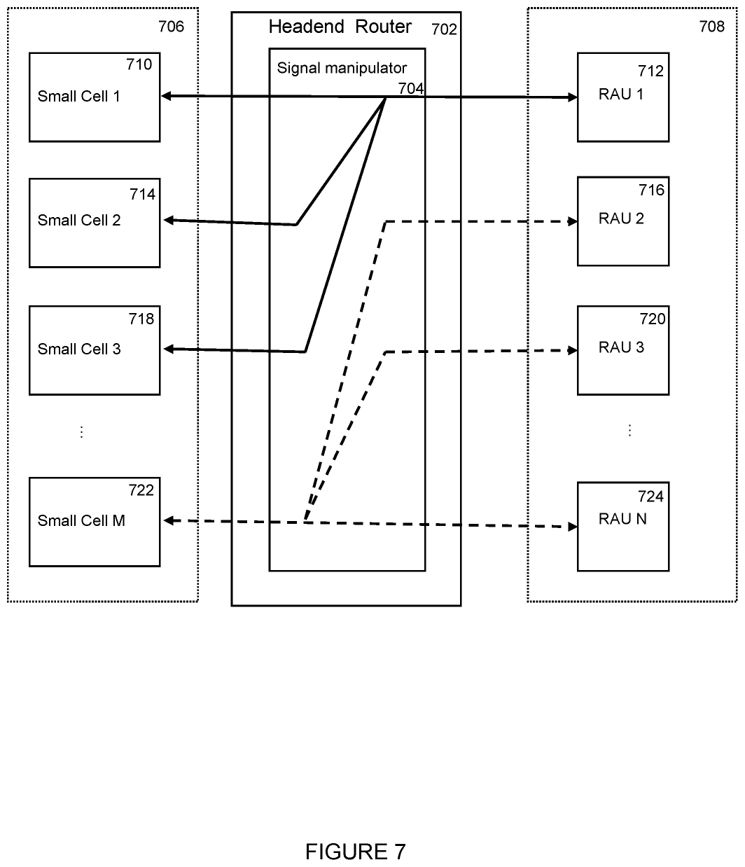

FIG. 7 shows another example of a schematic diagram for routing signals. In the example shown in FIG. 7, a headend router 702 routes signals between small cell devices 706 and RAUs 708. Headend router 702 comprises a signal manipulator 704. Signal manipulator 704 may be programmable. For example, signal manipulator 704 may be a programmable splitter-combiner that splits and/or combines signals received from or transmitted to small cell devices 706 and/or received from or transmitted to RAUs 708. In the example shown in FIG. 7, headend router 702 routes signals between small cell devices 710, 714, and 718 and RAU 712. That is, headend router 702 may route signals between a plurality of small cell devices and one RAU. The solid arrows indicate signals that are routed to and from RAU 712. In the example shown in FIG. 7, headend router 702 routes signals between small cell device 722 and RAUs 716, 720, and 724. That is, headend router 702 may route signals between one small cell device and a plurality of RAUs. The dashed arrows indicate signals that are routed to and from small cell device 722.

In some embodiments, a small cell controller transmits a configuration for routing signals between one or more small cell devices associated with a facility (e.g., a building) and one or more RAUs associated with the facility. The small cell controller may determine the configuration, e.g., based at least in part on current and/or predicted (e.g., future) usage of the small cell devices by one or more mobile devices in the facility.

In some embodiments, the headend router receives the configuration from the controller(s) (e.g., from the small cell controller). The controller can be part of the control system, e.g., as disclosed herein. The headend router may route downstream signals based at least in part on the configuration. For example, a small cell device of the one or more small cell devices may receive downstream data (e.g., bits representing network traffic, audio signals, and/or other data) from a network (e.g., a 4G network, a 5G network, or other network). The small cell device is communicatively coupled to the network. The downstream data may be for a particular UE (e.g., mobile device) in the facility. Downstream signals transmitted from one or more small cell devices to one or more RAUs may be analog signals or digital signals. In an instance in which the signals are analog signals, in response to receiving the downstream data, the small cell device may modulate the downstream data into a downstream signal (e.g., baseband or intermediate frequency (IF) signal). In an instance in which the downstream signals are digital signals, the small cell device may transmit a digitized representation of the received downstream signal. For example, the digitized representation may comprise the received downstream signal sampled at a particular sampling rate (e.g., at least about the Nyquist frequency). The small cell device may transmit the downstream signal to the headend router. The headend router may manipulate one or more downstream signals, including the downstream signal received from the small cell device. Manipulation of the downstream signals may be programmable. For example, in an instance in which the configuration indicates that downstream signals from two or more small cell devices (e.g., two, three, five, ten, or the like) including the small cell device that transmitted the downstream signal are to be routed to a single RAU, the headend router may combine downstream signals from the two or more small cell devices. In some embodiments, such as in an instance in which the downstream signals are analog signals, the headend router may combine downstream signals from the two or more small cell devices, each occupying a different frequency band, into a single broadband signal and route the broadband signal to the RAU. In some embodiments, such as in an instance in which the downstream signals are digital signals, the headend router may combine the digital signals from the two or more small cell devices and route the combined digital signals to the RAU. As another example, in an instance in which the configuration indicates that downstream signals from one small cell device are to be routed to two or more RAUs (e.g., two, three, five, ten, or the like), the headend router may split the downstream signal from the one small device into a plurality of versions of the same downstream signal and route each version to a corresponding one of the two or more RAUs.

In some embodiments, the downstream signals are be provided to the one or more RAUs via one or more cables. In some embodiments, the one or more cables may be optical cables, coaxial cables, twisted cable, and/or any combination thereof. The one or more cables may be any cable disclosed herein. The cabling may be considered part of a network of the facility (e.g., part of a local network of the facility). For example, in some embodiments, one or more optical cables may be used to carry downstream signals from the headend router to a particular floor or region of the facility. In some embodiments, one or more coaxial cables may be used to carry downstream signals within a particular floor or region of the facility to a particular RAU. In some embodiments, for example, in instances in which the downstream signal comprises analog signals, the headend router may amplify the downstream signal. For example, in some embodiments, the headend router may amplify the downstream signal according to information received from the small cell controller. Examples for cabling, network, targets (e.g., devices) and control system can be found in International Patent Application Serial No. PCT/US21/17946, filed Feb. 12, 2021; and in U.S. patent application Ser. No. 17/083,128, filed Oct. 28, 2020, each of which is incorporated herein by reference in its entirety.

In some embodiments, an RAU receives a downstream signal from the headend router. The RAU may then up-convert the downstream signal. For example, the RAU may up-convert the downstream signal to an RF frequency band associated with one or more antennas communicatively coupled to the RAU. In instances in which the downstream signal received from the headend router comprises digital signals, the RAU may up-sample the downstream signal. The RAU may then up-convert the up-sampled downstream signal. For example, the RAU may up-convert the up-sampled downstream signal to an RF frequency associated with one or more antennas communicatively coupled to the RAU. The RAU may cause the one or more antennas to transmit the up-converted downstream signal. In some embodiments, the one or more antennas may amplify the downstream signal.

In some embodiments, the headend router routes upstream signals based at least in part on the configuration. For example, an RAU receives an upstream signal from one or more antennas communicatively coupled to the RAU. The RAU may then down-convert the upstream signal. For example, in an instance in which upstream signals transmitted from the RAU to one or more small cell devices comprise analog signals, the RAU may down-convert the upstream signal to a baseband frequency or an intermediate frequency (abbreviated herein as “IF”). The RAU may transmit the down-converted upstream signal to the headend router. As another example, in an instance in which the upstream signals transmitted from the RAU to the one or more small cell devices comprise digital signals, the RAU may down-convert the upstream signal to a baseband frequency or an IF. The RAU may down-sample the down-converted upstream signal to generate a digitized representation of the upstream signal.

In some embodiments, the upstream signals are provided to the headend router from the RAU via one or more cables. In some embodiments, the one or more cables may be optical cables, coaxial cables, and/or any combination thereof. The cabling may be considered part of a network of the facility (e.g., part of a local network of the facility). For example, in some embodiments, one or more optical cables may be used to carry upstream signals from an RAU on a particular floor or in a particular region of the facility to the headend router. In some embodiments, one or more coaxial cables may be used to carry upstream signals within a particular floor or region of the facility to a particular RAU.

The headend router may manipulate one or more upstream signals, including the upstream signal received from the RAU. Manipulation of the upstream signals may be programmable. For example, in an instance in which the configuration indicates that upstream signals from two or more RAUs (e.g., two, three, five, ten, or the like) including the RAU that transmitted the upstream signal are to be routed to a single small cell device, the headend router may combine upstream signals from the two or more RAUs. In some embodiments, the headend router may combine upstream signals from the two or more RAUs to be routed to the small cell device. For example, in an instance in which the upstream signals comprise analog signals, the headend router may combine the upstream signals from the two or more RAUs to a single frequency band. As another example, in an instance in which the configuration indicates that upstream signals from one RAU are to be routed to two or more small cell devices (e.g., two, three, five, ten, or the like), the headend router may split the upstream signal from the one RAU into a plurality of upstream signals and route each upstream signal to a corresponding small cell device. For example, in an instance in which the upstream signals comprise analog signals, the headend router the plurality of upstream signals may be associated with different frequency bands.

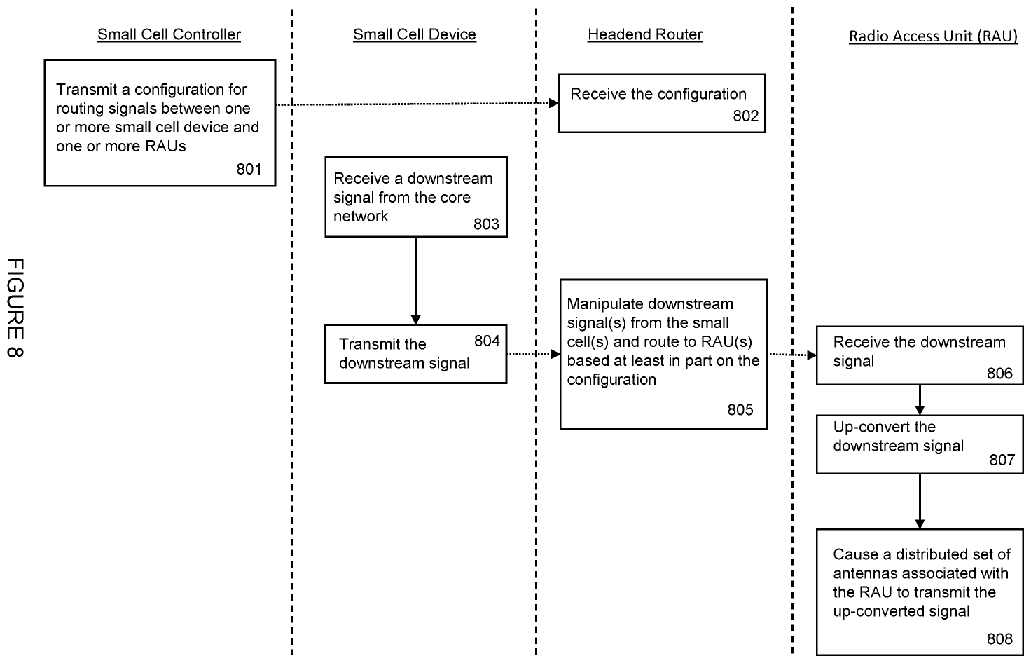

FIG. 8 shows an example of an information flow diagram for routing downstream signals between one or more small cell devices and one or more RAUs. At 801, a small cell controller transmits a configuration for routing signals between one or more small cell devices and one or more RAUs. At 802, a headend router receives the configuration. At 803, a small cell device receives downstream data from a network. The core network may be a 4G network, a 5G network, or other type of network. The network may transmit signal complying with communication protocol of at least a second (2G), third (3G), fourth (4G), or fifth (5G) generation. The network may transmit signal complying with communication protocols including two or more of: a second (2G), third (3G), fourth (4G), and a fifth (5G) generation communication protocol. At 804, the small cell device modulates the downstream data into a downstream signal and transmits the downstream signal to the headend router. At 805, the headend router manipulates the downstream signal from the small cell device and routes it to an RAU, e.g., based at least in part on the configuration. For example, the headend router may manipulate the downstream signals by combining a plurality of downstream signals (including the downstream signal transmitted by the small cell device at 804) from a plurality of small cell devices and transmitting the combined plurality of downstream signals to a single RAU. As another example, the headend router may manipulate the downstream signals by splitting a plurality of downstream signals from a single small cell device (including the small cell device that transmitted the downstream signal at 804) and transmitting the split downstream signals to a plurality of RAUs. For example, in an instance in which the downstream signals comprise analog signals, the headend router may split the plurality of downstream signals to a plurality of broadband frequencies, the broadband frequencies corresponding to different RAUs. The split downstream signals can be transmitted to a plurality of RAUs. At 806, the RAU receives the downstream signal. At 807, the RAU up-converts the downstream signal. In some embodiments, for example, in an instance in which the downstream signals received by the RAU comprise digital signals, the RAU may up-sample the downstream signal prior to up-converting the downstream signal. At 808, the RAU causes a distributed set of antennas associated with the RAU to transmit the up-converted signal.

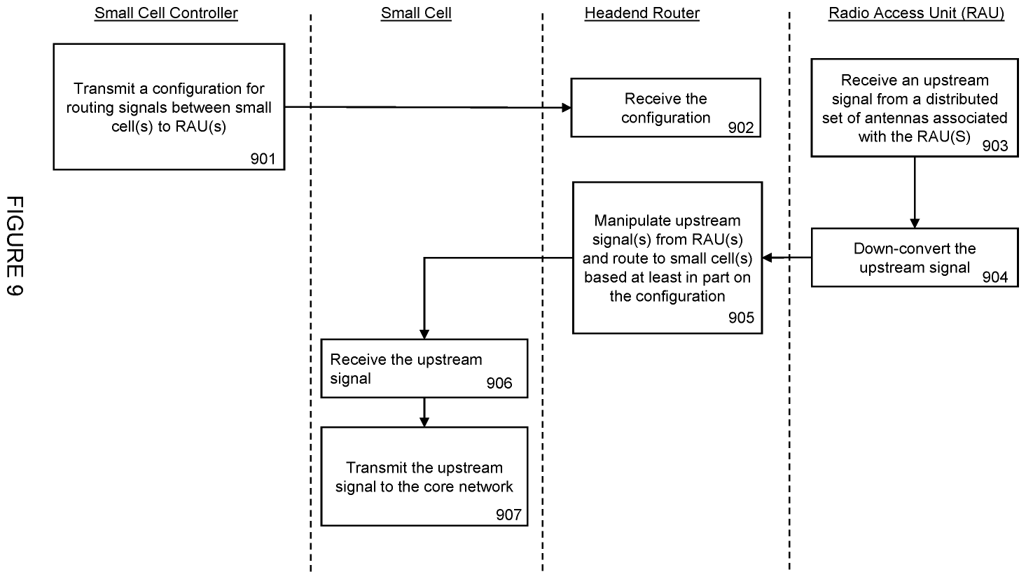

FIG. 9 shows an example of an information flow diagram for routing upstream signals between one or more small cell devices and one or more RAUs. At 901, a small cell controller transmits a configuration for routing signals between one or more small cell devices and one or more RAUs. At 902, a headend router receives the configuration. At 903, an RAU receives an upstream signal from a distributed set of antennas associated with the RAU. The upstream signal may be received from one or more user equipments (abbreviated herein as “UEs”) in a facility. At 904, the RAU down-converts the upstream signal. In some embodiments, for example, in an instance in which the upstream signals to be transmitted from the RAU comprise digital signals, the RAU may down-sample the upstream signals after down-converting the upstream signals. The upstream signal is then transmitted to the headend router. At 905, the headend router manipulates the upstream signal(s) from the RAU(s) and routes the upstream signals to one or more small cell devices based at least in part on the configuration. For example, the headend router may manipulate the upstream signal by combining a plurality of upstream signals (including the upstream signal transmitted by the RAU at 904) from a plurality of RAUs to a single small cell device. As another example, the headend router may manipulate the upstream signals by splitting a plurality of upstream signals from a single RAU (including the RAU that transmitted the upstream signal at 904). For example, in an instance in which the upstream signal comprises analog signals, the headend router may split the upstream signals to a plurality of frequency bands, each corresponding to a different small cell device. The split upstream signals can then be transmitted to a plurality of small cell devices. At 906, a small cell device receives the upstream signal. At 907, the small cell device transmits the upstream signal to a core network. The core network may be a 4G network, a 5G network, or other network.

In some embodiments, a controller determines a configuration for routing signals between one or more small cell devices and one or more RAUs. The controller may be a small cell controller that transmits an indication of the configuration, for example, to a router (e.g., a headend router) associated with a facility. In some embodiments, at least a portion of the controller may have a cloud component. In some embodiments, the controller may be part of a control system associated with the facility. For example, the controller may be part of a control system associated with the facility that controls a lighting system, an HVAC system, or the like.

In some embodiments, the controller receives inputs from various sources. For example, in some embodiments, the controller may receive inputs associated with cellular communications signals transmitted and/or received by one or more mobile devices within a facility. The inputs associated with the cellular communications signals may indicate a strength of the signal, a current usage of cellular communication by the one or more mobile devices (e.g., an amount of data transferred over a previous time window), or the like. As another example, in some embodiments, the controller may receive inputs that indicate a current or predicted occupancy of one or more regions of the facility. In some embodiments, inputs may be from one or more sensors that indicate current occupancy information of one or more particular regions (e.g., wings, floors, rooms, offices, common areas, outside areas, and/or other regions) of the facility. Example types of sensor data that may be received by a controller include electromagnetic radiation data (e.g., data associated with electromagnetic radiation in a visual spectrum, in an infrared spectrum, a radio frequency spectrum, ultrawideband radiation, or any combination thereof), geolocation signals (e.g., GPS signals, ultrawideband signals (UWB), short-range wireless signals, Bluetooth signals (BLE), ultra-high frequency signals (UHF), and/or other geolocation related signals), heat signatures determined by an infrared sensor, and/or any combination thereof. In some embodiments, inputs may be from scheduling information associated with the facility. For example, the scheduling information may indicate planned events (e.g., meetings, parties, and/or other planned events) that will occur in particular regions of the facility. The scheduling information may indicate timing information associated with a planned event, a planned location, a number of expected people at the planned event, or other suitable event information. Inputs (e.g., sensor data, scheduling information, and/or any other inputs) may be received from a cloud, from a server, and/or directly provided to the controller (e.g., by a user).

In some embodiments, a user is locatable in the enclosure (e.g., facility such as a building). The user can be located using one or more sensors, e.g., operatively coupled to the network. The user may carry a tag (e.g., ID tag). The tag may include geolocation technology (e.g., geolocation chip such as a microchip). The geolocation technology and/or tag may include radio frequency identification (e.g., RFID) technology (e.g., transceiver), Bluetooth technology, and/or Global Positional System (GPS) technology. The radio frequency may comprise ultrawide band radio frequency. The tag may be sensed by one or more sensors disposed in the enclosure. The sensor(s) may be disposed in a device ensemble (e.g., ensemble of targets). The device ensemble may comprise a sensor or an emitter. The sensor(s) may be operatively (e.g., communicatively) coupled to the network. The network may have low latency communication, e.g., within the enclosure. The radio waves (e.g., emitted and/or sensed by the tag) may comprise wide band, or ultra-wideband radio signals. The radio waves may comprise pulse radio waves. The radio waves may comprise radio waves utilized in communication. The radio waves may be at a medium frequency of at least about 300 kilohertz (KHz), 500 KHz, 800 KHz, 1000 KHz, 1500 KHz, 2000 KHz, or 2500 KHz. The radio waves may be at a medium frequency of at most about 500 KHz, 800 KHz, 1000 KHz, 1500 KHz, 2000 KHz, 2500 KHz, or 3000 KHz. The radio waves may be at any frequency between the aforementioned frequency ranges (e.g., from about 300 KHz to about 3000 KHz). The radio waves may be at a high frequency of at least about 3 megahertz (MHz), 5 MHz, 8 MHz, 10 MHz, 15 MHz, 20 MHz, or 25 MHz. The radio waves may be at a high frequency of at most about 5 MHz, 8 MHz, 10 MHz, 15 MHz, 20 MHz, 25 MHz, or 30 MHz. The radio waves may be at any frequency between the aforementioned frequency ranges (e.g., from about 3 MHz to about 30 MHz). The radio waves may be at a very high frequency of at least about 30 Megahertz (MHz), 50 MHz, 80 MHz, 100 MHz, 150 MHz, 200 MHz, or 250 MHz. The radio waves may be at a very high frequency of at most about 50 MHz, 80 MHz, 100 MHz, 150 MHz, 200 MHz, 250 MHz, or 300 MHz. The radio waves may be at any frequency between the aforementioned frequency ranges (e.g., from about 30 MHz to about 300 MHz). The radio waves may be at an ultra-high frequency of at least about 300 kilohertz (MHz), 500 MHz, 800 MHz, 1000 MHz, 1500 MHz, 2000 MHz, or 2500 MHz. The radio waves may be at an ultra-high frequency of at most about 500 MHz, 800 MHz, 1000 MHz, 1500 MHz, 2000 MHz, 2500 MHz, or 3000 MHz. The radio waves may be at any frequency between the aforementioned frequency ranges (e.g., from about 300 MHz to about 3000 MHz). The radio waves may be at a super high frequency of at least about 3 gigahertz (GHz), 5 GHz, 8 GHz, 10 GHz, 15 GHz, 20 GHz, or 25 GHz. The radio waves may be at a super high frequency of at most about 5 GHz, 8 GHz, 10 GHz, 15 GHz, 20 GHz, 25 GHz, or 30 GHz. The radio waves may be at any frequency between the aforementioned frequency ranges (e.g., from about 3 GHz to about 30 GHz).

In some embodiments, the identification tag of the occupant comprises a location device. The location device (also referred to herein as “locating device”) may compromise a radio emitter and/or receiver (e.g., a wide band, or ultra-wide band radio emitter and/or receiver). The locating device may include a Global Positioning System (GPS) device. The locating device may include a Bluetooth device. The locating device may include a radio wave transmitter and/or receiver. The radio waves may comprise wide band, or ultra-wideband radio signals. The radio waves may comprise pulse radio waves. The radio waves may comprise radio waves utilized in communication. The radio waves may be at a medium frequency of at least about 300 kilohertz (KHz), 500 KHz, 800 KHz, 1000 KHz, 1500 KHz, 2000 KHz, or 2500 KHz. The radio waves may be at a medium frequency of at most about 500 KHz, 800 KHz, 1000 KHz, 1500 KHz, 2000 KHz, 2500 KHz, or 3000 KHz. The radio waves may be at any frequency between the aforementioned frequency ranges (e.g., from about 300 KHz to about 3000 KHz). The radio waves may be at a high frequency of at least about 3 megahertz (MHz), 5 MHz, 8 MHz, 10 MHz, 15 MHz, 20 MHz, or 25 MHz. The radio waves may be at a high frequency of at most about 5 MHz, 8 MHz, 10 MHz, 15 MHz, 20 MHz, 25 MHz, or 30 MHz. The radio waves may be at any frequency between the aforementioned frequency ranges (e.g., from about 3 MHz to about 30 MHz). The radio waves may be at a very high frequency of at least about 30 Megahertz (MHz), 50 MHz, 80 MHz, 100 MHz, 150 MHz, 200 MHz, or 250 MHz. The radio waves may be at a very high frequency of at most about 50 MHz, 80 MHz, 100 MHz, 150 MHz, 200 MHz, 250 MHz, or 300 MHz. The radio waves may be at any frequency between the aforementioned frequency ranges (e.g., from about 30 MHz to about 300 MHz). The radio waves may be at an ultra-high frequency of at least about 300 kilohertz (MHz), 500 MHz, 800 MHz, 1000 MHz, 1500 MHz, 2000 MHz, or 2500 MHz. The radio waves may be at an ultra-high frequency of at most about 500 MHz, 800 MHz, 1000 MHz, 1500 MHz, 2000 MHz, 2500 MHz, or 3000 MHz. The radio waves may be at any frequency between the aforementioned frequency ranges (e.g., from about 300 MHz to about 3000 MHz). The radio waves may be at a super high frequency of at least about 3 gigahertz (GHz), 5 GHz, 8 GHz, 10 GHz, 15 GHz, 20 GHz, or 25 GHz. The radio waves may be at a super high frequency of at most about 5 GHz, 8 GHz, 10 GHz, 15 GHz, 20 GHz, 25 GHz, or 30 GHz. The radio waves may be at any frequency between the aforementioned frequency ranges (e.g., from about 3 GHz to about 30 GHz).

In some embodiments, a controller (e.g., as part of the control system) receives inputs from a server and/or from another controller, e.g., which predicts future occupancy information in one or more regions of a facility. In some embodiments, predictions may be generated using a neural network. For example, a neural network may take, as inputs, sensor data (e.g., that indicates occupancy information) and/or scheduling information, and may generate, as an output, a prediction of an occupancy level for a particular region of a building at a particular time or within a particular time window. An example prediction may be that a cafeteria region of the facility is likely to have a particular predicted occupancy (e.g., from about 50-100 people, from about 100-200 people, etc.) between 11 am.-1 p.m. Another example prediction may be that an auditorium region of the facility is likely to have a particular predicted occupancy (e.g., from about 10-20 people, from about 20-30 people, etc.) on a particular day of the week at a particular time (e.g., time window, or time period), for example, a day and time corresponding to a weekly staff meeting. A neural network may generate predictions based at least in part on sensor data obtained over any suitable time period (e.g., a previous week, a previous month, a previous year, and/or any other time period). In some embodiments, the neural network may be updated based on newly obtained sensor data to generate updated occupancy predictions. The neural network may comprise a machine learning computational scheme. A neural network may be a deep neural network (e.g., a Convolutional Neural Network, a Recurrent Neural Network, a Long Short-Term Memory Network, or the like). In some embodiments, the neural network may be a classifier that generates a prediction that an occupancy of a particular region of a facility will fall within a particular occupancy range.

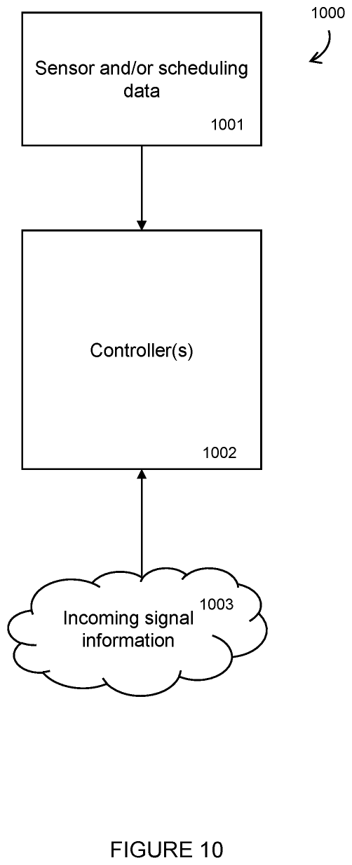

FIG. 10 shows an example of a schematic diagram 1000 of information sources for a controller. In the example shown in FIG. 10, one or more controller(s) 1002 receives sensor and/or scheduling data 1001. The one or more controller(s) 1002 may be local controllers (e.g., local to the facility, coupled to a local network of the facility, or other local controllers). In some embodiments, the one or more controller(s) 1002 may have a cloud component. The sensor and/or scheduling data 1001 may be received from a cloud, from a server, and/or may be directly provided to controller(s) 1002.

In some embodiments, data is analyzed by an artificial intelligence learning module. The data can be sensor data, schedule data, and/or user input. The learning module may comprise at least one rational decision making process, and/or learning that utilizes the data (e.g., as a learning set). The analysis of the data may be utilized to adjust and environment, e.g., by adjusting one or more components that affect the environment of the enclosure. The analysis of the data may be utilized to control a certain target apparatus, e.g., to produce a product, according to user preferences, and/or choose the certain target apparatus (e.g., based on user preference and/or user location). The data analysis may be performed by a machine based system (e.g., comprising a circuitry). The circuitry may be of a processor. The sensor data analysis may utilize artificial intelligence. The data analysis may rely on one or more models (e.g., mathematical models). In some embodiments, the data analysis comprises linear regression, least squares fit, Gaussian process regression, kernel regression, nonparametric multiplicative regression (NPMR), regression trees, local regression, semiparametric regression, isotonic regression, multivariate adaptive regression splines (MARS), logistic regression, robust regression, polynomial regression, stepwise regression, ridge regression, lasso regression, elasticnet regression, principal component analysis (PCA), singular value decomposition, fuzzy measure theory, Borel measure, Han measure, risk-neutral measure, Lebesgue measure, group method of data handling (GMDH), Naive Bayes classifiers, k-nearest neighbors algorithm (k-NN), support vector machines (SVMs), neural networks, support vector machines, classification and regression trees (CART), random forest, gradient boosting, or generalized linear model (GLM) technique. The data analysis may include a deep learning algorithm and/or artificial neural networks (ANN). The data analysis may comprise a learning schemes with a plurality of layers in the network (e.g., ANN). The learning of the learning module may be supervised, semi-supervised, or unsupervised. The deep learning architecture may comprise deep neural networks, deep belief networks, recurrent neural networks, or convolutional neural networks. The learning schemes may be ones utilized in computer vision, machine vision, speech recognition, natural language processing, audio recognition, social network filtering, machine translation, bioinformatics, drug design, medical image analysis, material inspection programs, and/or board game programs.

In some embodiments, a controller (e.g., a small cell controller) associated with a facility determines a configuration for routing signals between one or more small cell devices and one or more RAUs. The controller may determine the configuration based on signal information (e.g., current signal strength information, current cellular communication network usage information, and/or any other signal information), current occupancy information, predicted occupancy information, and/or any combination thereof. In some embodiments, signal strength information may be predicted based at least in part on factors such as a building shape, locations of antennas with respect to locations of mobile devices, building construction material, or the like. For example, a relatively weak signal strength may be predicted in instances in which a mobile device is relatively far from one or more antennas, in instances in which a mobile device is in a region of the facility that has a particular type of wall that blocks radio frequency (RF) signals, and/or any combination thereof.

In some embodiments, current and/or predicted occupancy information is used to determine a configuration for routing signals between one or more small cell devices and one or more RAUs. For example, a configuration may be determined that allocates two or more small cell devices to a single RAU associated with a particular floor or region of the facility, e.g., in response to receiving input information that indicates more than a predetermined occupancy (e.g., current and/or predicted occupancy) in the particular floor or region of the facility associated with the single RAU. The predetermined occupancy may be a number of people (e.g., a measured or predicted number of people), a relative occupancy increases relative to normal or typical occupancy (e.g., a 10% increase, a 20% increase, and/or any other suitable increase), and/or any other suitable occupancy metric. The increase may be measured in percentages or in headcount. As another example, a configuration may be determined that allocates one small cell device to one or more RAUs associated with particular floors or regions of the facility in response to receiving input information that indicates less than a predetermined occupancy (e.g., current and/or predicted occupancy) in the particular floors or regions of the facility associated with the one or more RAUs.

In some embodiments, a configuration is based at least in part on capacities of one or more small cell devices. For example, a configuration may be determined based at least in part on a flex or reserve capacity of a small cell device. A flex or reserve capacity of a small cell device may indicate a capacity headroom of the small cell device beyond typical (e.g., average) usage of the small cell device. For example, a configuration may be determined such that a small cell device is to route signals to and from a plurality of RAUs, where a number of RAUs in the plurality of RAUs is determined based at least in part on the flex or reserve capacity (e.g., such that the number of RAUs does not cause the small cell device to exceed its capacity). Capacity of a small cell device may be determined based at least in part on a bandwidth of the small cell device. A bandwidth of a small cell device may indicate a number of devices (e.g., mobile devices or UEs) the small cell device can support.

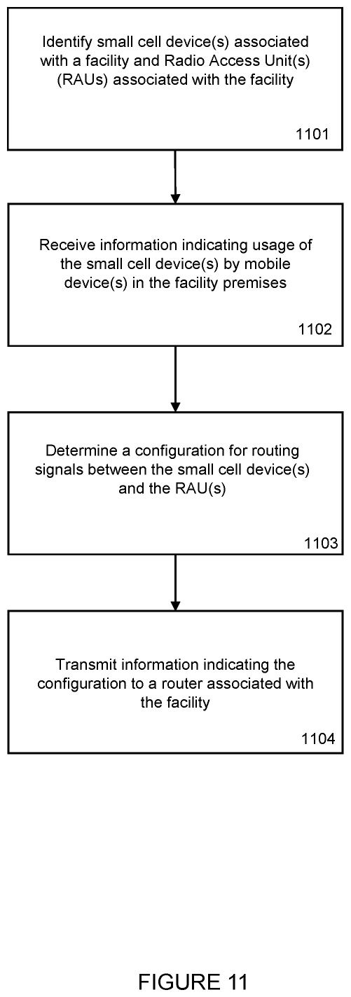

FIG. 11 shows an example flow diagram for determining a configuration for routing signals. At 1101, small cell devices associated with a facility and RAUs associated with a facility are identified. The small cell devices and/or the RAUs may be identified via explicit user input (e.g., received via a user interface), via a look-up table, and/or any combination thereof. Identifying a small cell device may comprise determining an identifier of the small cell device, a typical capacity of the small cell device, a flex or reserve capacity of the small cell device, and/or other identifying information. Identifying an RAU may comprise determining an identifier of the RAU, a location of the RAU within the facility, a number of antennas operatively coupled to the RAU, and/or other identifying information. At 1102, information indicating usage of the small cell device(s) by mobile device(s) in the facility premises is received. In some embodiments, the information may indicate a number of mobile device(s), signal strength information associated with one or more of the mobile device(s), a data transfer rate associated with one or more of the mobile device(s), current and/or predicted occupancy information within the facility premises (e.g., within particular regions of the facility premises), and/or other usage information. At 1103, a configuration for routing signals between the small cell device(s) and the RAU(s) is determined. The configuration may be determined based at least in part on the usage information. The configuration may indicate routing using identifiers of one or more small cell devices and/or identifiers of one or more RAUs. At 1104, the configuration is transmitted to a router (e.g., a headend router) associated with the facility.

In some embodiments, a configuration for routing signals between one or more small cell device(s) of a facility and one or more RAUs associated with the facility is based at least in part on usage information associated with the facility. The usage information may comprise occupancy information in the facility. The occupancy information may comprise current occupancy information associated with the facility and/or predicted occupancy information associated with the facility. Occupancy information may be determined based at least in part on sensor data, scheduling information, outputs of one or more machine learning models, and/or any combination thereof. The sensor data may be obtained by occupancy sensors. The occupancy sensors may comprise visible sensors (e.g., camera), IR sensors (e.g., IR camera), geolocation sensors, identification tags, sound sensors, carbon dioxide sensors, VOC sensors, oxygen sensors, particulate matter sensors, or humidity sensors. At times, sensor data may be analyzed (e.g., integrated), and the analysis of the sensor data may provide occupancy determination and/or prediction. The analysis may be directed and/or performed by the controller(s). The analysis may be performed by processors operatively coupled to the controller(s) (e.g., as part of the control system of the facility). The sensors may be coupled to the network of the facility. At least one of the sensors may be disposed internally in the facility (e.g., in the building). At least one of the sensors may be disposed externally to the facility (e.g., outside the building).

In some embodiments, current occupancy information indicates a number of people (personnel) at particular locations or regions of a facility at a present time. Examples of current occupancy information include X people currently in the cafeteria, Y people currently on the 10^{th} floor, Z people currently on the outside patio, etc., where X, Y and Z are integers. In some embodiments, current occupancy information may be determined based at least in part on sensor data. Examples of sensor data that may be used to determine current occupancy information include sensor data from shortrange wireless beacon devices (e.g., ID tags), RF sensing data, geolocation data (e.g., GPS data, or other positioning data), data from ultrawideband tags or beacons, infrared data (e.g., that indicate presence of a person in a particular region), data from one or more camera devices, and/or any combination thereof. In some embodiments, current occupancy information may be estimated. Current occupancy information may be estimated based at least in part on sensor data, scheduling information, or any combination thereof. For example, in some embodiments, current occupancy information may be estimated based at least in part on scheduling information (e.g., based at least in part on a calendared event that is associated with a particular number of invitees) and adjusted based at least in part on sensor data.

In some embodiments, predicted occupancy information indicates a number of people (personnel) at particular locations or regions of a facility at a future time. In some embodiments, predicted occupancy information may be for a specific future date and/or time, such as for a date and/or time at which an event has been scheduled (e.g., as indicated in one or more calendars associated with the facility). In some embodiments, predicted occupancy information may be for a recurring day of the week, day of the month, or the like. For example, predicted occupancy information may indicate an estimation of X people in an auditorium region of a facility at a day of the week and time of day corresponding to a weekly meeting, an estimation of Y people in an entryway of a facility on weekdays at times of day corresponding to a typical work start time or end time, or the like. In some embodiments, predicted occupancy information may be determined using a trained machine learning model (e.g., using AI). For example, the trained machine learning model may generate outputs that indicated predicted occupancies at particular days and/or times of day. In one example, the trained machine learning model may predict occupancy information for particular recurring days of the week, days of the month, times of day, etc. In other example, the trained machine learning model may identify occupancy information at particular times that correspond to a start time and/or end time of a typical workday. As another example, the trained machine learning model may identify occupancy information that indicates that people tend to gather on Friday evenings in a particular region. A trained machine learning model may take sensor data, scheduling information, or any combination thereof as inputs (e.g., as a learning set). The learning set may comprise historical occupancy data, e.g., obtained by any of the occupancy means described herein. A machine learning model may be retrained, for example, once per week, once per month, and/or at any other timepoints. The machine learning model may be trained (or re-trained) in real time and/or in times of low occupancy in the facility (e.g., during the night or work hours for a home; during off work hours, weekend, and holidays for a workplace; during weekdays for a recreational center or for a shopping mall).

In some embodiments, current and/or predicted occupancy information is determined based at least in part on scheduling information. The scheduling information may comprise calendar information, such as one or more calendars associated with the facility. The calendars may be associated with particular regions, floors, rooms, etc. of the facility, such as a calendar to reserve a particular location for an event. The calendars may be associated with one or more people, for example, who work in the facility, who manage the facility, or the like.

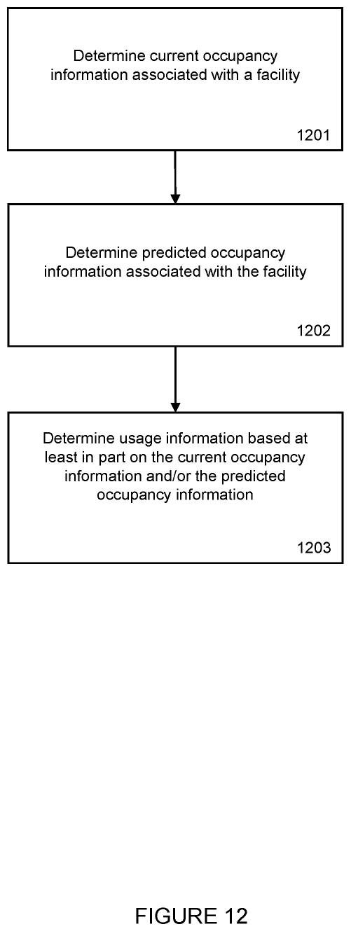

FIG. 12 shows an example flow diagram for determining usage information based at least in part on occupancy information. At 1201, current occupancy information associated with a facility is determined. The present (e.g., current, or real-time) occupancy information may indicate detected occupancy levels at particular regions of the facility at a present time and/or estimated occupancy levels at particular regions of the facility at the present time. The present occupancy information may be determined based on sensor data, scheduling information, and/or any combination thereof. At 1202, predicted occupancy information associated with the facility is determined. The predicted occupancy information may indicate occupancy information predicted for particular regions of the facility at a future time. The predicted occupancy information may be determined based on sensor data, scheduling information, and/or any combination thereof. The predicted occupancy information may be determined using a trained machine learning model. At 1203, usage information is determined based at least in part on the current occupancy information and/or the predicted occupancy information. In some embodiments, the usage information may comprise an aggregate occupancy information that combines the current occupancy information and the predicted occupancy information. In some embodiments, the usage information may comprise a weighted combination of the current occupancy information and the predicted occupancy information. For example, the predicted occupancy information may be weighted based on a confidence level associated with the predicted occupancy information. As another example, the current occupancy information may be weighted based at least in part on an amount of discrepancy between current sensor data that indicates detected occupancy at a present time and scheduling information for the present time (e.g., that indicates one or more scheduled events at the present time).

In some embodiments, usage information associated with devices in a facility is used to determine a channel sharing protocol for a plurality of small cells routed to an RAU. The device may be a service device (e.g., device that is utilized by personnel in the facility). The service device may be a factory machinery, a printer, or a vending machine. For example, in instances in which small cells transmit analog data, usage information may be used to determine a channel sharing protocol such that a plurality of small cells share a channel allocated to a single RAU. Examples of channel sharing protocols include Frequency-division multiple access (FDMA), time-divisional multiple access (TDMA), code-division multiple access (CDMA), and/or space-division multiple access (SDMA).

In some embodiments, the control system is operatively coupled to one or more targets of the facility, and is configured to control the one or more targets (e.g., devices). For example, the control system may control mechanical, electrical, electromechanical, and/or electromagnetic (e.g., optical and/or thermal) actions of the target. For example, the control system may control a physical action of the target. For example, the control system may control if the target apparatus is turned on or off, if any controllable compartment thereof is open or closed, direct directionality (e.g., left, right, up, down), enter and/or change settings, enable or deny access, transfer data to memory, reset data in the memory, upload and/or download software or executable code to the target apparatus, cause executable code to be run by a processor associated with and/or incorporated in the target apparatus, change channels, change volume, causing an action to return to a default setting and/or mode. The control system may change a set-point stored in a data set associated with the target, configure or reconfigure software associated with the target. The memory can be associated with and/or be part of the target. The control system may include the small cell controller(s).

In some embodiments, the target is operatively (e.g., communicatively) coupled to the network (e.g., communication, power and/or control network) of the facility. Once the target becomes operatively coupled to the network of the facility, it may be part of the targets controlled via the control system. A target may be a device (e.g., a sensor or an emitter). A target (e.g., third party target) may offer one or more services to a user. For example, the target (e.g., target apparatus) may be a dispenser. The dispenser may dispense food, beverage, and/or equipment, upon a command. The target may be a service device. The service device may include media players (e.g., which media may include music, video, television, and/or internet), manufacturing equipment, medical device, and/or exercise equipment. The target apparatus may comprise a television, recording device (e.g., video cassette recorder (VCR), digital video recorder (DVR), or any non-volatile memory), Digital Versatile Disc or Digital Video Disc (DVD) player, digital audio file player (e.g., MP3 player), cable and/or satellite converter set-top box (“STBs”), amplifier, compact disk (CD) player, game console, home lighting, electrically controlled drapery (e.g., blinds), tintable window (e.g., electrochromic window), fan, HVAC system, thermostat, personal computer, dispenser (e.g., soap, beverage, food, or equipment dispenser), washing machine, or dryer. In some embodiments, the target (e.g., target apparatus) excludes entertainment an entertainment device (e.g., a television, recording device (e.g., video cassette recorder (VCR), digital video recorder (DVR), or any non-volatile memory), Digital Versatile Disc or Digital Video Disc (DVD) player, digital audio file player (e.g., MP3 player), cable and/or satellite converter set-top box (“STBs”), amplifier, compact disk (CD) player, and/or game console). The target may be a control target. In some embodiments, the one or more devices comprises a service, office and/or factory apparatus.

In some embodiments, the facility comprises a local network. The network may be operatively coupled to the control system. The network may be a network of the facility (e.g., of the building). The network may be configured to transmit communication and/or power. The network may be any network disclosed herein. The network may extend to a room, a floor, several rooms, several floors, the building, or several buildings of the facility. The network may operatively (e.g., to facilitate power and/or communication) couple to a control system (e.g., as disclosed herein), to sensor(s), emitter(s), antenna, router(s), power supply, building management system (and/or its components). The network may be operatively coupled to personal computers of users (e.g., occupants) associated with the facility (e.g., employees and/or tenants). At least part of the network may be installed as the initial network of the facility, and/or disposed in an envelope structure of the facility. At least a portion of the network may be the first network deployed in the facility, e.g., upon its creation. The network may be operatively coupled to one or more targets (e.g., devices) in the facility that perform operations for, or associated with, the facility (e.g., production machinery, communication machinery, and/or service devices such as service machinery). The production machinery may include computers, factory related machinery, and/or any other machinery configured to produce product(s) (e.g., printers and/or dispensers). The service machinery may include food and/or beverage related machinery, hygiene related machinery (e.g., mask dispenser, and/or disinfectant dispensers). The communication machinery may include media projectors, media display, touch screens, speakers, and/or lighting (e.g., entry, exit, and/or security lighting).

In some embodiments, usage information is used to determine power specifications (e.g., for transmitting and/or receiving upstream and/or downstream signals) for one or more components of the facility. For example, a small cell controller may transmit instructions to one or more RAUs of the facility instructing the one or more RAUs to amplify downstream signals received from a router (e.g., a headend router) prior to causing one or more antennas operatively coupled to the RAU to transmit the signal. As another example, a small cell controller may transmit instructions to one or more RAUs of the facility instructing the one or more RAUs to amplify upstream signals received from one or more antennas operatively coupled to the one or more RAUs prior to transmitting the upstream signals to a router (e.g., the headend router). In some embodiments, the small cell controller may identify RAUs that are to amplify upstream and/or downstream signals based at least in part on the usage information. For example, in an instance in which the usage information indicates that one or more devices receiving information from antennas operatively coupled to a particular RAU are outside of a predetermined proximity to the antennas, the small cell controller may instruct the RAU to amplify upstream and/or downstream signals. The usage information may include a proximity of one or more devices to one or more antennas in a facility and/or an indication of a line of sight between one or more devices to one or more antennas in a facility (e.g., whether the one or more devices are blocked by a wall or other structure to the one or more antennas). In some embodiments, line of sight information (including materials of particular walls and/or other structures) may be determined based at least in part on blueprint information and/or other architectural information. For example, line of sight information may utilized a BMI (e.g., such as a Revit file). In some embodiments, the small cell controller may instruct one or more active antennas in the facility to amplify upstream and/or downstream signals based at least in part on usage information. In some embodiments, the controller may be operatively coupled to a BMI file.

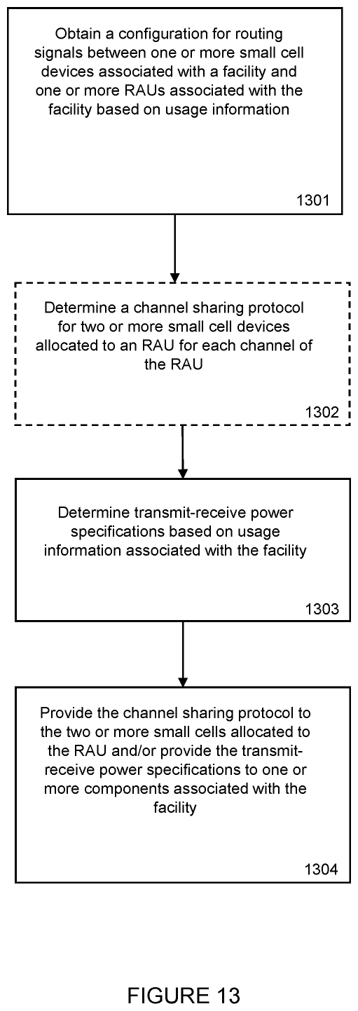

FIG. 13 shows a flow diagram for determining channel sharing protocols and/or power specifications based on usage information. At 1301, a configuration for routing signals between one or more small cell devices associated with a facility and one or more RAUs associated with the facility is obtained based on usage information of devices (e.g., mobile devices) in the facility. The configuration may be determined or obtained based at least in part on current and/or predicted occupancy information at one or more regions and/or locations of the facility. The configuration may be obtained or determined by a small cell controller, e.g., as part of the control system. In some embodiments, at 1302, a channel sharing protocol for two or more small cell devices allocated to a single RAU is determined for each channel of the RAU. The channel sharing protocol may be determined in instances in which upstream and/or downstream signals transmitted between the two or more small cell devices and a router (e.g., a headend router) are in an analog format. The channel sharing protocol may include Frequency-division multiple access (FDMA), Time-division multiple access (TDMA), Code-division multiple access (CDMA), Space-division multiple access (SDMA), and/or any other suitable channel sharing protocol (e.g., that allows upstream and/or downstream signals to be transmitted between the two or more small cell devices and the single RAU within a single channel). For example, a bandwidth of the single channel may be divided into a plurality of portions each corresponding to one of the two or more small cell devices. The number of portions in the plurality of portions may be determined based at least in part on a number of small cell devices sharing the single channel. At 1303, transmit/receive power specifications are determined based at least in part on usage information associated with the facility. The transmit-receive power specification may indicate whether and/or how much upstream and/or downstream signals are to be amplified. Amplification may occur at one or more RAUs and/or one or more antennas in the facility. The usage information may indicate a proximity of one or more devices to one or more antennas within the facility, line of sight information associated with one or more devices to one or more antennas within the facility, and/or other usage information. At 1304, the transmit-receive power specifications are provided to one or more components of the facility. The one or more components may include one or more RAUs in the facility and/or one or more antennas in the facility. In some embodiments, at 1304, the channel sharing protocol is provided to the two or more small cell devices allocated to a single RAU. For example, the channel sharing protocol may be provided to the two or more small cell devices in instances in which upstream and/or downstream signals between the two or more small cell devices and a router (e.g., a headend router) are analog signals.

In some embodiments, a facility in which small cell devices and/or a small cell controller is deployed may also be equipped with one or more windows, such as tintable (e.g., electrochromic) windows. In some embodiments, a control system may be shared between the small cell devices and the one or more windows (e.g., and be part of a control system of the facility). In some embodiments, various networks, connectors, cables, or the like may be shared between a control system associated with one or more small cell devices and one or more controllable devices in a facility (e.g., one or more tintable windows). In various embodiments, a network infrastructure supports a control system for one or more windows such as tintable (e.g., electrochromic) windows. The control system may comprise one or more controllers operatively coupled (e.g., directly or indirectly) to one or more windows. While the disclosed embodiments describe tintable windows (also referred to herein as “optically switchable windows,” or “smart windows”) such as electrochromic windows, the concepts disclosed herein may apply to other types of switchable optical devices comprising a liquid crystal device, an electrochromic device, suspended particle device (SPD), NanoChromics display (NCD), Organic electroluminescent display (OELD), suspended particle device (SPD), NanoChromics display (NCD), or an Organic electroluminescent display (OELD). The display element may be attached to a part of a transparent body (such as the windows). The tintable window may be disposed in a (non-transitory) facility such as a building, and/or in a transitory facility (e.g., vehicle) such as a car, RV, bus, train, airplane, helicopter, ship, or boat.

In some embodiments, a tintable window exhibits a (e.g., controllable and/or reversible) change in at least one optical property of the window, e.g., when a stimulus is applied. The change may be a continuous change. A change may be to discrete tint levels (e.g., to at least about 2, 4, 8, 16, or 32 tint levels). The optical property may comprise hue, or transmissivity. The hue may comprise color. The transmissivity may be of one or more wavelengths. The wavelengths may comprise ultraviolet, visible, or infrared wavelengths. The stimulus can include an optical, electrical and/or magnetic stimulus. For example, the stimulus can include an applied voltage and/or current. One or more tintable windows can be used to control lighting and/or glare conditions, e.g., by regulating the transmission of solar energy propagating through them. One or more tintable windows can be used to control a temperature within a building, e.g., by regulating the transmission of solar energy propagating through the window. Control of the solar energy may control heat load imposed on the interior of the facility (e.g., building). The control may be manual and/or automatic. The control may be used for maintaining one or more requested (e.g., environmental) conditions, e.g., occupant comfort. The control may include reducing energy consumption of a heating, ventilation, air conditioning and/or lighting systems. At least two of heating, ventilation, and air conditioning may be induced by separate systems. At least two of heating, ventilation, and air conditioning may be induced by one system. The heating, ventilation, and air conditioning may be induced by a single system (abbreviated herein as “HVAC). In some cases, tintable windows may be responsive to (e.g., and communicatively coupled to) one or more environmental sensors and/or user control. Tintable windows may comprise (e.g., may be) electrochromic windows. The windows may be located in the range from the interior to the exterior of a structure (e.g., facility, e.g., building). However, this need not be the case. Tintable windows may operate using liquid crystal devices, suspended particle devices, microelectromechanical systems (MEMS) devices (such as microshutters), or any technology known now, or later developed, that is configured to control light transmission through a window. Windows (e.g., with MEMS devices for tinting) are described in U.S. Pat. No. 10,359,681, issued Jul. 23, 2019, filed May 15, 2015, titled “MULTI-PANE WINDOWS INCLUDING ELECTROCHROMIC DEVICES AND ELECTROMECHANICAL SYSTEMS DEVICES,” and incorporated herein by reference in its entirety. In some cases, one or more tintable windows can be located within the interior of a building, e.g., between a conference room and a hallway. In some cases, one or more tintable windows can be used in automobiles, trains, aircraft, and other vehicles, e.g., in lieu of a passive and/or non-tinting window. In some embodiments, the tintable window comprises an electrochromic device (referred to herein as an “EC device” (abbreviated herein as ECD), or “EC”). An EC device may comprise at least one coating that includes at least one layer. The at least one layer can comprise an electrochromic material. In some embodiments, the electrochromic material exhibits a change from one optical state to another, e.g., when an electric potential is applied across the EC device. The transition of the electrochromic layer from one optical state to another optical state can be caused, e.g., by reversible, semi-reversible, or irreversible ion insertion into the electrochromic material (e.g., by way of intercalation) and a corresponding injection of charge-balancing electrons. For example, the transition of the electrochromic layer from one optical state to another optical state can be caused, e.g., by a reversible ion insertion into the electrochromic material (e.g., by way of intercalation) and a corresponding injection of charge-balancing electrons. Reversible may be for the expected lifetime of the ECD. Semi-reversible refers to a measurable (e.g., noticeable) degradation in the reversibility of the tint of the window over one or more tinting cycles. In some instances, a fraction of the ions responsible for the optical transition is irreversibly bound up in the electrochromic material (e.g., and thus the induced (altered) tint state of the window is not reversible to its original tinting state). In various EC devices, at least some (e.g., all) of the irreversibly bound ions can be used to compensate for “blind charge” in the material (e.g., ECD).

In some implementations, suitable ions include cations. The cations may include lithium ions (Li+) and/or hydrogen ions (H+) (i.e., protons). In some implementations, other ions can be suitable. Intercalation of the cations may be into an (e.g., metal) oxide. A change in the intercalation state of the ions (e.g., cations) into the oxide may induce a visible change in a tint (e.g., color) of the oxide. For example, the oxide may transition from a colorless to a colored state. For example, intercalation of lithium ions into tungsten oxide (WO3-y (0<y≤˜0.3)) may cause the tungsten oxide to change from a transparent state to a colored (e.g., blue) state. EC device coatings as described herein are located within the viewable portion of the tintable window such that the tinting of the EC device coating can be used to control the optical state of the tintable window.

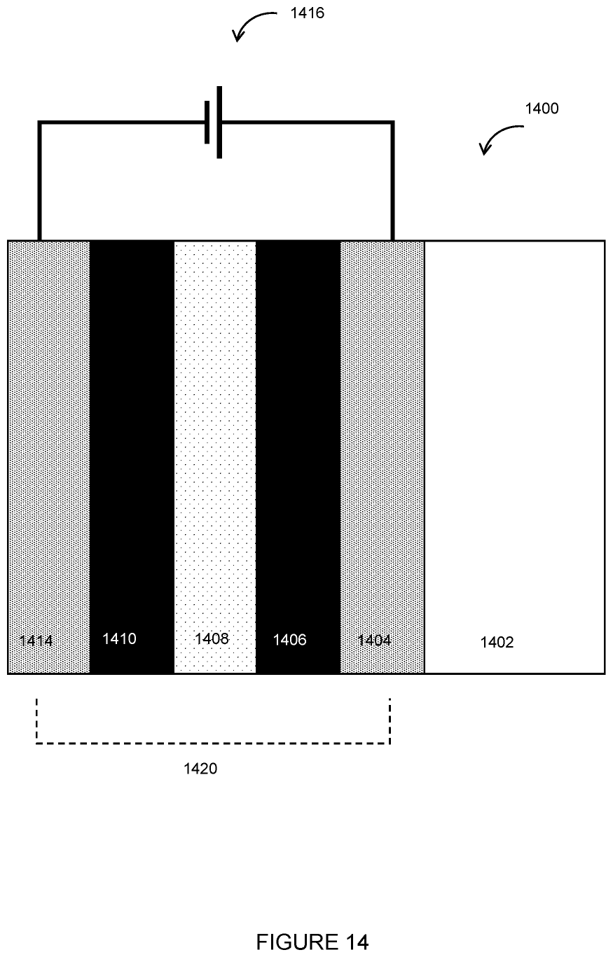

FIG. 14 shows an example of a schematic cross-section of an electrochromic device 1400 in accordance with some embodiments is shown in FIG. 14. The EC device coating is attached to a substrate 1402, a transparent conductive layer (TCL) 1404, an electrochromic layer (EC) 1406 (sometimes also referred to as a cathodically coloring layer or a cathodically tinting layer), an ion conducting layer or region (IC) 1408, a counter electrode layer (CE) 1410 (sometimes also referred to as an anodically coloring layer or anodically tinting layer), and a second TCL 1414.

Elements 1404, 1406, 1408, 1410, and 1414 are collectively referred to as an electrochromic stack 1420. A voltage source 1416 operable to apply an electric potential across the electrochromic stack 1420 effects the transition of the electrochromic coating from, e.g., a clear state to a tinted state. In other embodiments, the order of layers is reversed with respect to the substrate. That is, the layers are in the following order: substrate, TCL, counter electrode layer, ion conducting layer, electrochromic material layer, TCL.

In various embodiments, the ion conductor region (e.g., 1408) may form from a portion of the EC layer (e.g., 1406) and/or from a portion of the CE layer (e.g., 1410). In such embodiments, the electrochromic stack (e.g., 1420) may be deposited to include cathodically coloring electrochromic material (the EC layer) in direct physical contact with an anodically coloring counter electrode material (the CE layer). The ion conductor region (sometimes referred to as an interfacial region, or as an ion conducting substantially electronically insulating layer or region) may form where the EC layer and the CE layer meet, for example through heating and/or other processing steps. Examples of electrochromic devices (e.g., including those fabricated without depositing a distinct ion conductor material) can be found in U.S. patent application Ser. No. 13/462,725, filed May 2, 2012, titled “ELECTROCHROMIC DEVICES,” that is incorporated herein by reference in its entirety. In some embodiments, an EC device coating may include one or more additional layers such as one or more passive layers. Passive layers can be used to improve certain optical properties, to provide moisture, and/or to provide scratch resistance. These and/or other passive layers can serve to hermetically seal the EC stack 1420. Various layers, including transparent conducting layers (such as 1404 and 1414), can be treated with anti-reflective and/or protective layers (e.g., oxide and/or nitride layers).

In certain embodiments, the electrochromic device is configured to (e.g., substantially) reversibly cycle between a clear state and a tinted state. Reversible may be within an expected lifetime of the ECD. The expected lifetime can be at least about 5, 10, 15, 25, 50, 75, or 100 years. The expected lifetime can be any value between the aforementioned values (e.g., from about 5 years to about 100 years, from about 5 years to about 50 years, or from about 50 years to about 100 years). A potential can be applied to the electrochromic stack (e.g., 1420) such that available ions in the stack that can cause the electrochromic material (e.g., 1406) to be in the tinted state reside primarily in the counter electrode (e.g., 1410) when the window is in a first tint state (e.g., clear). When the potential applied to the electrochromic stack is reversed, the ions can be transported across the ion conducting layer (e.g., 1408) to the electrochromic material and cause the material to enter the second tint state (e.g., tinted state).

It should be understood that the reference to a transition between a clear state and tinted state is non-limiting and suggests only one example, among many, of an electrochromic transition that may be implemented. Unless otherwise specified herein, whenever reference is made to a clear-tinted transition, the corresponding device or process encompasses other optical state transitions such as non-reflective-reflective, and/or transparent-opaque. In some embodiments, the terms “clear” and “bleached” refer to an optically neutral state, e.g., untinted, transparent and/or translucent. In some embodiments, the “color” or “tint” of an electrochromic transition is not limited to any wavelength or range of wavelengths. The choice of appropriate electrochromic material and counter electrode materials may govern the relevant optical transition (e.g., from tinted to untinted state).

In certain embodiments, at least a portion (e.g., all of) the materials making up electrochromic stack are inorganic, solid (i.e., in the solid state), or both inorganic and solid. Because various organic materials tend to degrade over time, particularly when exposed to heat and UV light as tinted building windows are, inorganic materials offer an advantage of a reliable electrochromic stack that can function for extended periods of time. In some embodiments, materials in the solid state can offer the advantage of being minimally contaminated and minimizing leakage issues, as materials in the liquid state sometimes do. One or more of the layers in the stack may contain some amount of organic material (e.g., that is measurable). The ECD or any portion thereof (e.g., one or more of the layers) may contain little or no measurable organic matter. The ECD or any portion thereof (e.g., one or more of the layers) may contain one or more liquids that may be present in little amounts. Little may be of at most about 100 ppm, 10 ppm, or 1 ppm of the ECD. Solid state material may be deposited (or otherwise formed) using one or more processes employing liquid components, such as certain processes employing sol-gels, physical vapor deposition, and/or chemical vapor deposition.

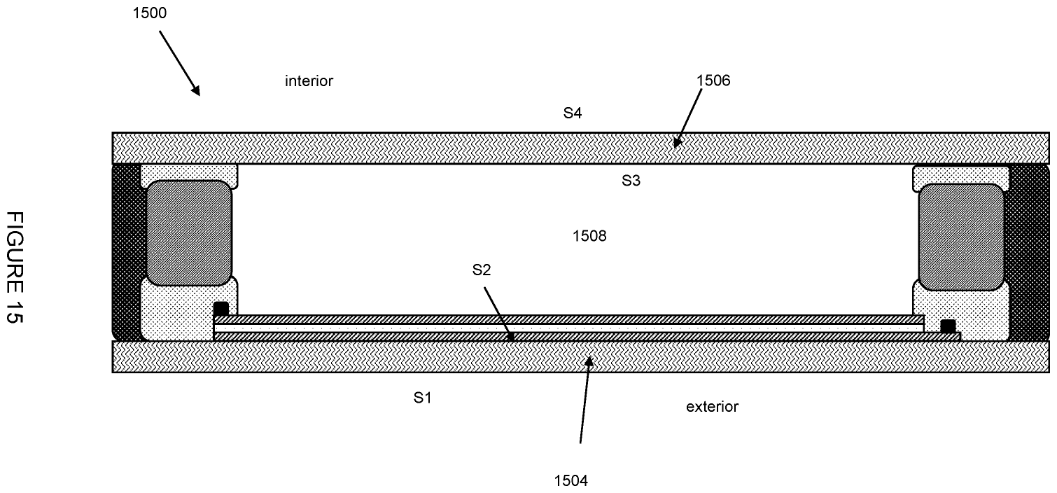

FIG. 15 show an example of a cross-sectional view of a tintable window embodied in an insulated glass unit (“IGU”) 1500, in accordance with some implementations. The terms “IGU,” “tintable window,” and “optically switchable window” can be used interchangeably herein. It can be desirable to have IGUs serve as the fundamental constructs for holding electrochromic panes (also referred to herein as “lites”) when provided for installation in a building. An IGU lite may be a single substrate or a multi-substrate construct. The lite may comprise a laminate, e.g., of two substrates. IGUs (e.g., having double- or triple-pane configurations) can provide a number of advantages over single pane configurations. For example, multi-pane configurations can provide enhanced thermal insulation, noise insulation, environmental protection and/or durability, when compared with single-pane configurations. A multi-pane configuration can provide increased protection for an ECD. For example, the electrochromic films (e.g., as well as associated layers and conductive interconnects) can be formed on an interior surface of the multi-pane IGU and be protected by an inert gas fill in the interior volume (e.g., 1508) of the IGU. The inert gas fill may provide at least some (heat) insulating function for an IGU. Electrochromic IGUs may have heat blocking capability, e.g., by virtue of a tintable coating that absorbs (and/or reflects) heat and light.

In some embodiments, an “IGU” includes two (or more) substantially transparent substrates. For example, the IGU may include two panes of glass. At least one substrate of the IGU can include an electrochromic device disposed thereon. The one or more panes of the IGU may have a separator disposed between them. An IGU can be a hermetically sealed construct, e.g., having an interior region that is isolated from the ambient environment. A “window assembly” may include an IGU. A “window assembly” may include a (e.g., stand-alone) laminate. A “window assembly” may include one or more electrical leads, e.g., for connecting the IGUs and/or laminates. The electrical leads may operatively couple (e.g., connect) one or more electrochromic devices to a voltage source, switches and the like, and may include a frame that supports the IGU or laminate. A window assembly may include a window controller, and/or components of a window controller (e.g., a dock).

FIG. 15 shows an example implementation of an IGU 1500 that includes a first pane 1504 having a first surface S1 and a second surface S2. In some implementations, the first surface S1 of the first pane 1504 faces an exterior environment, such as an outdoors or outside environment. The IGU 1500 also includes a second pane 1506 having a first surface S3 and a second surface S4. In some implementations, the second surface (e.g., S4) of the second pane (e.g., 1506) faces an interior environment, such as an inside environment of a home, building, vehicle, or compartment thereof (e.g., an enclosure therein such as a room).

In some implementations, the first and the second panes (e.g., 1504 and 1506) are transparent or translucent, e.g., at least to light in the visible spectrum. For example, each of the panes (e.g., 1504 and 1506) can be formed of a glass material. The glass material may include architectural glass, and/or shatter-resistant glass. The glass may comprise a silicon oxide (SOX). The glass may comprise a soda-lime glass or float glass. The glass may comprise at least about 75% silica (SiO₂). The glass may comprise oxides such as Na₂O, or CaO. The glass may comprise alkali or alkali-earth oxides. The glass may comprise one or more additives. The first and/or the second panes can include any material having suitable optical, electrical, thermal, and/or mechanical properties. Other materials (e.g., substrates) that can be included in the first and/or the second panes are plastic, semi-plastic and/or thermoplastic materials, for example, poly(methyl methacrylate), polystyrene, polycarbonate, allyl diglycol carbonate, SAN (styrene acrylonitrile copolymer), poly(4-methyl-1-pentene), polyester, and/or polyamide. The first and/or second pane may include mirror material (e.g., silver). In some implementations, the first and/or the second panes can be strengthened. The strengthening may include tempering, heating, and/or chemically strengthening.

In some embodiments, an enclosure includes one or more sensors. The sensor may facilitate controlling the environment of the enclosure such that inhabitants of the enclosure may have an environment that is more comfortable, delightful, beautiful, healthy, productive (e.g., in terms of inhabitant performance), easer to live (e.g., work) in, or any combination thereof. The sensor(s) may be configured as low or high resolution sensors. Sensor may provide on/off indications of the occurrence and/or presence of a particular environmental event (e.g., one pixel sensors). In some embodiments, the accuracy and/or resolution of a sensor may be improved via artificial intelligence analysis of its measurements. Examples of artificial intelligence techniques that may be used include: reactive, limited memory, theory of mind, and/or self-aware techniques know to those skilled in the art). Sensors may be configured to process, measure, analyze, detect and/or react to one or more of: data, temperature, humidity, sound, force, pressure, electromagnetic waves, position, distance, movement, flow, acceleration, speed, vibration, dust, light, glare, color, gas(es), and/or other aspects (e.g., characteristics) of an environment (e.g., of an enclosure). The gases may include volatile organic compounds (VOCs). The gases may include carbon monoxide, carbon dioxide, water vapor (e.g., humidity), oxygen, radon, and/or hydrogen sulfide. The one or more sensors may be calibrated in a factory setting and/or at the target environment (e.g., deployment site). A sensor may be optimized to be capable of performing accurate measurements of one or more environmental characteristics present in the factory setting and/or at the target environment. In some instances, a factory calibrated sensor may be less optimized for operation in a target environment. For example, a factory setting may comprise a different environment than a target environment. The target environment can be an environment in which the sensor is deployed. The target environment can be an environment in which the sensor is expected and/or destined to operate. The target environment may differ from a factory environment. A factory environment corresponds to a location at which the sensor was assembled and/or built. The target environment may comprise a factory in which the sensor was not assembled and/or built. In some instances, the factory setting may differ from the target environment, e.g., to the extent that sensor readings captured in the target environment are erroneous (e.g., to a measurable extent). In this context, “erroneous” may refer to sensor readings that deviate from a specified accuracy (e.g., specified by a manufacture of the sensor). In some situations, a factory-calibrated sensor may provide readings that do not meet accuracy specifications (e.g., by a manufacturer) when operated in the target environments.

In some embodiments, the control system is operatively (e.g., communicatively) coupled to an ensemble of devices (e.g., sensors and/or emitters). One or more sensors may be configured to process, measure, analyze, detect and/or react to: data, temperature, humidity, sound, force, pressure, concentration, electromagnetic waves, position, distance, movement, flow, acceleration, speed, vibration, dust, light, glare, color, gas(es) type, and/or other aspects (e.g., characteristics) of an environment (e.g., of an enclosure). The gases may include volatile organic compounds (VOCs). The gases may include carbon monoxide, carbon dioxide, water vapor (e.g., humidity), oxygen, radon, and/or hydrogen sulfide. The one or more sensors may be calibrated in a factory setting and/or in the facility. A sensor may be optimized to performing accurate measurements of one or more environmental characteristics present in the factory setting and/or in the facility in which it is deployed. The environmental characteristic may comprise temperature, humidity, pressure, CO₂, CO, VOC, debris (e.g., smoke, particulates), radon, sound, sound emitter, temperature, or electromagnetic radiation (e.g., UV having wavelength range of from about 10 nanometers (nm) to about 400 nm, IR having wavelength range of from about 700 nm to about 1 mm, or visible light having wavelength range of from about 400 to about 700 nm). A device ensemble may include CO₂, VOC, temperature, humidity, electromagnetic light, pressure, and/or noise sensors. The sensor may comprise a gesture sensor (e.g., RGB gesture sensor), an acetometer, or a sound sensor. The VOC sensor may be configured to measure Total VOC (abbreviated herein as “TVOC,” or “tVOC”). In some embodiments, the ensemble facilitates the control of the environment and/or the alert. The control may utilize a control scheme such as feedback control, or any other control scheme delineated herein. The ensemble may comprise at least one sensor configured to sense electromagnetic radiation. The electromagnetic radiation may be (humanly) visible, infrared (IR), or ultraviolet (UV) radiation. The at least one sensor may comprise an array of sensors. For example, the ensemble may comprise an IR sensor array (e.g., a far infrared thermal array such as the one by Melexis). The IR sensor array may have a resolution of at least 32×24 pixels. The IR sensor may be coupled to a digital interface. The ensemble may comprise an IR camera. The ensemble may comprise a sound detector. The ensemble may comprise a microphone. The ensemble may comprise any sensor and/or emitter disclosed herein. The ensemble may include CO₂, VOC, temperature, humidity, electromagnetic light, pressure, and/or noise sensors. The sensor may comprise a gesture sensor (e.g., RGB gesture sensor), an acetometer, or a sound sensor. The sounds sensor may comprise an audio decibel level detector. The sensor may comprise a meter driver. The ensemble may include a microphone and/or a processor. The ensemble may comprise a camera (e.g., a 4K pixel camera), a UWB sensor and/or emitter, a Bluetooth (BLE) sensor and/or emitter, a processor. The camera may have any camera resolution disclosed herein. One or more of the devices (e.g., sensors) can be integrated on a chip. The device (e.g., sensor) ensemble may be utilized to determine presence of occupants in an enclosure, their number and/or identity (e.g., using the camera). The device ensemble may be utilized to control (e.g., monitor and/or adjust) one or more environmental characteristics in the enclosure environment.

The sensors coupled to the network may be configured to sense properties comprising temperature, Relative Humidity (RH), Illuminance (e.g., in Lux), temperature (in degrees Celsius), correlated color temperature (CCT, e.g., in degrees Kelvin), carbon dioxide (e.g., in parts per million (ppm)), volatile organic compounds (VOC, e.g., as an index value), pressure (e.g., as sound pressure in Decibels), pulverous material, infrared, ultraviolet, or visible light. The sensor may have an accuracy. The sensor may have a random variability. The random variability (e.g., statistical measures of long-term random variability). The random variability of the temperature sensor may be at most about 0.5 degrees Celsius (° C.), 0.3° C., 0.2° C. or 0.1° C. The random variability of the RH sensor may be at most about 3%, 2%, 1.5%, or 1%. The random variability of the Illuminance sensor may be at most about 20 LUX, 15 LUX, 10 LUX, or 5LUX. The random variability of the CCT sensor may be at most about 250 Kelvin (K), 220K, 210K, 200K, 190K, or 150K. The random variability of the carbon dioxide sensor may be at most about 25 ppm, 23 ppm, 20 ppm, 19 ppm, or 15 ppm. The random variability of the VOC sensor may be at most about 15 index value (IV), 12IV, 11IV, 10IV, or 5IV. The random variability of the sound pressure sensor may be at most about 10 Decibels (dB), 8 dB, 5 dB, 4 dB, or 2 dB. At times, a sensor ensemble may comprise measuring the temperature in the device ensemble (e.g., internal device ensemble temperature) and/or out of the device ensemble (e.g., external device ensemble temperature such as temperature in a room in which the device ensemble is disposed). In some embodiments, data from the sensor(s) undergoes processing and/or analysis.

In some embodiments, a plurality of devices may be operatively (e.g., communicatively) coupled to the control system. The plurality of devices may be disposed in a facility (e.g., including a building and/or room). The control system may comprise the hierarchy of controllers. The devices may comprise an emitter, a sensor, or a window (e.g., IGU). The device may be any device as disclosed herein. At least two of the plurality of devices may be of the same type. For example, two or more IGUs may be coupled to the control system. At least two of the plurality of devices may be of different types. For example, a sensor and an emitter may be coupled to the control system. At times, the plurality of devices may comprise at least 20, 50, 100, 500, 1000, 2500, 5000, 7500, 10000, 50000, 100000, or 500000 devices. The plurality of devices may be of any number between the aforementioned numbers (e.g., from 20 devices to 500000 devices, from 20 devices to 50 devices, from 50 devices to 500 devices, from 500 devices to 2500 devices, from 1000 devices to 5000 devices, from 5000 devices to 10000 devices, from 10000 devices to 100000 devices, or from 100000 devices to 500000 devices). For example, the number of windows in a floor may be at least 5, 10, 15, 20, 25, 30, 40, or 50. The number of windows in a floor can be any number between the aforementioned numbers (e.g., from 5 to 50, from 5 to 25, or from 25 to 50). At times, the devices may be in a multi-story building. At least a portion of the floors of the multi-story building may have devices controlled by the control system (e.g., at least a portion of the floors of the multi-story building may be controlled by the control system). For example, the multi-story building may have at least 2, 8, 10, 25, 50, 80, 100, 120, 140, or 160 floors that are controlled by the control system. The number of floors (e.g., devices therein) controlled by the control system may be any number between the aforementioned numbers (e.g., from 2 to 50, from 25 to 100, or from 80 to 160). The floor may be of an area of at least about 150 m², 250 m², 500 m², 1000 m², 1500 m², or 2000 square meters (m²). The floor may have an area between any of the aforementioned floor area values (e.g., from about 150 m² to about 2000 m², from about 150 m² to about 500 m², from about 250 m² to about 1000 m², or from about 1000 m² to about 2000 m²). The building may comprise an area of at least about 1000 square feet (sqft), 2000 sqft, 5000 sqft, 10000 sqft, 100000 sqft, 150000 sqft, 200000 sqft, or 500000 sqft. The building may comprise an area between any of the above mentioned areas (e.g., from about 1000 sqft to about 5000 sqft, from about 5000 sqft to about 500000 sqft, or from about 1000 sqft to about 500000 sqft). The building may comprise an area of at least about 100 m², 200 m², 500 m², 1000 m², 5000 m², 10000 m², 25000 m², or 50000 m². The building may comprise an area between any of the above mentioned areas (e.g., from about 100 m² to about 1000 m², from about 500 m² to about 25000 m², from about 100 m² to about 50000 m²). The facility may comprise a commercial or a residential building. The commercial building may include tenant(s) and/or owner(s). The residential facility may comprise a multi or a single family building. The residential facility may comprise an apartment complex. The residential facility may comprise a single family home. The residential facility may comprise multifamily homes (e.g., apartments). The residential facility may comprise townhouses. The facility may comprise residential and commercial portions. The facility may comprise at least about 1, 2, 5, 10, 50, 100, 150, 200, 250, 300, 350, 400, 420, 450, 500, or 550 windows (e.g., tintable windows). The windows may be divided into zones (e.g., based at least in part on the location, façade, floor, ownership, utilization of the enclosure (e.g., room) in which they are disposed, any other assignment metric, random assignment, or any combination thereof. Allocation of windows to the zone may be static or dynamic (e.g., based on a heuristic). There may be at least about 2, 5, 10, 12, 15, 30, 40, or 46 windows per zone. The facility may comprise a commercial or a residential building. The residential facility may comprise a multi or a single family building.

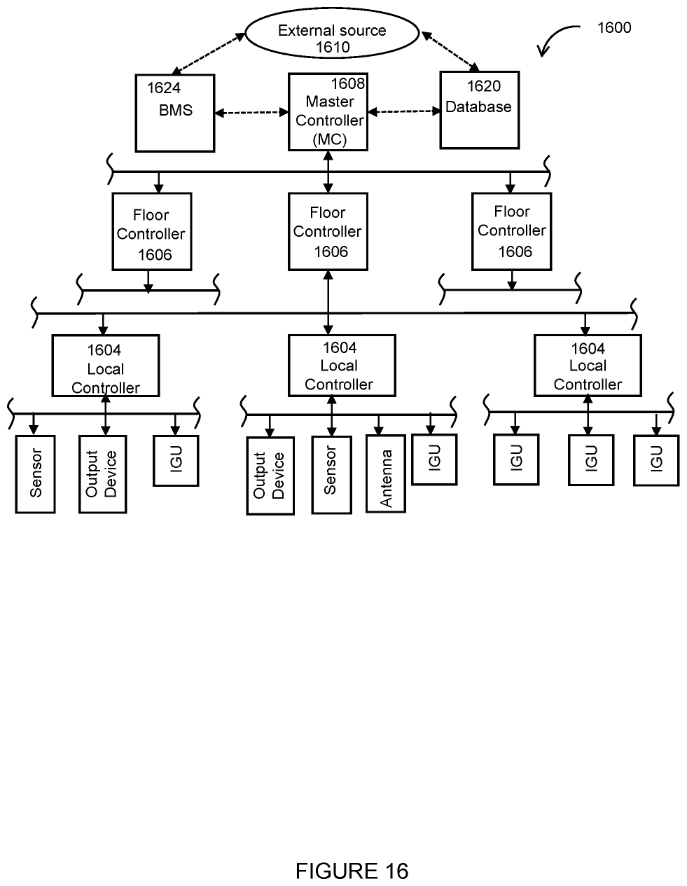

In some embodiments, the sensor(s) are operatively coupled to at least one controller and/or processor. Sensor readings may be obtained by one or more processors and/or controllers. A controller may comprise a processing unit (e.g., CPU or GPU). A controller may receive an input (e.g., from at least one sensor). The controller may include circuitry, electrical wiring, optical wiring, socket, and/or outlet. A controller may deliver an output. A controller may comprise multiple (e.g., sub-) controllers. The controller may be a part of a control system. A control system may comprise a master controller, floor (e.g., comprising network controller) controller, or a local controller. The local controller may be a window controller (e.g., controlling an optically switchable window), enclosure controller, or component controller. The controller can be a device controller (e.g., any device disclosed herein). For example, a controller may be a part of a hierarchal control system (e.g., comprising a main controller that directs one or more controllers, e.g., floor controllers, local controllers (e.g., window controllers), enclosure controllers, and/or component controllers). A physical location of the controller type in the hierarchal control system may be changing. For example, at a first time: a first processor may assume a role of a main controller, a second processor may assume a role of a floor controller, and a third processor may assume the role of a local controller. At a second time: the second processor may assume a role of a main controller, the first processor may assume a role of a floor controller, and the third processor may remain with the role of a local controller. At a third time: the third processor may assume a role of a main controller, the second processor may assume a role of a floor controller, and the first processor may assume the role of a local controller. A controller may control one or more devices (e.g., be directly coupled to the devices). A controller may be disposed proximal to the one or more devices it is controlling. For example, a controller may control an optically switchable device (e.g., IGU), an antenna, a sensor, and/or an output device (e.g., a light source, sounds source, smell source, gas source, HVAC outlet, or heater). In one embodiment, a floor controller may direct one or more window controllers, one or more enclosure controllers, one or more component controllers, or any combination thereof. The floor controller may comprise a floor controller. For example, the floor (e.g., comprising network) controller may control a plurality of local (e.g., comprising window) controllers. A plurality of local controllers may be disposed in a portion of a facility (e.g., in a portion of a building). The portion of the facility may be a floor of a facility. For example, a floor controller may be assigned to a floor. In some embodiments, a floor may comprise a plurality of floor controllers, e.g., depending on the floor size and/or the number of local controllers coupled to the floor controller. For example, a floor controller may be assigned to a portion of a floor. For example, a floor controller may be assigned to a portion of the local controllers disposed in the facility. For example, a floor controller may be assigned to a portion of the floors of a facility. A master controller may be coupled to one or more floor controllers. The floor controller may be disposed in the facility. The master controller may be disposed in the facility, or external to the facility. The master controller may be disposed in the cloud. A controller may be a part of, or be operatively coupled to, a building management system. A controller may receive one or more inputs. A controller may generate one or more outputs. The controller may be a single input single output controller (SISO) or a multiple input multiple output controller (MIMO). A controller may interpret an input signal received. A controller may acquire data from the one or more components (e.g., sensors). Acquire may comprise receive or extract. The data may comprise measurement, estimation, determination, generation, or any combination thereof. A controller may comprise feedback control. A controller may comprise feed-forward control. Control may comprise on-off control, proportional control, proportional-integral (PI) control, or proportional-integral-derivative (PID) control. Control may comprise open loop control, or closed loop control. A controller may comprise closed loop control. A controller may comprise open loop control. A controller may comprise a user interface. A user interface may comprise (or operatively coupled to) a keyboard, keypad, mouse, touch screen, microphone, speech recognition package, camera, imaging system, or any combination thereof. Outputs may include a display (e.g., screen), speaker, or printer. FIG. 16 shows an example of a control system architecture 1600 comprising a master controller 1608 that controls floor controllers 1606, that in turn control local controllers 1604. In some embodiments, a local controller controls one or more IGUs, one or more sensors, one or more output devices (e.g., one or more emitters), or any combination thereof. FIG. 16 shows an example of a configuration in which the master controller is operatively coupled (e.g., wirelessly and/or wired) to a building management system (BMS) 1624 and to a database 1620. Arrows in FIG. 16 represents communication pathways. A controller may be operatively coupled (e.g., directly/indirectly and/or wired and/wirelessly) to an external source 1610. The external source may comprise a network. The external source may comprise one or more sensor or output device. The external source may comprise a cloud-based application and/or database. The communication may be wired and/or wireless. The external source may be disposed external to the facility. For example, the external source may comprise one or more sensors and/or antennas disposed, e.g., on a wall or on a ceiling of the facility. The communication may be monodirectional or bidirectional. In the example shown in FIG. 16, the communication all communication arrows are meant to be bidirectional. The local controller 1604 may be (e.g., directly) operatively coupled to any of the targets (e.g., devices) disclosed herein. Directly operatively coupled refers to an absence of any other controller therebetween. The control system 1600 may be operatively coupled to any of the targets (e.g., devices) disclosed herein.

In some embodiments, a BMS is disposed in a facility. The facility can comprise a building such as a multistory building. The BMS may functions at least to control the environment in the building. The control system and/or BMS may control at least one environmental characteristic of the enclosure. The at least one environmental characteristic may comprise temperature, humidity, fine spray (e.g., aerosol), sound, electromagnetic waves (e.g., light glare, color), gas makeup, gas concentration, gas speed, vibration, volatile compounds (VOCs), debris (e.g., dust), or biological matter (e.g., gas borne bacteria and/or virus). The gas(es) may comprise oxygen, nitrogen, carbon dioxide, carbon monoxide, hydrogen sulfide, Nitric oxide (NO) and nitrogen dioxide (NO₂), inert gas, Nobel gas (e.g., radon), cholorophore, ozone, formaldehyde, methane, or ethane. For example, a BMS may control temperature, carbon dioxide levels, and/or humidity within an enclosure. Mechanical devices that can be controlled by a BMS and/or control system may comprise lighting, a heater, air conditioner, blower, or vent. To control the enclosure (e.g., building) environment, a BMS and/or control system may turn on and off one or more of the devices it controls, e.g., under defined conditions. A (e.g., core) function of a BMS and/or control system may be to maintain a comfortable environment for the occupants of the enclosure, e.g., while minimizing energy consumption (e.g., while minimizing heating and cooling costs/demand). A BMS and/or control system can be used to control (e.g., monitor), and/or to optimize the synergy between various systems, for example, to conserve energy and/or lower enclosure (e.g., facility) operation costs.

The controller may monitor and/or direct (e.g., physical) alteration of the operating conditions of the apparatuses, software, and/or methods described herein. Control may comprise regulate, manipulate, restrict, direct, monitor, adjust, modulate, vary, alter, restrain, check, guide, or manage. Controlled (e.g., by a controller) may include attenuated, modulated, varied, managed, curbed, disciplined, regulated, restrained, supervised, manipulated, and/or guided. The control may comprise controlling a control variable (e.g., temperature, power, voltage, and/or profile). The control can comprise real time or off-line control. A calculation utilized by the controller can be done in real time, and/or off-line. The controller may be a manual or a non-manual controller. The controller may be an automatic controller. The controller may operate upon request. The controller may be a programmable controller. The controller may be programed. The controller may comprise a processing unit (e.g., CPU or GPU). The controller may receive an input (e.g., from at least one sensor). The controller may deliver an output. The controller may comprise multiple (e.g., sub-) controllers. The controller may be a part of a control system. The control system may comprise a master controller, floor controller, local controller (e.g., enclosure controller, or window controller). The controller may receive one or more inputs. The controller may generate one or more outputs. The controller may be a single input single output controller (SISO) or a multiple input multiple output controller (MIMO). The controller may interpret the input signal received. The controller may acquire data from the one or more sensors. Acquire may comprise receive or extract. The data may comprise measurement, estimation, determination, generation, or any combination thereof. The controller may comprise feedback control. The controller may comprise feed-forward control. The control may comprise on-off control, proportional control, proportional-integral (PI) control, or proportional-integral-derivative (PID) control. The control may comprise open loop control, or closed loop control. The controller may comprise closed loop control. The controller may comprise open loop control. The controller may comprise a user interface. The user interface may comprise (or operatively coupled to) a keyboard, keypad, mouse, touch screen, microphone, speech recognition package, camera, imaging system, or any combination thereof. The outputs may include a display (e.g., screen), speaker, or printer.

The methods, systems and/or the apparatus described herein may comprise a control system. The control system can be in communication with any of the apparatuses (e.g., sensors) described herein. The sensors may be of the same type or of different types, e.g., as described herein. For example, the control system may be in communication with the first sensor and/or with the second sensor. The control system may control the one or more sensors. The control system may control one or more components of a building management system (e.g., lightening, security, and/or air conditioning system). The controller may regulate at least one (e.g., environmental) characteristic of the enclosure. The control system may regulate the enclosure environment using any component of the building management system. For example, the control system may regulate the energy supplied by a heating element and/or by a cooling element. For example, the control system may regulate velocity of an air flowing through a vent to and/or from the enclosure. The control system may comprise a processor. The processor may be a processing unit. The controller may comprise a processing unit. The processing unit may be central. The processing unit may comprise a central processing unit (abbreviated herein as “CPU”). The processing unit may be a graphic processing unit (abbreviated herein as “GPU”). The controller(s) or control mechanisms (e.g., comprising a computer system) may be programmed to implement one or more methods of the disclosure. The processor may be programmed to implement methods of the disclosure. The controller may control at least one component of the forming systems and/or apparatuses disclosed herein.

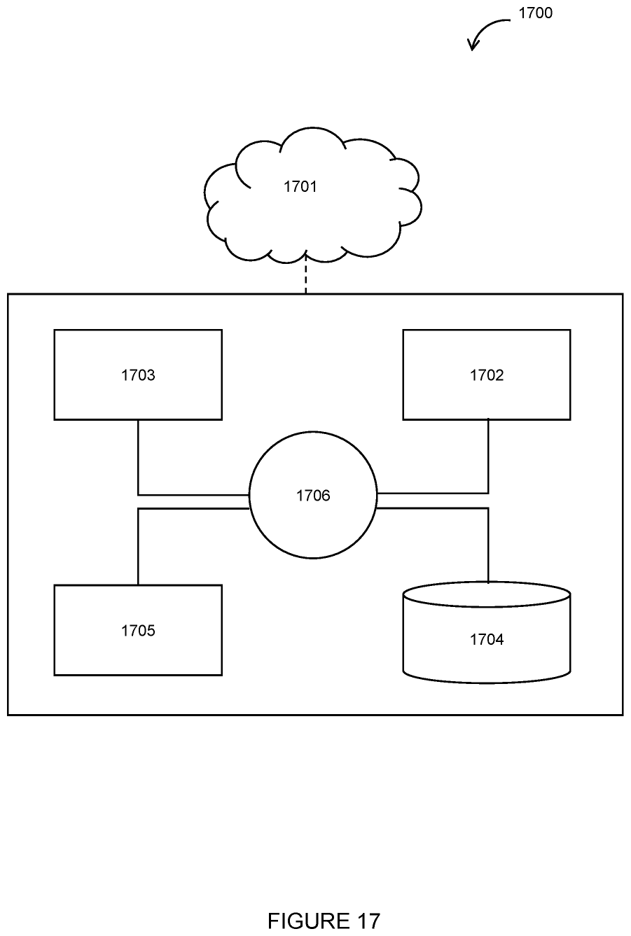

FIG. 17 shows a schematic example of a computer system 1700 that is programmed or otherwise configured to one or more operations of any of the methods provided herein. The computer system can control (e.g., direct, monitor, and/or regulate) various features of the methods, apparatuses, and systems of the present disclosure, such as, for example, control heating, cooling, lightening, and/or venting of an enclosure, or any combination thereof. The computer system can be part of, or be in communication with, any sensor or sensor ensemble disclosed herein. The computer may be coupled to one or more mechanisms disclosed herein, and/or any parts thereof. For example, the computer may be coupled to one or more sensors, valves, switches, lights, windows (e.g., IGUs), motors, pumps, optical components, or any combination thereof.

The computer system can include a processing unit (e.g., 1706) (also “processor,” “computer” and “computer processor” used herein). The computer system may include memory or memory location (e.g., 1702) (e.g., random-access memory, read-only memory, flash memory), electronic storage unit (e.g., 1704) (e.g., hard disk), communication interface (e.g., 1703) (e.g., network adapter) for communicating with one or more other systems, and peripheral devices (e.g., 1705), such as cache, other memory, data storage and/or electronic display adapters. In the example shown in FIG. 17, the memory 1702, storage unit 1704, interface 1703, and peripheral devices 1705 are in communication with the processing unit 1706 through a communication bus (solid lines), such as a motherboard. The storage unit can be a data storage unit (or data repository) for storing data. The computer system can be operatively coupled to a computer network (“network”) (e.g., 1701) with the aid of the communication interface. The network can be the Internet, an internet and/or extranet, or an intranet and/or extranet that is in communication with the Internet. In some cases, the network is a telecommunication and/or data network. The network can include one or more computer servers, which can enable distributed computing, such as cloud computing. The network, in some cases with the aid of the computer system, can implement a peer-to-peer network, which may enable devices coupled to the computer system to behave as a client or a server.

The processing unit can execute a sequence of machine-readable instructions, which can be embodied in a program or software. The instructions may be stored in a memory location, such as the memory 1702. The instructions can be directed to the processing unit, which can subsequently program or otherwise configure the processing unit to implement methods of the present disclosure. Examples of operations performed by the processing unit can include fetch, decode, execute, and write back. The processing unit may interpret and/or execute instructions. The processor may include a microprocessor, a data processor, a central processing unit (CPU), a graphical processing unit (GPU), a system-on-chip (SOC), a co-processor, a network processor, an application specific integrated circuit (ASIC), an application specific instruction-set processor (ASIPs), a controller, a programmable logic device (PLD), a chipset, a field programmable gate array (FPGA), or any combination thereof. The processing unit can be part of a circuit, such as an integrated circuit. One or more other components of the system 1800 can be included in the circuit.

The storage unit can store files, such as drivers, libraries and saved programs. The storage unit can store user data (e.g., user preferences and user programs). In some cases, the computer system can include one or more additional data storage units that are external to the computer system, such as located on a remote server that is in communication with the computer system through an intranet or the Internet.

The processing unit (e.g., computer system) can communicate with one or more remote computer systems through a network. For instance, the computer system can communicate with a remote computer system of a user (e.g., operator). Examples of remote computer systems include personal computers (e.g., portable PC), slate or tablet PC's (e.g., Apple® iPad, Samsung® Galaxy Tab), telephones, Smart phones (e.g., Apple® iPhone, Android-enabled device, Blackberry®), or personal digital assistants. A user can access the computer system via the network. The processing unit may comprise a CPU or a GPU. The processing unit may comprise a media player. The processing unit may be included in a circuit board. The circuit board may comprise a Jetson Nano™ Developer Kit by NVIDIA®, (e.g., 2 GB or 4 GB developer kit) or Raspberry-Pi kit (e.g., 1 GB, 2 GB, 4 GB, or 8 GB developer kit). The processing unit may be operatively coupled to a plurality of ports comprising at least one media port (e.g., a DisplayPort, HDMI, and/or micro-HDMI), USB, or an audio-video jack, e.g., that may be included in the circuit board. The processing unit may be operatively coupled to a Camera Serial Interface (CSI), or a Display Serial Interface (DSI), e.g., as part of the circuit board. The processing unit is configured to support communication such as ethernet (e.g., Gigabit Ethernet). The circuitry board may comprise a Wi-Fi functionality, a Bluetooth functionality, or a wireless adapter. The wireless adapter may be configured to comply with a wireless networking standard in the 802.11 set of protocols (e.g., USB 802.11ac). The wireless adapter may be configured to provide a high-throughput wireless local area networks (WLANs), e.g., on at least about a 5 GHz band. The USB port may have a transfer speed of at least about 480 megabits per second (Mbps), 4,800 Mbps, or 10,000 Mbps. The at least one processor may comprise a synchronous (e.g., clocked) processor. The clock speed of the processor may be of at least about 1.2 GigaHertz (GHz), 1.3 GHz, 1.4 GHz, 1.5 GHz, or 1.6 GHz. The processing unit may comprise a random access memory (RAM). The RAM may comprise a double data rate synchronous dynamic RAM (SDRAM). The RAM may be configured for mobile devices (e.g., laptop, pad, or mobile phone such as cellular phone). The RAM may comprise a Low-Power Double Data Rate (LPDDR) RAM. The RAM may be configured to permit a channel that is at least about 16, 32, or 64 bit wide. A user (e.g., client) can access the computer system via the network.

Methods as described herein can be implemented by way of machine (e.g., computer processor) executable code stored on an electronic storage location of the computer system, such as, for example, on the memory 1702 or electronic storage unit 1704. The machine executable or machine-readable code can be provided in the form of software. During use, the processor 1706 can execute the code. In some cases, the code can be retrieved from the storage unit and stored on the memory for ready access by the processor. In some situations, the electronic storage unit can be precluded, and machine-executable instructions are stored on memory.

The code can be pre-compiled and configured for use with a machine have a processer adapted to execute the code or can be compiled during runtime. The code can be supplied in a programming language that can be selected to enable the code to execute in a pre-compiled or as-compiled fashion.

In some embodiments, the processor comprises a code. The code can be program instructions. The program instructions may cause the at least one processor (e.g., computer) to direct a feed forward and/or feedback control loop. In some embodiments, the program instructions cause the at least one processor to direct a closed loop and/or open loop control scheme. The control may be based at least in part on one or more sensor readings (e.g., sensor data). One controller may direct a plurality of operations. At least two operations may be directed by different controllers. In some embodiments, a different controller may direct at least two of operations (a), (b) and (c). In some embodiments, different controllers may direct at least two of operations (a), (b) and (c). In some embodiments, a non-transitory computer-readable medium cause each a different computer to direct at least two of operations (a), (b) and (c). In some embodiments, different non-transitory computer-readable mediums cause each a different computer to direct at least two of operations (a), (b) and (c). The controller and/or computer readable media may direct any of the apparatuses or components thereof disclosed herein. The controller and/or computer readable media may direct any operations of the methods disclosed herein.

In some embodiments, the at least one sensor is operatively coupled to a control system (e.g., computer control system). The sensor may comprise light sensor, acoustic sensor, vibration sensor, chemical sensor, electrical sensor, magnetic sensor, fluidity sensor, movement sensor, speed sensor, position sensor, pressure sensor, force sensor, density sensor, distance sensor, or proximity sensor. The sensor may include temperature sensor, weight sensor, material (e.g., powder) level sensor, metrology sensor, gas sensor, or humidity sensor. The metrology sensor may comprise measurement sensor (e.g., height, length, width, angle, and/or volume). The metrology sensor may comprise a magnetic, acceleration, orientation, or optical sensor. The sensor may transmit and/or receive sound (e.g., echo), magnetic, electronic, or electromagnetic signal. The electromagnetic signal may comprise a visible, infrared, ultraviolet, ultrasound, radio wave, or microwave signal. The gas sensor may sense any of the gas delineated herein. The distance sensor can be a type of metrology sensor. The distance sensor may comprise an optical sensor, or capacitance sensor. The temperature sensor can comprise Bolometer, Bimetallic strip, calorimeter, Exhaust gas temperature gauge, Flame detection, Gardon gauge, Golay cell, Heat flux sensor, Infrared thermometer, Microbolometer, Microwave radiometer, Net radiometer, Quartz thermometer, Resistance temperature detector, Resistance thermometer, Silicon band gap temperature sensor, Special sensor microwave/imager, Temperature gauge, Thermistor, Thermocouple, Thermometer (e.g., resistance thermometer), or Pyrometer. The temperature sensor may comprise an optical sensor. The temperature sensor may comprise image processing. The temperature sensor may comprise a camera (e.g., IR camera, CCD camera). The pressure sensor may comprise Barograph, Barometer, Boost gauge, Bourdon gauge, Hot filament ionization gauge, Ionization gauge, McLeod gauge, Oscillating U-tube, Permanent Downhole Gauge, Piezometer, Pirani gauge, Pressure sensor, Pressure gauge, Tactile sensor, or Time pressure gauge. The position sensor may comprise Auxanometer, Capacitive displacement sensor, Capacitive sensing, Free fall sensor, Gravimeter, Gyroscopic sensor, Impact sensor, Inclinometer, Integrated circuit piezoelectric sensor, Laser rangefinder, Laser surface velocimeter, LIDAR, Linear encoder, Linear variable differential transformer (LVDT), Liquid capacitive inclinometers, Odometer, Photoelectric sensor, Piezoelectric accelerometer, Rate sensor, Rotary encoder, Rotary variable differential transformer, Selsyn, Shock detector, Shock data logger, Tilt sensor, Tachometer, Ultrasonic thickness gauge, Variable reluctance sensor, or Velocity receiver. The optical sensor may comprise a Charge-coupled device, Colorimeter, Contact image sensor, Electro-optical sensor, Infra-red sensor, Kinetic inductance detector, light emitting diode (e.g., light sensor), Light-addressable potentiometric sensor, Nichols radiometer, Fiber optic sensor, Optical position sensor, Photo detector, Photodiode, Photomultiplier tubes, Phototransistor, Photoelectric sensor, Photoionization detector, Photomultiplier, Photo resistor, Photo switch, Phototube, Scintillometer, Shack-Hartmann, Single-photon avalanche diode, Superconducting nanowire single-photon detector, Transition edge sensor, Visible light photon counter, or Wave front sensor. The one or more sensors may be connected to a control system (e.g., to a processor, to a computer).

While preferred embodiments of the present invention have been shown, and described herein, it will be obvious to those skilled in the art that such embodiments are provided by way of example only. It is not intended that the invention be limited by the specific examples provided within the specification. While the invention has been described with reference to the afore-mentioned specification, the descriptions and illustrations of the embodiments herein are not meant to be construed in a limiting sense. Numerous variations, changes, and substitutions will now occur to those skilled in the art without departing from the invention. Furthermore, it shall be understood that all aspects of the invention are not limited to the specific depictions, configurations, or relative proportions set forth herein which depend upon a variety of conditions and variables. It should be understood that various alternatives to the embodiments of the invention described herein might be employed in practicing the invention. It is therefore contemplated that the invention shall also cover any such alternatives, modifications, variations, or equivalents. It is intended that the following claims define the scope of the invention and that methods and structures within the scope of these claims and their equivalents be covered thereby.

### Example Embodiments

Clause 1: A method of routing signals in a facility, the method comprising: identifying small cell devices and Radio Access Units (RAUs) operatively coupled to a network of the facility; receiving one or more inputs through the network; determining a configuration for routing cellular communication signals between one or more of the small cell devices and one or more of the RAUs, which configuration is based at least in part on the one or more inputs; and routing the cellular communication signals between the one or more of the small cell devices and the one or more of the RAUs based at least in part on the configuration.
Clause 2: The method of clause 1, wherein the small cell devices are disposed in the facility.
Clause 3: The method of any one of clauses 1 or 2, wherein the RAUs are disposed in the facility.
Clause 4: The method of any one of clauses 1-3, wherein the network is operatively coupled to one or more sensors of the facility.
Clause 5: The method of clause 4, wherein the one or more sensors are disposed in the facility.
Clause 6: The method of clause 4, wherein the one or more sensors are disposed outside of the facility.
Clause 7: The method of clause 4, wherein the one or more sensors are attached to the facility.
Clause 8: The method of any one of clauses 1-7, wherein the network comprises cabling.
Clause 9: The method of clause 8, wherein the cabling comprises optical cabling and/or coaxial cabling.
Clause 10: The method of any one of clauses 8 or 9, wherein a cable of the cabling is configured to transmit electrical power and communication signals.
Clause 11: The method of any one of clauses 8-10, wherein a cable of the cabling is configured to transmit electrical power, cellular communication signals, and communication signals of at least one other communication type.
Clause 12: The method of any one of clauses 8-11, wherein a cable of the cabling is disposed at least in part in an envelope of the facility.
Clause 13: The method of any one of clauses 8-12, wherein the facility comprises a building.
Clause 14: The method of clause 13, wherein a cable of the cabling is disposed at least in part in an envelope of the building.
Clause 15: The method of any one of clauses 8-14, wherein the cabling is a first cabling system installed in the facility.
Clause 16: The method of any one of clauses 11-15, wherein the at least one other communication type comprises media communication, control communication, or data communication.
Clause 17: The method of clause 16, wherein the data communication comprises communication of sensor data.
Clause 18: The method of any one of clauses 1-17, wherein the one or more inputs are associated with an occupancy of personnel in the facility.
Clause 19: The method of any one of clauses 1-18, wherein the one or more inputs comprise scheduling information, occupancy information, sensor data, or any combination thereof.
Clause 20: The method of clause 19, wherein the sensor data comprises electromagnetic radiation data.
Clause 21: The method of clause 20, wherein the electromagnetic radiation data comprises data associated with electromagnetic radiation in a visual spectrum, an infrared spectrum, a radio frequency spectrum, or any combination thereof.
Clause 22: The method of any one of clauses 20 or 21, wherein the electromagnetic radiation data comprises data associated with ultrawideband radiation.
Clause 23: The method of any one of clauses 19-22, wherein the sensor data comprises geolocation signals.
Clause 24: The method of clause 23, wherein the geolocation signals comprise Global Positioning System signals, ultrawideband signals, short-range wireless signal, or any combination thereof.
Clause 25: The method of any one of clauses 19-24, wherein the sensor data comprises heat signatures associated with one or more personnel.
Clause 26: The method of any one of clauses 1-25, wherein the configuration is dynamically determined.
Clause 27: The method of any one of clauses 1-26, wherein the configuration is determined in real-time during receipt of the cellular communication signals.
Clause 28: The method of any one of clauses 1-27, wherein the network is operatively coupled to one or more controllers.
Clause 29: The method of clause 28, wherein the one or more controllers are part of a hierarchical control system.
Clause 30: The method of any one of clauses 28 or 29, wherein the one or more controllers are configured to control at least one device.
Clause 31: The method of clause 30, wherein the at least one device includes (i) a service device, (ii) a safety device, (iii) a security device, and/or (iv) a health device.
Clause 32: The method of clause 31, wherein the service device comprises a media player, a media display, a radio, a music player, a heater, a cooler, a ventilator, lighting, a tintable window, an automatic door, or a heating, ventilation, and air conditioning (HVAC) system.
Clause 33: The method of any one of clauses 31 or 32, wherein the service device is configured to adjust an environment of the facility.
Clause 34: The method of any one of clauses 31-33, wherein the safety device comprises an alarm, an announcement system, alarm lighting, a sensor, a door, a window, or a lock.
Clause 35: The method of clause 34, wherein the door, window, and/or lock, are automatic.
Clause 36: The method of any one of clauses 30-35, wherein the at least one device comprises a sensor.
Clause 37: The method of clause 36, wherein the sensor includes a temperature sensor, a motion sensor, a pressure sensor, an infrared sensor, a visual sensor, and/or an occupancy sensor.
Clause 38: The method of any one of clauses 31-37, wherein the health device comprises a glucose monitor, a heart rate monitor, a blood pressure monitor, a temperature sensor, an infrared sensor, an ultraviolet sensor, or a visual sensor.
Clause 39: The method of any one of clauses 31-38, wherein the service device includes a processor, or a media display.
Clause 40: The method of clause 39, wherein the media display comprises a television screen or a computer monitor.
Clause 41: The method of any one of clauses 30-40, wherein the at least one device is disposed in a device ensemble.
Clause 42: The method of clause 41, wherein the device ensemble comprises (i) sensors or (ii) a sensor and an emitter.
Clause 43: The method of any one of clauses 41 or 42, wherein the device ensemble is affixed to, or disposed in, a fixture of the facility.
Clause 44: The method of any one of clauses 1-43, wherein the cellular communication signals arrive at the small cell devices directly from a service provider.
Clause 45: The method of any one of clauses 1-44, wherein the configuration dynamically routes the cellular communication signals based at least in part on occupancy in one or more portions of the facility.
Clause 46: The method of any one of clauses 1-45, wherein the configuration is based at least in part on an occupancy in the facility.
Clause 47: The method of any one of clauses 1-46, wherein the configuration is based at least in part on an occupancy of users of the cellular communication signals in the facility.
Clause 48: The method of any one of clauses 1-47, wherein routing the cellular communication signals between the one or more of the small cell devices and the one or more of the RAUs based at least in part on the configuration comprises transmitting information indicating the configuration to a router associated with the facility, the router configurable to carry out routing of the cellular communication signals between the one or more of the small cell devices and the one or more of the RAUs.
Clause 49: The method of any one of clauses 1-48, wherein the cellular communication signals are modulated.
Clause 50: An apparatus for routing signals in a facility, the apparatus comprising at least one controller configured to execute, or direct execution of, one or more operations of any of the methods of clauses 1 to 49.
Clause 51: The apparatus of clause 50, wherein the at least one controller comprises circuitry.
Clause 52: The apparatus of any one of clauses 50 or 51, wherein at least two of the one or more operations are executed by a controller of the at least one controller.
Clause 53: The apparatus of any one of clauses 50-52, wherein at least two of the one or more operations are each executed by a different controllers of the at least one controller.
Clause 54: An apparatus for routing signals in a facility, the apparatus comprising at least one controller, which at least one controller is configured to: operatively couple (i) to small cell devices and (ii) to Radio Access Units (RAUs), which are operatively coupled to a network of the facility; receive, or direct receipt of, one or more inputs through the network; determine, or direct determination of, a configuration for routing cellular communication signals between one or more of the small cell devices and one or more of the RAUs, which configuration is based at least in part on the one or more inputs; and route, or direct routing of, the cellular communication signals between the one or more of the small cell devices and the one or more of the RAUs based at least in part on the configuration.
Clause 55: The apparatus of clause 54, wherein the at least one controller is configured to direct a device.
Clause 56: The apparatus of any one of clauses 54 or 55, wherein the at least one controller is part of a distributed network of controllers in which one controller is configured to direct an other controller.
Clause 57: The apparatus of clause 56, wherein the one controller and the other controller are part of the distributed network of controllers.
Clause 58: The apparatus of any one of clauses 56 or 57, wherein the distributed network of controllers is a hierarchical network of controllers.
Clause 59: A non-transitory computer program instructions for routing signals in a facility, the non-transitory computer program instructions, when read by one or more processors, causes the one or more processors to execute, or direct execution of, one or more operations of any of the methods of clauses 1 to 49.
Clause 60: The non-transitory computer program instructions of clause 59, wherein the program instructions are embedded in at least one program product.
Clause 61: The non-transitory computer program instructions of any one of clauses 59 or 60, wherein the program instructions are embedded in a medium or in media.
Clause 62: The non-transitory computer program instructions of any one of clauses 59-61, wherein at least two of the one or more operations are executed by a processor of the one or more processors.
Clause 63: The non-transitory computer program instructions of any one of clauses 59-62, wherein at least two of the one or more operations are each executed by a different processor of the one or more processors.
Clause 64: A non-transitory computer readable program instructions for routing signals in a facility, the non-transitory computer readable program instructions, when read by one or more processors, causes the one or more processors to execute operations comprising: receiving, or directing receipt of, one or more inputs through the network; determining, or directing determination of, a configuration for routing cellular communication signals between one or more of the small cell devices and one or more of the RAUs, which configuration is based at least in part on the one or more inputs; and routing the cellular communication signals between the one or more of the small cell devices and the one or more of the RAUs based at least in part on the configuration, wherein the one or more processors are operatively coupled (i) to the small cell devices and (ii) to the Radio Access Units (RAUs), which are operatively coupled to the network of the facility.
Clause 65: The non-transitory computer readable program instructions of clause 64, wherein the one or more processors are configured to direct a device.
Clause 66: The non-transitory computer readable program instructions of any one of clauses 64 or 65, wherein the one or more processors are part of a distributed network of processors in which one processor is configured to direct an other processor.
Clause 67: The non-transitory computer readable program instructions of clause 66, wherein the one processors and the other processor are part of the distributed network of processors.
Clause 68: The non-transitory computer readable program instructions of any one of clauses 66 or 67, wherein the distributed network of processors is a hierarchical network of processors.
Clause 69: A system for routing signals in a facility, the system comprises a network disposed in the facility; one or more small cell devices operatively coupled to the network; and one or more RAUs operatively coupled to the network; which network is configured to facilitate one or more operations of any of the methods of clauses 1 to 49.
Clause 70: The system of clause 69, wherein the network is configured to facilitate control at least in part by being configured to transmit control related communication.
Clause 71: The system of any one of clauses 69 or 70, wherein the network is configured to facilitate the one or more operations at least in part by being configured to transmit communication of one or more protocols associated with the one or more operations.
Clause 72: A system for routing signals in a facility, the system comprising: a network disposed in the facility; one or more small cell devices operatively coupled to the network; one or more RAUs operatively coupled to the network; which network is configured to facilitate: transmission of one or more inputs; determination of a configuration for routing cellular communication signals between one or more of the small cell devices and one or more of the RAUs, which configuration is based at least in part on the one or more inputs; and routing the cellular communication signals to be routed between the one or more small cell devices and the one or more RAUs based at least in part on the configuration.
Clause 73: The system of clause 72, wherein the network is configured to facilitate transmission of the one or more inputs, determination of the configuration, and routing the cellular communication signals at least in part by being configured to transmit appropriate signals confirming to respective protocols.
Clause 74: A method of changing communications characteristics in a facility, the method comprising: obtaining a configuration for routing signals between one or more small cell devices associated with the facility and one or more Radio Access Units (RAUs) associated with the facility; obtaining usage information associated with the facility, wherein the usage information indicates current or expected small cell device usage by mobile devices associated with the facility; determining one or more parameters associated with: (I) a channel sharing protocol for two or more small cell devices allocated to an RAU of the one or more RAUs based at least in part on the configuration, (II) transmit or receive power specifications for one or more components associated with the facility based at least in part on the usage information, or (III) any combination thereof; and providing the one or more parameters associated with: (i) the channel sharing protocol to the two or more small cell devices, (ii) the transmit or receive power specifications to the one or more components associated with the facility, or (iii) any combination thereof.
Clause 75: The method of clause 74, wherein the one or more small cell devices are disposed in the facility.
Clause 76: The method of any one of clauses 74 or 75, wherein the one or more RAUs are disposed in the facility.
Clause 77: The method of any one of clauses 74-76, wherein the usage information is based on data from one or more sensors of the facility.
Clause 78: The method of clause 77, wherein the one or more sensors are disposed in the facility.
Clause 79: The method of any one of clauses 77 or 78, wherein the one or more sensors are disposed outside the facility.
Clause 80: The method of any one of clauses 77-79, wherein the one or more sensors are attached to the facility.
Clause 81: The method of any one of clauses 77-80, wherein the one or more sensors provide sensor data comprising electromagnetic radiation data.
Clause 82: The method of clause 81, wherein the electromagnetic radiation data comprises data associated with electromagnetic radiation in a visual spectrum, an infrared spectrum, a radio frequency spectrum, or any combination thereof.
Clause 83: The method of any one of clauses 81 or 82, wherein the electromagnetic radiation data comprises data associated with ultrawideband radiation.
Clause 84: The method of any one of clauses 77-83, wherein the one or more sensors provide sensor data comprising geolocation signals.
Clause 85: The method of clause 84, wherein the geolocation signals comprise Global Positioning System signals, ultrawideband signals, short-range wireless signal, or any combination thereof.
Clause 86: The method of any one of clauses 77-85, wherein the one or more sensors provide sensor data comprising heat signatures associated with one or more personnel.
Clause 87: The method of any one of clauses 74-86, wherein the facility comprises a building.
Clause 88: The method of any one of clauses 74-87, wherein the usage information is received via a network associated with the facility.
Clause 89: The method of clause 88, wherein the network comprises cabling.
Clause 90: The method of clause 89, wherein the cabling comprises optical cabling and/or coaxial cabling.
Clause 91: The method of any one of clauses 89 or 90, wherein a cable of the cabling is disposed at least in part in an envelope of a building of the facility.
Clause 92: The method of any one of clauses 74-91, wherein the usage information comprises scheduling information, occupancy information, or any combination thereof.
Clause 93: The method of clause 92, wherein the scheduling information comprises calendar information associated with the facility.
Clause 94: The method of clause 93, wherein the calendar information indicates scheduled events at one or more locations of the facility.
Clause 95: The method of any one of clauses 92-94, wherein the occupancy information comprises current occupancy at one or more locations of the facility.
Clause 96: The method of any one of clauses 92-95, wherein the occupancy information comprises a future occupancy at one or more locations of the facility.
Clause 97: The method of clause 96, wherein the future occupancy is predicted by a machine learning model trained to predict the future occupancy at the one or more locations of the facility.
Clause 98: The method of any one of clauses 74-97, wherein the one or more parameters are determined based on a noise level in the facility.
Clause 99: The method of clause 98, wherein the noise level in the facility is based on current or planned construction in the facility.
Clause 100: The method of any one of clauses 74-99, wherein determining the one or more parameters associated with the channel sharing protocol comprises determining two or more channels corresponding to the two or more small cell devices allocated to the one RAU.
Clause 101: The method of clause 100, wherein the channel sharing protocol comprises Frequency Division Multiple Access (FDMA).
Clause 102: The method of any one of clauses 74-101, wherein the one or more components comprise a headend router associated with the facility, one or more of the one or more RAUs, one or more antennas operatively coupled to the one or more RAUs, or any combination thereof.
Clause 103: An apparatus for changing communications characteristics in a facility, the apparatus comprising at least one controller configured to execute, or direct execution of, one or more operations of any of the methods of clauses 74 to 102.
Clause 104: An apparatus for changing communications characteristics in a facility, the apparatus comprising at least one controller, which at least one controller is configured to: obtain, or direct obtainment of, a configuration for routing signals between one or more small cell devices associated with the facility and one or more Radio Access Units (RAUs) associated with the facility; obtain, or direct obtainment of, usage information associated with the facility, wherein the usage information indicates current or expected small cell device usage by mobile devices associated with the facility; determine, or direct determination of, one or more parameters associated with: (I) a channel sharing protocol for two or more small cell devices allocated to an RAU of the one or more RAUs based at least in part on the configuration, (II) transmit or receive power specifications for one or more components associated with the facility based at least in part on the usage information, or (III) any combination thereof; and provide, or direct provision of, the one or more parameters associated with: (i) the channel sharing protocol to the two or more small cell devices, (ii) the transmit or receive power specifications to the one or more components associated with the facility, or (iii) any combination thereof.
Clause 105: A non-transitory computer readable program instructions for changing communications characteristics in a facility, the non-transitory computer program instructions, when read by one or more processors, causes the one or more processors to execute, or direct execution of, one or more operations of any of the methods of clauses 74 to 102.
Clause 106: A non-transitory computer readable program instructions for changing communications characteristics in a facility, the non-transitory computer readable program instructions, when read by one or more processors, causes the one or more processors to execute operations comprising: obtaining, or directing obtainment of, usage information associated with the facility, wherein the usage information indicates current or expected small cell device usage by mobile devices associated with the facility; obtaining, or directing obtainment of, usage information associated with the facility, wherein the usage information indicates current or expected small cell device usage by mobile devices associated with the facility; determining, or directing determination of, one or more parameters associated with: (I) a channel sharing protocol for two or more small cell devices allocated to an RAU of the one or more RAUs based at least in part on the configuration, (II) power specifications for one or more components associated with the facility based at least in part on the usage information, or (III) any combination thereof; and providing, or directing provision of, the one or more parameters associated with: (i) the channel sharing protocol to the two or more small cell devices, (ii) the exchange of power specifications to the one or more components associated with the facility, or (iii) any combination thereof.
Clause 107: The non-transitory computer readable program instructions of clause 106, wherein the power specifications for the one or more components comprise a transmit power and/or a receive power.
Clause 108: A system for changing communication characteristics in a facility, the system comprising one or more small cell devices associated with the facility and one or more RAUs associated with the facility, and at least one controller configured to facilitate one or more operations of any of the methods of clauses 74 to 102.
Clause 109: A system for changing communication characteristics in a facility, the system comprising: a network disposed in the facility; one or more small cell devices operatively coupled to the network; one or more Radio Access Units (RAUs) operatively coupled to the network; which network is configured to facilitate: obtaining a configuration for routing signals between the one or more small cell devices associated with the facility and the one or more RAUs associated with the facility; obtaining usage information associated with the facility, wherein the usage information indicates current or expected small cell device usage by mobile devices associated with the facility; determining one or more parameters associated with: (I) a channel sharing protocol for two or more small cell devices allocated to an RAU of the one or more RAUs based at least in part on the configuration, (II) transmit or receive power specifications for one or more components associated with the facility based at least in part on the usage information, or (III) any combination thereof; and providing the one or more parameters associated with: (i) the channel sharing protocol to the two or more small cell devices, (ii) the transmit or receive power specifications to the one or more components associated with the facility, or (iii) any combination thereof.
Clause 110: The system of clause 109, wherein the network is configured to facilitate obtaining of the configuration, obtaining the usage information, determining the one or more parameters, and providing the one or more parameters, at least in part by being configured to transmit appropriate signals confirming to respective protocols.
Clause 111: A method of routing signals in a facility, the method comprising: receiving a configuration for routing cellular communication signals between small cell devices associated with the facility and Radio Access Units (RAUs) associated with the facility; and routing the cellular communication signals between one or more of the small cell devices and one or more of the RAUs, wherein routing the cellular communication signals between the one or more of the small cell devices and the one or more of the RAUs comprises: (A) receiving a downstream cellular communication signal from at least one of the one or more of the small cell devices; (B) manipulating the downstream cellular communication signal at least in part by splitting and/or combining the downstream cellular communication signal based at least in part on the configuration; and (C) routing the downstream cellular communication signal manipulated, to at least one RAU of the one or more of the RAUs based at least in part on the configuration; and/or (ii) (a) receiving an upstream cellular communication signal from at least one RAU of the one or more of the RAUs; (b) manipulating the upstream cellular communication signal by splitting and/or combining the upstream cellular communication signal based at least in part on the configuration; and (c) routing the manipulated upstream cellular communication signal to at least one of the one or more of the small cell devices based at least in part on the configuration.
Clause 112: The method of clause 111, wherein the downstream cellular communication signals have been modulated.
Clause 113: The method of clause 112, wherein the downstream cellular communication signal has been modulated to a baseband frequency or an Intermediate Frequency (IF) prior to routing to the at least one RAU.
Clause 114: The method of any one of clauses 111-113, wherein the upstream cellular communication signal has been modulated.
Clause 115: The method of clause 114, wherein the upstream cellular communication signal has been modulated to a baseband frequency or an Intermediate Frequency (IF) prior to routing to the one or more small cell devices.
Clause 116: The method of any one of clauses 111-115, wherein manipulating the downstream cellular communication signal comprises splitting the downstream cellular communication signal to a number of channels that corresponds to a number of RAUs to which the downstream cellular communication signal manipulated, is routed.
Clause 117: The method of any one of clauses 111-116, wherein manipulating the downstream cellular communication signal comprises combining downstream cellular communication signals from two or more small cell devices to one channel that is routed to a single RAU.
Clause 118: The method of any one of clauses 111-117, wherein manipulating the upstream cellular communication signal comprises splitting the upstream cellular communication signal from a single RAU to a number of channels that corresponds to a number of small cell devices to which the manipulated upstream cellular communication signal is routed.
Clause 119: The method of any one of clauses 111-118, wherein manipulating the upstream cellular communication signal comprises combining upstream cellular communication signals from two or more RAUs to one channel that is routed to a single small cell device.
Clause 120: The method of any one of clauses 111-119, wherein the small cell devices are disposed in the facility.
Clause 121: The method of any one of clauses 111-120, wherein the RAUs are disposed in the facility.
Clause 122: The method of any one of clauses 111-121, wherein the small cell devices and the RAUs are operatively coupled to a network of the facility.
Clause 123: The method of clause 122, wherein the configuration is obtained via the network.
Clause 124: The method of any one of clauses 122 or 123, wherein the network comprises cabling.
Clause 125: The method of clause 124, wherein the cabling comprises optical cabling and/or coaxial cabling.
Clause 126: The method of any one of clauses 124 or 125, wherein the downstream cellular communication signal manipulated, is routed to the at least one RAU via the cabling.
Clause 127: The method of any one of clauses 124-126, wherein the cabling is configured to transmit electrical power and communication signals.
Clause 128: The method of any one of clauses 124-127, wherein a cable of the cabling is configured to transmit electrical power, cellular communication signals, and communication signals of at least one other communication type.
Clause 129: The method of any one of clauses 124-128, wherein a cable of the cabling is disposed at least in part in an envelope of the facility.
Clause 130: The method of clause 129, wherein the facility comprises a building.
Clause 131: The method of clause 130, wherein the cabling is disposed at least in part in an envelope of the building.
Clause 132: The method of any one of clauses 124-131, wherein the cabling is a first cabling system installed in the facility.
Clause 133: An apparatus for routing signals in a facility, the apparatus comprising at least one controller configured to execute, or direct execution of, one or more operations of any of the methods of clauses 111 to 132.
Clause 134: An apparatus for routing signals in a facility, the apparatus comprising at least one controller, which at least one controller is configured to: receive, or direct receipt of, a configuration for routing cellular communication signals between small cell devices associated with the facility and Radio Access Units (RAUs) associated with the facility; and route, or direct routing of, the cellular communication signals between one or more of the small cell devices and one or more of the RAUs, wherein routing the cellular communication signals between the one or more of the small cell devices and the one or more of the RAUs comprises: (i) (A) receive, or direct receipt of, a downstream cellular communication signal from at least one of the one or more of the small cell devices; (B) manipulate, or direct manipulation of, the downstream cellular communication signal by splitting and/or combining the downstream cellular communication signal based at least in part on the configuration; and (C) route, or direct routing of, the downstream cellular communication signal manipulated, to at least one RAU of the one or more of the RAUs based at least in part on the configuration; and/or (ii) (a) receive, or direct receipt of, an upstream cellular communication signal from at least one RAU of the one or more of the RAUs; (b) manipulate, or direct manipulation of, the upstream cellular communication signal at least in part by splitting and/or combining the upstream cellular communication signal based at least in part on the configuration; and (c) routing the upstream cellular communication signal manipulated, to at least one of the one or more of the small cell devices based at least in part on the configuration.
Clause 135: A non-transitory computer readable program instructions for routing signals in a facility, the non-transitory computer program instructions, when read by one or more processors, causes the one or more processors to execute, or direct execution of, one or more operations of any of the methods of clauses 111 to 132. Clause 136: A non-transitory computer readable program instructions for routing signals in a facility, the non-transitory computer program instructions, when read by one or more processors, causes the one or more processors to execute operations comprising: receiving, or directing receipt of, a configuration for routing cellular communication signals between small cell devices associated with the facility and Radio Access Units (RAUs) associated with the facility; and routing, or directing routing of, the cellular communication signals between one or more of the small cell devices and one or more of the RAUs, wherein routing, or directing routing of, the cellular communication signals between the one or more of the small cell devices and the one or more of the RAUs comprises: (i) (A) receiving, or directing receipt of, a downstream cellular communication signal from at least one of the one or more of the small cell devices; (B) manipulating, or directing manipulation of, the downstream cellular communication signal by splitting and/or combining the downstream cellular communication signal based at least in part on the configuration; and (C) routing, or directing routing of, the downstream cellular communication signal manipulated, to at least one RAU of the one or more of the RAUs based at least in part on the configuration; and/or (ii) (a) receiving, or directing receipt of, an upstream cellular communication signal from at least one RAU of the one or more of the RAUs; (b) manipulating, or directing manipulation of, the upstream cellular communication signal at least in part by splitting and/or combining the upstream cellular communication signal based at least in part on the configuration; and (c) routing, or directing routing of, the upstream cellular communication signal manipulated, to at least one of the one or more of the small cell devices based at least in part on the configuration.
Clause 137: A system for routing signals in a facility, the system comprising one or more small cell devices associated with the facility, one or more Radio Access Units (RAUs) associated with the facility, and at least one controller configured to facilitate one or more operations of any of the methods of clauses 111 to 132.
Clause 138: A system for routing signals in a facility, the system comprising: a network disposed in the facility; small cell devices operatively coupled to the network;
Radio Access Units (RAUs) operatively coupled to the network; and a router operatively coupled to the network, which router is configured to: receive, or direct receipt of, a configuration for routing cellular communication signals between small cell devices associated with the facility and Radio Access Units (RAUs) associated with the facility; and route, or direct routing of, the cellular communication signals between one or more of the small cell devices and one or more of the RAUs, wherein routing the cellular communication signals between the one or more of the small cell devices and the one or more of the RAUs comprises: (i) (A) receive, or direct receipt of, a downstream cellular communication signal from at least one of the one or more of the small cell devices; (B) manipulating the downstream cellular communication signal by splitting and/or combining the downstream cellular communication signal based at least in part on the configuration; and (C) routing the downstream cellular communication signal manipulated, to at least one RAU of the one or more of the RAUs based at least in part on the configuration; and/or (ii) (a) receive, or direct receipt of, an upstream cellular communication signal from at least one RAU of the one or more of the RAUs; (b) manipulating the upstream cellular communication signal at least in part by splitting and/or combining the upstream cellular communication signal based at least in part on the configuration; and (c) routing the upstream cellular communication signal manipulated, to at least one of the one or more of the small cell devices based at least in part on the configuration.
Clause 139: The system of clause 138, wherein the router comprises one or more processors.

1. A method of routing signals in a facility, the method comprising:
identifying small cell devices and Radio Access Units (RAUs) operatively coupled to a network of the facility;
receiving one or more inputs through the network;
determining a configuration for routing cellular communication signals between one or more of the small cell devices and one or more of the RAUs, which configuration is based at least in part on the one or more inputs; and
routing the cellular communication signals between the one or more of the small cell devices and the one or more of the RAUs based at least in part on the configuration.

2. The method of claim 1, wherein the small cell devices are disposed in the facility and/or the RAUs are disposed in the facility.

3. (canceled)

4. (canceled)

5. The method of claim 1, wherein the one or more inputs are associated with an occupancy of personnel in the facility.

6. The method of claim 1, wherein the one or more inputs comprise scheduling information, occupancy information, sensor data, or any combination thereof.

7. The method of claim 6, wherein the sensor data comprises electromagnetic radiation data.

8. The method of claim 6, wherein the sensor data comprises geolocation signals.

9. The method of claim 8, wherein the geolocation signals comprise Global Positioning System signals, ultrawideband signals, short-range wireless signal, or any combination thereof.

10. The method of claim 6, wherein the sensor data comprises heat signatures associated with one or more personnel.

11. The method of claim 1, wherein the configuration is determined in real-time during receipt of the cellular communication signals.

12. The method of claim 1, wherein the network is operatively coupled to one or more controllers that are configured to control at least one device that includes (i) a service device, (ii) a safety device, (iii) a security device, and/or (iv) a health device.

13. (canceled)

14. (canceled)

15. The method of claim 12, wherein the service device comprises a media player, a media display, a radio, a music player, a heater, a cooler, a ventilator, lighting, a tintable window, an automatic door, or a heating, ventilation, and air conditioning (HVAC) system.

16. The method of claim 2, wherein the service device is configured to adjust an environment of the facility.

17. (canceled)

18. The method of claim 1, wherein the configuration dynamically routes the cellular communication signals based at least in part on occupancy in one or more portions of the facility.

19. The method of claim 1, wherein the configuration is based at least in part on an occupancy in the facility.

20. The method of claim 1, wherein the configuration is based at least in part on an occupancy of users of the cellular communication signals in the facility.

21. The method of claim 1, wherein routing the cellular communication signals between the one or more of the small cell devices and the one or more of the RAUs based at least in part on the configuration comprises transmitting information indicating the configuration to a router associated with the facility, the router configurable to carry out routing of the cellular communication signals between the one or more of the small cell devices and the one or more of the RAUs.

22. (canceled)

23. (canceled)

24. (canceled)

25. A method of changing communications characteristics in a facility, the method comprising:
obtaining a configuration for routing signals between one or more small cell devices associated with the facility and one or more Radio Access Units (RAUs) associated with the facility;
obtaining usage information associated with the facility, wherein the usage information indicates current or expected small cell device usage by mobile devices associated with the facility;
determining one or more parameters associated with: (I) a channel sharing protocol for two or more small cell devices allocated to an RAU of the one or more RAUs based at least in part on the configuration, (II) transmit or receive power specifications for one or more components associated with the facility based at least in part on the usage information, or (III) any combination thereof; and
providing the one or more parameters associated with: (i) the channel sharing protocol to the two or more small cell devices, (ii) the transmit or receive power specifications to the one or more components associated with the facility, or (iii) any combination thereof.

26. (canceled)

27. The method of claim 25, wherein the usage information comprises scheduling information, occupancy information, or any combination thereof.

28.-40. (canceled)

41. A method of routing signals in a facility, the method comprising:
receiving a configuration for routing cellular communication signals between small cell devices associated with the facility and Radio Access Units (RAUs) associated with the facility; and
routing the cellular communication signals between one or more of the small cell devices and one or more of the RAUs, wherein routing the cellular communication signals between the one or more of the small cell devices and the one or more of the RAUs comprises:
(i)(A) receiving a downstream cellular communication signal from at least one of the one or more of the small cell devices; (B) manipulating the downstream cellular communication signal at least in part by splitting and/or combining the downstream cellular communication signal based at least in part on the configuration; and (C) routing the downstream cellular communication signal manipulated, to at least one RAU of the one or more of the RAUs based at least in part on the configuration; and/or
(ii) (a) receiving an upstream cellular communication signal from at least one RAU of the one or more of the RAUs; (b) manipulating the upstream cellular communication signal by splitting and/or combining the upstream cellular communication signal based at least in part on the configuration; and (c) routing the manipulated upstream cellular communication signal to at least one of the one or more of the small cell devices based at least in part on the configuration.

42. The method of claim 41, wherein the downstream cellular communication signals have been modulated and/or the upstream cellular communication signal has been modulated.

43.-56. (canceled)
